(19) United States
(12) Patent Application Publication
(10) Pub. No.: US 2024/0112929 A1
(43) Pub. Date: Apr. 4, 2024

(54) PROCESSING DEVICE

(71) Applicant: YAMAHA HATSUDOKI KABUSHIKI KAISHA, Shizuoka (JP)

(72) Inventors: Yoshikuni SUZUKI, Iwata-shi, Sizuoka (JP); Shigeyuki UCHIYAMA, Chikuma-shi, Nagano (JP)

(73) Assignee: YAMAHA HATSUDOKI KABUSHIKI KAISHA, Shizuoka (JP)

(21) Appl. No.: 18/264,709

(22) PCT Filed: Feb. 10, 2021
(86) PCT No.: PCT/JP2021/005042

§ 371 Date: Aug. 8, 2023

(51) Int. Cl. H01L 21/67; H01L 21/677; H01L 21/68; H01L 21/683; H01L 21/687

(52) U.S. Cl. CPC H01L 21/67092; H01L 21/67259; H01L 21/67766; H01L 21/681; H01L 21/6838; H01L 21/68764; H01L 21/68785

(57) ABSTRACT

A processing device that processes a workpiece of a plate shape having a thickness direction along an upper-bottom direction includes a controller configured to control an operation of the processing device, a storing section storing the workpiece, a transfer section including a transfer hand on which the workpiece is placed and that moves the workpiece from and into the storing section, a processing section processing the workpiece, a holding section holding an upper surface of the workpiece, and a moving section horizontally moving the holding section between the transfer hand and the processing section. The holding section receives and places the workpiece from and on the transfer hand above the transfer hand. The processing section processes the workpiece from below and the workpiece is held by the holding section.

### CROSS-REFERENCE TO RELATED APPLICATION

This application is a National Stage of International Patent Application No. PCT/JP2021/005042, filed Feb. 10, 2021, the entire content of which is incorporated herein by reference.

### BACKGROUND

### Technical Field

The present disclosure relates to a processing device.

### Background Art

A processing device for processing a workpiece such as a semiconductor wafer described in Japanese Unexamined Patent Publication No. 2018-098363 has been known. In the laser processing device (a processing device) described in Japanese Unexamined Patent Publication No. 2018-098363, a workpiece that is stored in a cassette (a storing section) is moved to a temporary table with using a robot hand. Then, the workpiece placed on the temporary table is moved to a chuck table (a holding section) with using a sucker pad and the workpiece on the chuck table is processed with laser beam processing.

The workpiece is transferred from the cassette to the chuck table via the robot hand, the temporary table, and the sucker pad in this order and four transfer operations are necessary before starting the processing of the workpiece stored in the cassette.

### SUMMARY

Problems described below may be caused in the above-described laser processing device. A space for the temporary table is necessary and this increases the size of the processing device and a large installation space is necessary. The increased number of transfer operations increases the required time and this may lower productivity. Furthermore, with the increased number of transfer operations, the workpiece may be likely to be contacted with other components and receive impact and the yield may decrease.

The technology described herein is a processing device processing a workpiece of a plate shape having a thickness direction along an upper-bottom direction. The processing device includes a controller configured to control an operation of the processing device, a storing section storing the workpiece, a transfer section, a processing section processing the workpiece, a holding section holding an upper surface of the workpiece, and a moving section. The transfer section includes a transfer hand on which the workpiece is placed and moves the workpiece from and into the storing section. The moving section horizontally moves the holding section between the transfer hand and the processing section and moves the holding section relative to the processing section when the processing section processes the workpiece. The holding section receives and places the workpiece from and on the transfer hand above the transfer hand. The processing section processes the workpiece from below and the workpiece is held by the holding section.

The holding section can hold the upper surface of the workpiece. Therefore, the holding section can directly hold the workpiece that is placed on the transfer hand. With the holding section that holds the workpiece releasing the holding, the workpiece can be directly placed on the transfer hand that is disposed on a lower side. Accordingly, when the workpiece is transferred between the holding section and the transfer hand, a space (a temporary space) in which the workpiece is temporarily placed is not necessary. This downsizes the processing device and an installation space for the processing device can be reduced.

The direct transferring without using the temporary space can reduce the number of times the workpiece is transferred. This shortens the time required for starting the processing and the time required for storing the processed workpiece in the storing section. This increases productivity of the processing device.

With the number of transfer times being reduced, the workpiece has less opportunity to receive an impact and to be contacted with other components. The workpiece is less likely to be damaged and the yield increases.

The processing section processes the workpiece from a lower side. Dust caused by the processing drops down and is less likely to adhere to the workpiece. Accordingly, the workpiece can be kept clean and contamination is less likely to occur and the yield increases.

According to the present disclosure, the transfer hand that transfers the workpiece from the storing section directly places and receives the workpiece on and from the holding section without using a temporary table. Therefore, a temporary table is not necessary and this downsizes the processing device and decreases the installation space for the processing device.

The workpiece is transferred from the storing section to the holding section via the transfer hand. In the transferring operation, the number of transfer times before the starting of the processing is only two. This shortens total time required for the transferring operation and productivity of the processing device can be increased. With the number of transfer times being decreased, the workpiece has less opportunity to receive a damage and the yield of the workpiece can increase.

### BRIEF DESCRIPTION OF THE DRAWINGS

FIG. 1A is a plan view of a processing device;

FIG. 1B is a front view of the processing device;

FIG. 1C is a side view of the processing device;

FIG. 2 is a block diagram of the processing device;

FIG. 3 is a front view of a holding section and a processing section;

FIG. 4 is a perspective view of a workpiece;

FIG. 5 is a cross-sectional view of the workpiece along A-A line;

FIG. 6 is a plan view of a transfer section;

FIG. 7 is a side view of the transfer section;

FIG. 8 is a side view of a temporary positioning unit;

FIG. 9 is a flowchart of an inclination calculation process in a wafer inclination correction process;

FIG. 10 is a bottom view of a semiconductor wafer;

FIG. 11 is a graph representing inclination of a device surface;

FIG. 12 is graphs representing Xs-axis speed and Zs-axis speed during Xs-Zs axes synchronization control;

FIG. 13 is a flowchart of a previous calibration process;

FIG. 14 is a view illustrating measurement points Q1 to Q3;

FIG. 15 is a flowchart of a process performed by the processing device;

FIG. 16A is a view illustrating a supply process;

FIG. 16B is a view illustrating the supply process;

FIG. 16C is a view illustrating the supply process;

FIG. 16D is a view illustrating the supply process;

FIG. 16E is a view illustrating the supply process;

FIG. 16F is a view illustrating the supply process;

FIG. 16G is a view illustrating the supply process;

FIG. 16H is a view illustrating the supply process;

FIG. 16I is a view illustrating the supply process;

FIG. 17A is a view illustrating a storing process;

FIG. 17B is a view illustrating the storing process;

FIG. 17C is a view illustrating the storing process;

FIG. 17D is a view illustrating the storing process;

FIG. 17E is a view illustrating the storing process;

FIG. 17F is a view illustrating the storing process;

FIG. 17G is a view illustrating the storing process;

FIG. 17H is a view illustrating the storing process;

FIG. 17I is a view illustrating the storing process;

FIG. 18A is a view illustrating a whole process;

FIG. 18B is a view illustrating the whole process;

FIG. 18C is a view illustrating the whole process;

FIG. 18D is a view illustrating the whole process;

FIG. 18E is a view illustrating the whole process;

FIG. 18F is a view illustrating the whole process;

FIG. 18G is a view illustrating the whole process;

FIG. 18H is a view illustrating the whole process;

FIG. 19A is a plan view of a processing device according to a second embodiment;

FIG. 19B is a front view of the processing device according to the second embodiment;

FIG. 19C is a side view of the processing device according to the second embodiment;

FIG. 20 is a plan view of a third transfer section;

FIG. 21A is a side view of the third transfer section;

FIG. 21B is a side view of the third transfer section (without illustrating a Z3-axis moving section and a Y3-axis moving section);

FIG. 22 is a flowchart of a process in the processing device;

FIG. 23A is a view illustrating a process of supplying, processing, and storing;

FIG. 23B is a view illustrating the process of supplying, processing, and storing;

FIG. 23C is a view illustrating the process of supplying, processing, and storing;

FIG. 23D is a view illustrating the process of supplying, processing, and storing;

FIG. 23E is. a view illustrating the process of supplying, processing, and storing;

FIG. 23F is a view illustrating the process of supplying, processing, and storing;

FIG. 23G is a view illustrating the process of supplying, processing, and storing;

FIG. 23H is a view illustrating the process of supplying, processing, and storing;

FIG. 23I is a view illustrating the process of supplying, processing, and storing;

FIG. 23J is a view illustrating the process of supplying, processing, and storing;

FIG. 23K is a view illustrating the process of supplying, processing, and storing;

FIG. 23L is a view illustrating the process of supplying, processing, and storing;

FIG. 23M is a view illustrating the process of supplying, processing, and storing;

FIG. 23N is a view illustrating the process of supplying, processing, and storing;

FIG. 23O is a view illustrating the process of supplying, processing, and storing;

FIG. 23P is a view illustrating the process of supplying, processing, and storing;

FIG. 24A is a view illustrating the process of supplying, processing, and storing (a plan view);

FIG. 24B is a view illustrating the process of supplying, processing, and storing (a plan view);

FIG. 24C is a view illustrating the process of supplying, processing, and storing (a plan view);

FIG. 24D is a view illustrating the process of supplying, processing, and storing (a plan view);

FIG. 24E is a view illustrating the process of supplying, processing, and storing (a plan view);

FIG. 24F is a view illustrating the process of supplying, processing, and storing (a plan view);

FIG. 24G is a view illustrating the process of supplying, processing, and storing (a plan view); and

FIG. 24H is a view illustrating the process of supplying, processing, and storing (a plan view).

### DETAILED DESCRIPTION

<General Description of Processing Device>

A processing device processing a workpiece of a plate shape having a thickness direction along an upper-bottom direction includes a controller configured to control an operation of the processing device, a storing section storing the workpiece, a transfer section, a processing section processing the workpiece, a holding section holding an upper surface of the workpiece, and a moving section. The transfer section includes a transfer hand on which the workpiece is placed and moves the workpiece from and into the storing section. The moving section horizontally moves the holding section between the transfer hand and the processing section and moves the holding section relative to the processing section when the processing section processes the workpiece. The holding section receives and places the workpiece from and on the transfer hand above the transfer hand. The processing section processes the workpiece from below and the workpiece is held by the holding section.

According to such a configuration, when the holding section receives the workpiece from the transfer hand, the holding section holds the upper surface of the workpiece that is placed on the transfer hand. When the transfer hand receives the workpiece from the holding section, the workpiece whose upper surface is held by the holding section is placed on the transfer hand. Namely, the workpiece can be directly passed between the holding section and the transfer hand.

Accordingly, a temporary space between the transfer hand and the holding section is not necessary and this downsizes the processing device and decreases the installation space for the processing device.

The workpiece is directly transferred without using the temporary space and this decreases the number of transfer times of the workpiece. This shortens time required before starting the processing of the workpiece stored in the storing section and time required for storing the workpiece after the processing into the storing section and productivity of the processing device can be increased.

Furthermore, with the number of transfer times being decreased, the workpiece has less opportunity to receive a damage and be contacted with other components. Accordingly, the workpiece is less likely to be damaged and the yield of the workpiece can increase.

The processing section processes the workpiece from a lower side. Dust caused by the processing drops down and is less likely to adhere to the workpiece. Accordingly, the workpiece can be kept clean and contamination is less likely to occur and the yield of the workpiece increases.

The transfer section may include at least one sandwich section. The sandwich section may include at least two sandwich members. The two sandwich members may hold a side surface of the workpiece that is placed on the transfer hand from an outer side to position the workpiece on the transfer hand.

With such a configuration, the workpiece that is placed on the transfer hand is held by the two sandwich members with the side surface from an outer side to be positioned at a predefined position on the transfer hand. Since the positioning can be performed on the transfer hand, another space for the positioning is not necessary and the processing device can be downsized and a space for the processing device can be reduced.

With positioning being performed on the transfer hand, the workpiece need not be moved to a position where the positioning is performed. Therefore, the number of transfer time of the workpiece can be decreased. This increases productivity and the yield of the workpiece.

The moving section may include a first moving section moving the holding section in a first direction that is perpendicular to the upper-bottom direction and a second moving section moving the holding section in a second direction that is perpendicular to the upper-bottom direction and the first direction. The first direction may correspond to a processing direction in which the workpiece is processed and the second direction may correspond to an interval feeding direction of the workpiece. A position where the holding section receives and places the workpiece from and on the transfer hand and a position of the holding section when the workpiece is processed by the processing section may be arranged in the first direction.

Generally, the distance that the holding section moves in the first direction between a receiving position and a processing position is greater than the distance that the holding section moves in the second direction that is an interval feeding direction. The processing direction in which the workpiece is processed and the direction in which the holding section moves between the receiving position and the processing position are the first direction. In the movement in the second direction, which is the interval feeding direction, higher positioning accuracy is demanded than the movement in the first direction to process the workpiece at higher accuracy.

The first moving section that moves a great distance in the first direction or the processing direction may be designed with focusing on the moving speed and the straightness. On the other hand, the second moving section that moves in the second direction may be designed with more focusing on the positioning accuracy than the moving speed and the straightness. The first moving section and the second moving section can be reasonably designed according to the respective performances and a cost for the processing device can be reduced.

The workpiece may be received from and placed on the transfer hand in the second direction. The storing section may be disposed below the moving section such that the storing section at least partially overlaps an area in which the moving section is movable with a plan view.

As previously described, the receiving position and the processing position are arranged in the first direction and the distance that the holding section moves between the receiving position and the processing position is greater than the distance that the holding section moves in the second direction (the interval feeding direction). Therefore, the shape of the processing device excluding the storing section is elongated in the first direction.

If the workpiece is transferred from and to the storing section in the first direction, the storing section and the receiving position may be arranged in the first direction and this further increases the size of the processing device including the storing section in the first direction.

On the other hand, in the above configuration, the transferring direction of the workpiece is the second direction. Therefore, the storing section and the receiving position are arranged in the second direction and the length of the processing device including the storing section in the first direction is not increased.

The storing section overlap the movable area of the moving section with a plan view. This suppresses the processing device from increasing its size in the second direction. Accordingly, the processing device can be downsized.

The first moving section may include at least two first guide portions that extend in the first direction and may be arranged in parallel to each other with respect to the second direction. The two first guide portions may support the holding section to be movable in the first direction.

With such a configuration, the holding section is supported by the pair of (two) first guide portions. Therefore, the holding section can be firmly supported and rattling and vibration can be suppressed. Accordingly, the workpiece held by the holding section is less likely to drop and the holding section can move fast in the first direction.

The second moving section may include at least two second guide portions that extend in the second direction and may be arranged in parallel to each other with respect to the first direction. The two second guide portions may support the first moving section to be movable in the second direction.

The first moving section is supported by the pair of (two) second guide portions. Therefore, the first moving section can be firmly supported and rattling and vibration can be suppressed. Accordingly, the posture of the holding section can be stable in the movement in the second direction or the interval feeding direction. The interval feeding can be performed precisely.

The storing section may include a first storing section storing the workpiece that is not processed and a second storing section storing the workpiece that is processed. The transfer hand may include a first transfer hand that transfers the workpiece from the first storing section and to a position where the holding section receives the workpiece and a second transfer hand that receives the workpiece from the holding section and transfers the workpiece into the second storing section.

According to such a configuration, after the processed workpiece is transferred from the holding section to the second transfer hand, the holding section can move to be above the first transfer hand and receive the workpiece that is not processed from the first transfer hand before waiting until the processed workpiece is stored in the storing section. Accordingly, the takt time of the processing device can be shortened and the productivity is increased.

The transfer section may include an auxiliary hand on which the workpiece is placed. The auxiliary hand may receive the workpiece from the holding section and transfers the workpiece to the transfer hand.

Accordingly, right after transferring the processed workpiece to the auxiliary hand, the holding section can move to be above the transfer hand and receive the workpiece that is not processed from the transfer hand. Namely, the holding section can hold the workpiece to be processed next and move the workpiece to the processing section before waiting until the processed workpiece is stored in the storing section. Accordingly, the takt time of the processing device can be shortened and the productivity is increased.

The workpiece may have at least three plate surface measurement points on a plate surface. The processing section may include a camera that takes an image of each of the at least three plate surface measurement points and measures coordinates of each of the at least three plate surface measurement points and further include a third moving section that moves the processing section in the upper-bottom direction. The controller may specify the plate surface based on the coordinates of the plate surface measurement points before performing processing and control the processing section to perform the processing with controlling the third moving section to move the processing section such that distances between arbitrary points on the plate surface and the processing section are same.

Accordingly, the processing can be performed with keeping a constant distance between a point on the plate surface and the processing section with using the third moving section. This increases the processing accuracy of the processing in the upper-bottom direction by the processing section. Accordingly, the number of times of re-processing can be reduced and the yield can be increased.

The holding section may have a bottom surface that holds the workpiece and the bottom surface may include at least three bottom surface measurement points. The processing section may include a camera that takes an image of each of the at least three bottom surface measurement points and measure coordinates of each of the at least three bottom surface measurement points. The controller may specify the plate surface based on the coordinates of the bottom surface measurement points and calculate a distance between a point on the bottom surface and the processing section.

The holding section holds the upper surface of the workpiece with the bottom surface thereof and the holding section is contacted with the workpiece. The calculated distance between a point on the bottom surface of the holding section and the processing section is used as an initial value of the distance between the workpiece and the processing section at the starting of the processing. Accordingly, the distance between the workpiece and the processing section can be measured in a short time.

### First Embodiment

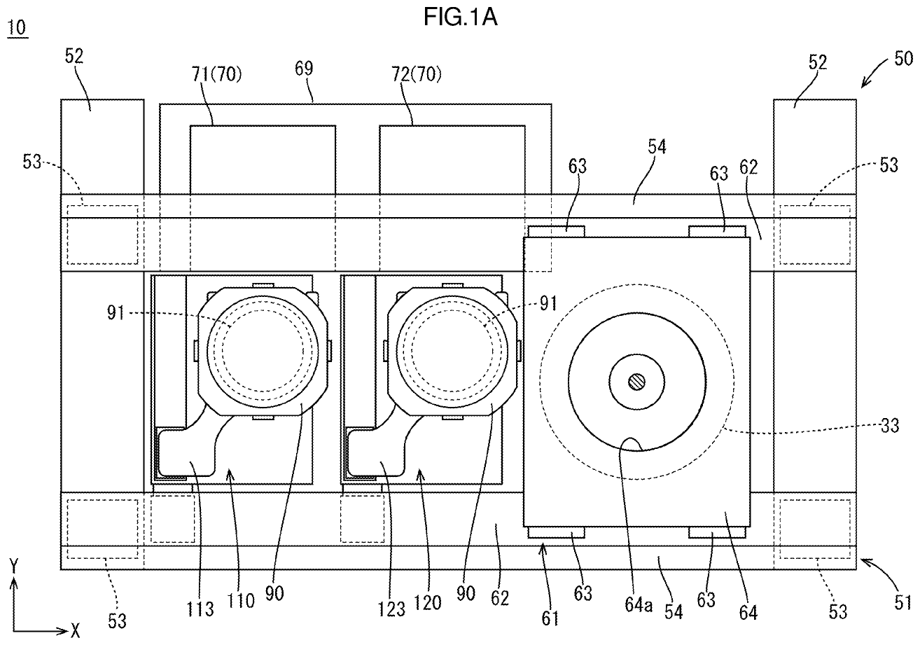

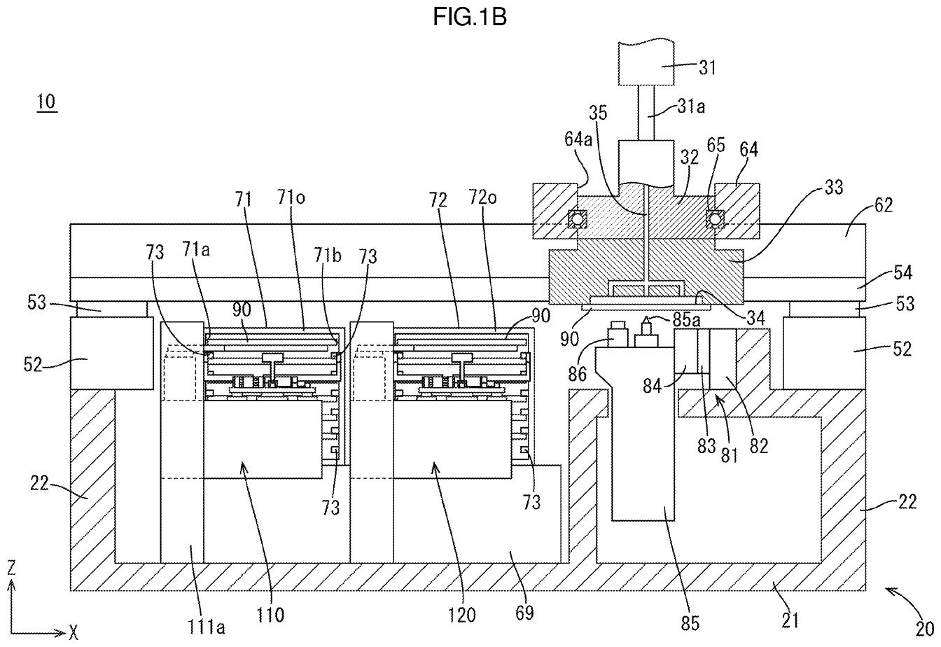

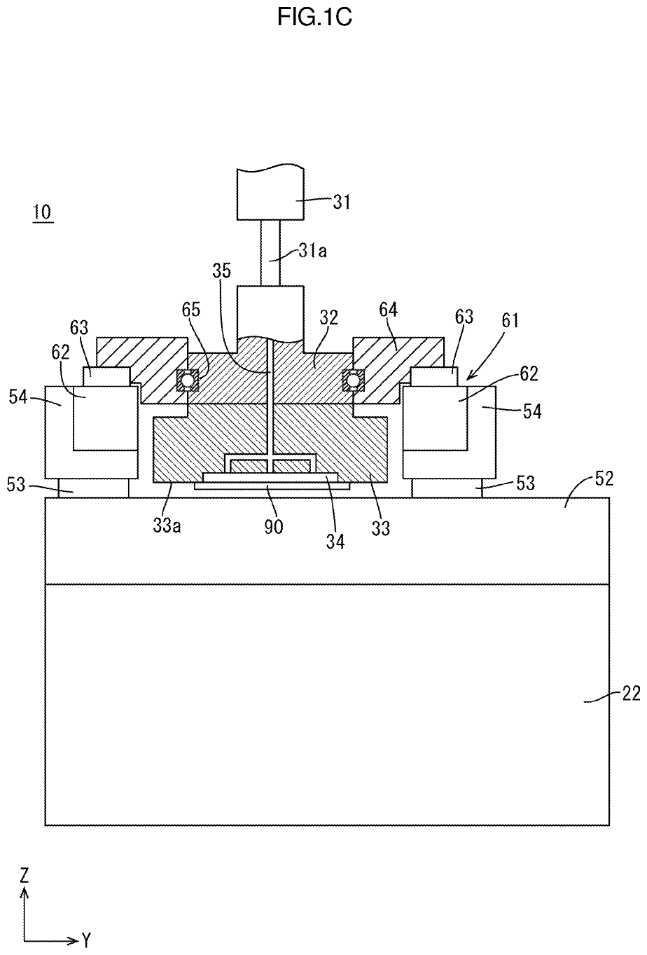

One embodiment of the technology described herein will be described with reference to FIGS. 1 to 18H as a first embodiment.

1. Configuration of Processing Device 10

1.1 Whole Configuration

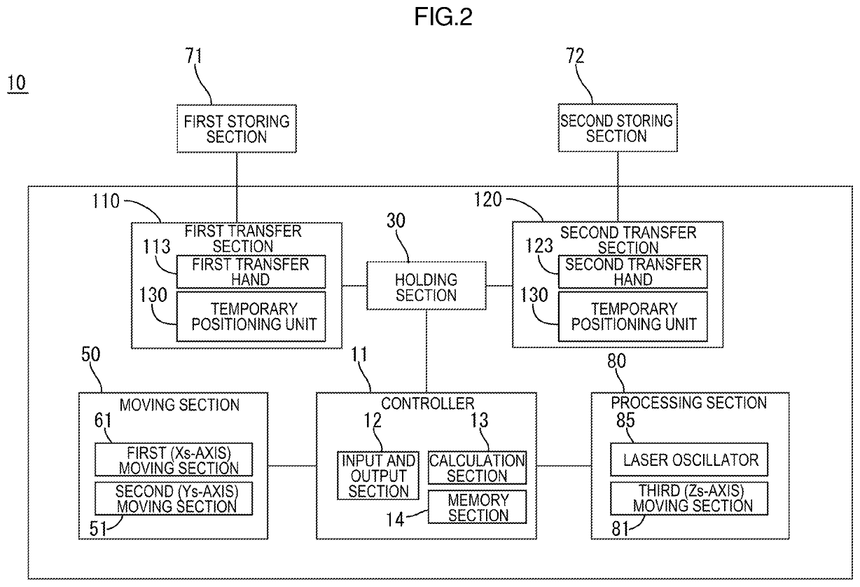

A processing device 10 is illustrated in FIGS. 1A to 1C as one example of a processing device according to the present disclosure. The processing device 10 is a laser dicing device that irradiates a pulse laser on a workpiece 90 to perform dicing processing. Three drawings of FIGS. 1A to 1C are a plan view, a front view, and a side view, respectively. FIG. 2 is a block diagram of the processing device 10.

The processing device 10 has a rectangular plan view shape elongated in an X-direction. The processing device 10 includes a base 20, a holding section 30, a moving section 50, a storing section 70, a storing section base 69, a processing section 80, and a controller 11. The holding section 30 holds the workpiece 90 from above. The moving section 50 is disposed on the base 20 and configured to move the holding section 30 in the X-direction and a Y-direction. The storing section 70 is disposed on the storing section base 69. The processing section 80 processes the workpiece 90 from below. The controller 11 is configured to control operations of the sections.

As illustrated in FIG. 2, the controller 11 includes an input and output section 12 such as a keyboard and a display, a calculation section 13 (CPU) configured to perform a calculation process, and a memory section 14 (RAM, ROM) storing control programs, measurement data, and processing instructions. The controller 11 is a generally used computer.

In the following description, the vertical direction is defined as a Z-direction, the right-left direction in the plan view of FIG. 1A (a long-side direction of the processing device 10) is defined as the X-direction, and the upper-bottom direction (a short-side direction of the processing device 10) is defined as the Y-direction. The X-direction is an example of a first direction and the Y-direction is an example of a second direction. An X-Y surface extending in the X-direction and the Y-direction is a horizontal surface.

As illustrated in FIG. 1B, the base 20 includes a base horizontal portion 21 having a rectangular plate shape and two base vertical portions 22. The base vertical portions 22 extend upward in the vertical direction from two edges of the base horizontal portion 21 with respect to the X-direction. Ys-axis ball screws 52 (one example of a second guide portion) are horizontally disposed on and fixed to the upper edge surfaces of the base vertical portions 22, respectively. The storing section base 69 on which the storing section 70 is disposed is disposed on the base horizontal portion 21.

The storing section base 69 is a rectangular parallelepiped base that is disposed on the base horizontal portion 21. The storing section base 69 has an upper surface 69a that is flat and horizontal. Two storing sections 70 (a first storing section 71, a second storing section 72) are disposed on the upper surface 69a to be arranged in the Y-direction. The storing section base 69 and the storing sections 71, 72 are disposed below the moving section 50.

The first storing section 71 is a rectangular parallelepiped box having an opening 710 opening to the front side with respect to the Y-direction and has a space therein. The space is defined by five plate surfaces of the first storing section 71 and two plate surfaces 71a, 71b of the five plate surfaces are opposite each other with respect to the X-direction. Projections 73 project vertically from the two plate surfaces 71a, 71b.

With the plate-shaped workpiece 90 being placed on and extend between the projections 73 of the plate surface 71a and the plate surface 71b from above, the workpiece 90 can be stored in the inner space of the first storing section 71 in a horizontal state. Six projections 73 are arranged in the upper-bottom direction at equal intervals on each of the plate surfaces 71a, 71b. In this embodiment, the six workpieces 90 can be stored in the first storing section 71 so as not to be contacted with each other. This embodiment includes the storing section storing six workpieces 90 for simplifying the drawing. However, the number of workpieces 90 that can be stored in the storing section is not necessarily six but may be greater or smaller than six.

The second storing section 72 has the same configuration as that of the first storing section 71. The second storing section 72 has an opening 72o that opens to the front side with respect to the Y-direction and stores six workpieces 90 in the space therein. In this embodiment, the first storing section 71 stores the workpieces 90 that are not processed and the second storing section 72 stores the workpieces 90 that are processed.

A front opening unified pod (FOUP) may be used as the storing section 70. The FOUP is a generally used container for storing workpieces such as semiconductor wafers so as to be spaced from each other and not to be contacted with each other. With an opening of the FOUP being covered with a cover, the FOUP can be transferred with being sealed. Using the FOUP allows the workpieces to be transferred from the previous process to the processing device 10 and from the processing device 10 to the subsequent process safely and surely with preventing the workpieces from getting dirty and being damaged.

1. 2 Configuration of Moving Section

The moving section 50 has a function of moving the holding section 30, which will be described later, in the X-direction and the Y-direction. The moving section 50 includes a Ys-axis moving section 51 (one example of a second moving section) and an Xs-axis moving section 61 (one example of a first moving section). The Ys-axis moving section 51 controls movement in the Y-direction and the Xs-axis moving section 61 control movement in the X-direction.

<Ys-Axis Moving Section>

As illustrated in FIG. 1A, the Ys-axis moving section 51 includes two Ys-axis ball screws 52 (one example of the second guide portion), four Ys-axis sliders 53, and two Y-stages 54. The two Ys-axis ball screws 52 extend in the Y-direction. The Ys-axis sliders 53 are fitted to the Ys-axis ball screws 52 to be movable in the Y-direction. The Y-stages 54 are fitted to the Ys-axis sliders 53 and extend from one of the two Ys-axis ball screws 52 to the other. The two Ys-axis sliders 53 and one Y-stage 54 are configured as one unit and two units are arranged at an interval with respect to the Y-direction.

The two Ys-axis ball screws 52 are disposed respectively on the upper surfaces of the base vertical portions 22 that are at two edges of the processing device 10 with respect to the X-direction and extend in the Y-direction. The Ys-axis ball screws 52 are rotated around the axes thereof by a driving section, which is not illustrated.

The Ys-axis slider 53 includes a nut therein and the nut is to be fitted to the Ys-axis ball screw 52. The Ys-axis slider 53 is connected to the Ys-axis ball screw 52 via the nut. By rotating the Ys-axis ball screw 52, the Ys-axis slider 53 moves in the Y-direction that is the axial direction of the Ys-axis ball screw 52. With the driving section controlling the rotation direction and the rotation speed of the Ys-axis ball screws 52, the Ys-axis sliders 53 can move on the Ys-axis ball screws 52 at desired speed and in a desired direction and stop at a desired position.

Two Ys-axis sliders 53 are fitted to each of the two Ys-axis ball screws 52 and the Ys-axis moving section 51 includes four Ys-axis sliders 53. The two Ys-axis ball screws 52 rotate in synchronization with each other and rotate in the same rotation direction and at the same rotation speed. As illustrated in FIG. 1A, the four Ys-axis sliders 53 reciprocate in the Y-direction with the four Ys-axis sliders 53 being positioned at the four corners of the rectangle.

As illustrated in FIG. 1C, the Y-stage 54 is an elongated member extending in the X-direction and having a cross-sectional L shape. Each of two Y-stages 54 extends from one to another one of the two Ys-axis sliders 53 having the same Y-coordinate. Upper surfaces of the Ys-axis sliders 53 and lower surfaces of the Y-stages 54 are bonded to each other, respectively, so as not to relatively move. By rotating the Ys-axis ball screws 52, the two Y-stages 54 reciprocate in the Y-direction with keeping a predefined distance between the two Y-stages 54. The Xs-axis moving section 61 is disposed on the two Y-stages 54.

<Xs-Axis Moving Section>

The configuration of the Xs-axis moving section 61 that is disposed on the two Y-stages 54 is similar to the configuration of the Ys-axis moving section 51 that is rotated by 90 degrees with a plan view. As illustrated in FIG. 1C, the Xs-axis moving section 61 includes two Xs-axis ball screws 62 (one example of a first guide portion) that extend in the X-direction and four Xs-axis sliders 63 that are fitted to the two Xs-axis ball screws 62 to be able to reciprocate in the X-direction. The Xs-axis moving section 61 further includes an XY-stage 64 instead of the two Y-stages. The XY-stage 64 is fitted to the upper surfaces of the four Xs-axis sliders 63 and extend from one to another one of the two Xs-axis ball screws 62.

The Xs-axis ball screws 62 extend in the X-direction in which the Y-stages 54 extend and are disposed on the Y-stages 54. The Xs-axis ball screws 62 are rotated around the axes by a driving section, which is not illustrated.

The Xs-axis sliders 63 include therein nuts that are to be fitted to the Xs-axis ball screws 62. With the nuts, the Xs-axis sliders 63 and the Xs-axis ball screws 62 are joined together. With the Xs-axis ball screws 62 rotating, the Xs-axis sliders 63 move in the X-direction that is an axial direction of the Xs-axis ball screws 62. With the driving section controlling the rotation direction and the rotation speed of the Xs-axis ball screw 62, the Xs-axis sliders 63 can move on the Xs-axis ball screws 62 at desired speed and in a desired direction and stop at a desired position.

Two Xs-axis sliders 63 are fitted to each of the two Xs-axis ball screws 62 and the Xs-axis moving section 61 includes four Xs-axis sliders 63. The two Xs-axis ball screws 62 rotate in synchronization with each other and rotate in the same rotation direction and at the same rotation speed. As illustrated in FIG. 1A, the four Xs-axis sliders 63 reciprocate in the X-direction with the four Xs-axis sliders 63 being positioned at the four corners of the rectangle.

<Xy-Stage>

The XY-stage 64 has a rectangular plan view shape elongated in the Y-direction and includes a circular hole 64a in a middle. A roller bearing 65 is fitted in the hole 64a. The holding section 30, which will be described later, is held via the roller bearing 65 so as to be rotatable around the Z-axis that extends in the Z-direction with respect to the XY-stage 64.

The Xs-axis sliders 63 are bonded to the XY-stage 64 such that the upper surfaces of the Xs-axis sliders 63 are bonded to four corners of the lower surface of the XY-stage 64. According to the movement of the Xs-axis sliders 63 in the X-direction, the XY-stage 64 also moves together with the Xs-axis sliders 63. The Xs-axis sliders 63 are disposed on the Y-stages 54 that are movable in the Y-direction and move together with the Y-stages 54 according to the movement of the Y-stages 54 in the Y-direction.

With such a configuration, the Ys-axis moving section moves the Y-stages 54 in the Y-direction and the Xs-axis moving section 61 moves the XY-stage 64 in the X-direction. The Xs-axis moving section 61 is disposed on the Y-stages 54. According to such a configuration, the moving section 50 moves the XY-stage 64 to a desired position with respect to the X-direction and the Y-direction.

<Required Performance of Moving Section>

Hereinafter, the performance required for the Ys-axis moving section 51 and the Xs-axis moving section 61 will be described. Examples of the performance required for the moving sections 51, 61 are straightness of movement, positioning accuracy, and moving speed.

The straightness of movement represents the performance of the moving section 51, 61 that moves a target object (the Y-stages 54 or the XY-stage 64 in this embodiment) straight along the axial direction (the Y-direction or the X-direction). For example, with the Xs-axis moving section 61 having low straightness of movement, the XY-stage 64 may move in a direction other than the X-direction (greatly shifted in the Y-direction) in the process of moving the XY-stage 64 in the X-direction. On the other hand, with the Xs-axis moving section 61 having high straightness of movement, the XY-stage 64 is less likely to shift in the Y-direction during the movement in the X-direction and the XY-stage 64 is more likely to move straight.

The positioning accuracy represents the performance of the moving section 51, 61 that move the target object to a predefined position with a small deviation. For example, with the Xs-axis moving section 61 having high positioning accuracy, the XY-stage 64 can be moved to the predefined X-coordinate position with a smaller deviation.

The moving speed represents speed at which the moving section 51, 61 move the target object in the axial direction. For example, with the moving speed of the Xs-axis moving section 61 being high, the XY-stage 64 can be moved at a high speed in the X-direction.

Due to the difference in the operations of the Xs-axis moving section 61 and the Ys-axis moving section 51, the performances required for the Xs-axis moving section 61 and the Ys-axis moving section 51 differ from each other. In the processing device 10 of this embodiment, high performances of the straightness of movement and the moving speed are more likely to be required for the Xs-axis moving section 61 than the Ys-axis moving section 51; however, high performance of the positioning accuracy is less likely to be required for the Xs-axis moving section 61 than the Ys-axis moving section 51. High performance of the positioning accuracy is likely to be required for the Ys-axis moving section 51 than the Xs-axis moving section 61 but high performances of the straightness of movement and the moving speed are less likely to be required for the Ys-axis moving section 51 than the Xs-axis moving section 61. The following is reasons.

The X-direction corresponds to a processing direction. If the straightness of movement of the Xs-axis moving section 61 is low, the irradiation position of laser irradiated on the workpiece 90, which moves in the X-direction together with the holding section 30, by the processing section 80 is likely to be deviated from a target position with respect to the Y-direction. This lowers processing accuracy. To increase the processing accuracy, the high performance of the straightness of movement is required for the Xs-axis moving section 61.

The X-direction that corresponds to the processing direction corresponds to a direction in which a line connecting a receiving position and a processing position extends. A distance between the receiving and placing position and the processing position is long as described before. With moving a long distance at a high speed, time required for the moving can be greatly shortened and productivity of the processing device 10 can be increased. Therefore, the moving speed of the Xs-axis moving section 61 is required to be fast.

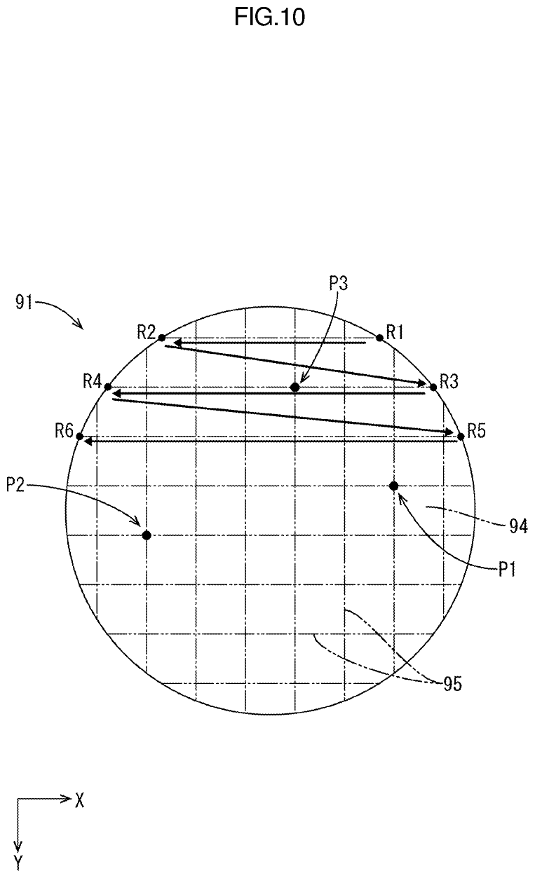

FIG. 10 illustrates a surface of a semiconductor wafer 91 included in a workpiece, which will be described later. As illustrated in FIG. 10, all processing lines 95 extend to cross the surface of the semiconductor wafer 91. In the processing, the moving section moves a distance from one end to another end of one processing line 95 at a constant speed with irradiating laser. Therefore, high positioning accuracy is not required. Specifically, in performing the processing along the processing line 95 connecting R1 and R2 in FIG. 10, laser is irradiated continuously from R1, which is a starting point, to R2, which is an end point. In the actual processing, irradiation of laser starts from a portion before the R1 (a right side of R1 in FIG. 10) and the irradiation of laser continues with moving the semiconductor wafer 91 in the X-direction and the irradiation of laser stops after a portion heading from the R2 is irradiated with laser. Namely, the irradiation of laser continues for a distance that is longer in the X-direction than a length of the processing line 95 that connects the R1 and R2. Therefore, even if the positioning accuracy of the Xs-axis moving section 61 is low and the position of the semiconductor wafer 91 in the X-direction is deviated from a target position at the time of starting the processing, the line from R1 to R2 can be processed without remaining an unprocessed portion since the distance for which the irradiation of laser is performed is longer than the processing line 95. Therefore, higher positioning accuracy is less likely to be required for the Xs-axis moving section 61 than the Ys-axis moving section 51.

As previously described, the Y-direction corresponds to the interval feeding direction. With the positioning accuracy of the Ys-axis moving section 51 being high, the processing is performed accurately according to the intervals between the processing lines 95 and this increases the processing accuracy. Therefore, high positioning accuracy is required for the Ys-axis moving section 51.

While the semiconductor wafer 91 is being processed with laser irradiation, the semiconductor wafer 91 is moved only in the X-direction (the processing direction) and does not move in the Y-direction. As previously described, laser irradiation is performed for a distance longer than the processing line 95 in the X-direction. Therefore, even if the Ys-axis moving section 51 has low straightness of movement and a positional deviation in the X-direction occurs, the processing accuracy is not adversely affected and therefore, the high straightness of movement is not required for the Ys-axis moving section 51.

After finishing the processing of one processing line 95, the moving section 50 moves the semiconductor wafer 91 such that laser is irradiated on the starting point of the processing line 95 to be processed next and the processing is performed again. Specifically, as illustrated in FIG. 10, after finishing the processing of the processing line 95 from the starting point R1 to the end point R2, the moving section 50 moves the semiconductor wafer 91 and the processing is started again from the starting point R3. With shortening the time required for the movement for a distance (from the end point R2 to the starting point R3) for which the laser irradiation is not performed, the productivity of the processing device 10 can be increased.

With dividing the movement from R2 to R3 into a movement distance in the X-direction and a movement distance in the Y-direction, the movement distance in the Y-direction corresponds to the interval between the processing lines 95 and is shorter than the movement distance in the X-direction. If the moving speeds of the moving sections 51, 61 are same, the movement in the Y-direction finishes earlier. The moving speed of the Ys-axis moving section 51 is not required to be fast as that of the Xs-axis moving section 61 as long as the movement in the Y-direction finishes before the movement in the X-direction finishes.

As previously described, each of the Ys-axis moving section 51 and the Xs-axis moving section 61 has the performance that is required and the performance that is less likely to be required. Therefore, all the performances are not necessarily increased in designing the moving sections 51, 61. By performing a cost distribution to satisfy the performances that are required for each of the moving sections 51, 61, a cost can be reduced and the moving sections are designed reasonably.

In the processing device 10 according to this embodiment, the straightness of movement of the Xs-axis moving section 61 is higher than the straightness of movement of the Ys-axis moving section 51. With such a configuration, the processing is likely to be performed straight along the processing direction and the processing accuracy can be increased. The positioning accuracy of the Ys-axis moving section 51 is higher than the positioning accuracy of the Xs-axis moving section 61. With such a configuration, the moving section can move a distance corresponding to the interval accurately and the processing accuracy of the workpiece 90 is improved. The moving speed of the Xs-axis moving section 61 is faster than the moving speed of the Ys-axis moving section 51. Accordingly, the time required for the movement in the X-direction can be shortened and the productivity of the processing device 10 can be increased.

1.3 Configuration of Holding Section

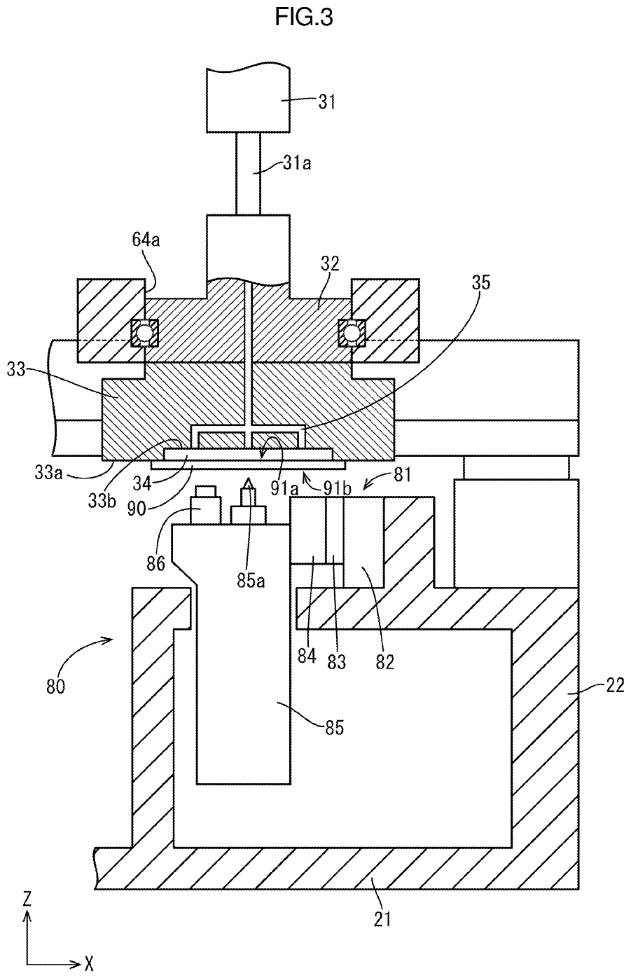

Next, the holding section 30 will be described. As illustrated in FIG. 3, the holding section 30 includes a θ-axis motor 31, a rotary member 32, and a chuck head 33. The rotary member 32 is connected to an output shaft 31a of the θ-axis motor 31 and rotatable in a θ-direction. The chuck head 33 is joined to a lower surface of the rotary member 32. The θ-axis is coaxial with the output shaft 31a and the rotation in the θ-direction represents the rotation around the θ-axis.

The θ-axis motor 31 is a DC motor, for example, and rotates the output shaft 31a by receiving power supplied from an external device. By changing a direction of a current flow, the rotational direction of the output shaft 31a is changed.

The rotary member 32 has a columnar shape having a stepped portion and is bonded to the output shaft 31a with an upper surface of the rotary member 32 so as to be rotated coaxially with the output shaft 31a. The rotary member 32 is fitted in the hole 64a and a fitted portion of the rotary member 32 has a diameter that is smaller than a diameter of the hole 64a of the XY-stage 64. The side surface of the fitted portion of the rotary member 32 is joined to the inner surface of the hole 64a via the roller bearing 65 such that the rotary member 32 is rotatable in the θ-direction with respect to the XY-stage 64. The rotary member 32 may be connected to the θ-axis motor 31 via a speed reducer.

The chuck head 33 has a disk shape and is bonded to a lower surface of the rotary member 32 so as to be coaxial with the rotary member 32 and the output shaft 31a. The chuck head 33 includes a recess 33b in a bottom surface 33a and a suction chuck 34 is closely fitted in the recess 33b. The suction chuck 34 is a disk shape member made of porous material (such as porous ceramic). The bottom surface 33a of the chuck head 33 is flush with a bottom surface of the suction chuck 34.

The rotary member 32 and the chuck head 33 include a suction cavity 35 that has openings at ends in the recess 33b. Other end of the suction cavity 35 is connected to a vacuum pump, which is not illustrated. The controller 11 switches pressure in the inner space of the suction cavity 35 between negative pressure and positive pressure with using the vacuum pump.

With the pressure in the suction cavity 35 being negative, an air flow from the lower surface toward the upper surface of the suction chuck 34 occurs in the suction chuck 34 that is made of porous material. With the workpiece 90 being contacted with the bottom surface of the suction chuck 34, the workpiece 90 is sucked and adheres on the bottom surface and the bottom surface 33a of the suction chuck 34 and held by the suction chuck 34. If the pressure in the inner space of the suction cavity 35 is switched to positive pressure with the workpiece 90 being held, the workpiece 90 is released. Thus, the holding section 30 holds and releases the workpiece 90, which is disposed below the bottom surface 33a, with the bottom surface 33a.

1.4 Configuration of Workpiece

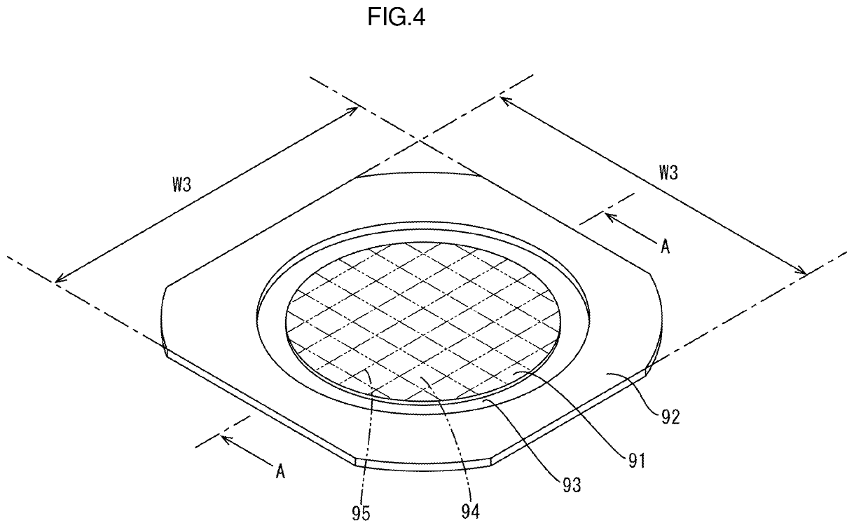

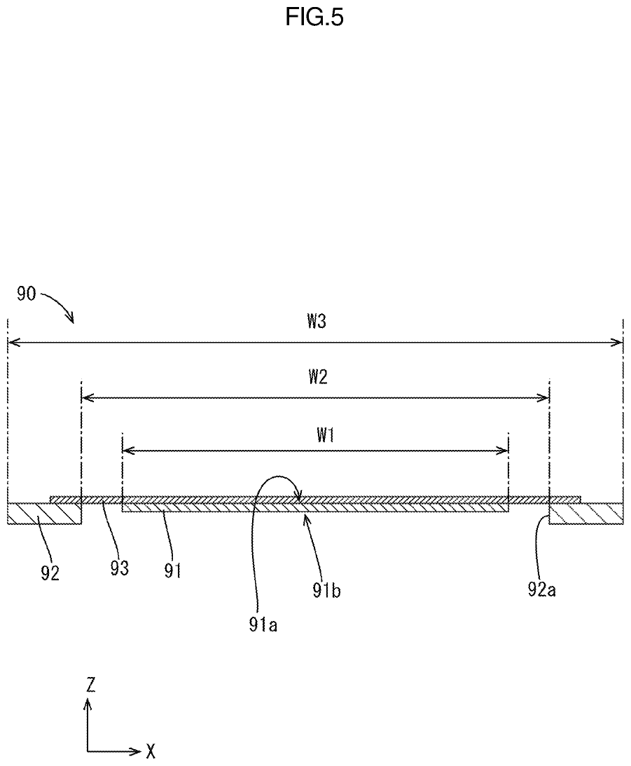

The workpiece 90 includes the semiconductor wafer 91, a wafer ring 92, and a dicing tape 93. As illustrated in FIG. 4 and FIG. 5, which is a cross-sectional view taken along A-A line in FIG. 4, the semiconductor wafer 91 and the wafer ring 92 are bonded to one surface of the dicing tape 93 and thus, the workpiece 90 is obtained.

The wafer ring 92 is a circular stainless plate having a circular hole 92a in a middle thereof. The circular hole 92a has a diameter W2. Four portions of the outer peripheral portion of the wafer ring 92 are cut off to form four sides. Two pairs of opposing sides are parallel to each other and lines extending from two adjacent sides are perpendicular. A distance between each of the two pairs of opposing sides is same and the distance is referred to an outer size W3 (refer to FIGS. 4 and 5).

One surface of the dicing tape 93 is coated with an adhesive. The dicing tape 93 is bonded to the wafer ring 92 such that the surface coated with the adhesive is opposite the plate surface of the wafer ring 92 to close the hole 92a.

The semiconductor wafer 91 is obtained by cutting a single-crystal silicon ingot into a disk-shaped member having a diameter W1 and forming a circuit pattern on one plate surface of the disc-shaped member with the CVD method. The surface having the circuit pattern is a device surface 91a and the other surface is a grinding surface 91b. In this embodiment, the device surface 91a of the semiconductor wafer 91 is bonded to the dicing tape 93.

FIG. 10 is a bottom view of the semiconductor wafer 91 seen from the grinding surface 91b side. Rectangular semiconductor chips are mounted in a matrix on the device surface 91a (an opposite surface of the surface illustrated in FIG. 10). The processing lines 95 are lines including sides of the semiconductor chips 94 and the processing section 80 irradiates laser along the lines. The processing lines 95 extend to an outer edge of the semiconductor wafer 91 and cross at right angles.

The holding section 30 holds the workpiece 90 such that the dicing tape 93 faces upward and the semiconductor wafer 91 faces downward (refer to FIG. 5). Namely, the chuck head 33 sucks the non-adhesive surface of the dicing tape 93 with the bottom surface 33a from above to hold the workpiece 90 facing downward. The processing section 80, which will be described later, irradiates laser on the grinding surface 91b along the processing lines 95 of the semiconductor wafer 91 to perform processing.

1.5 Configuration of Processing Section

As illustrated in FIG. 3, the processing section 80 includes a Zs-axis moving section 81 (one example of a third moving section), a laser oscillator 85, and a camera 86. The Zs-axis moving section 81 has a function of moving the laser oscillator 85 in the Z-direction. Specifically, the Zs-axis moving section 81 includes a Zs-axis ball screw 82 that is fixed to the base vertical portion 22 and extends in the Z-direction, a Zs-axis slider 83 that includes a nut to be fitted to the Zs-axis ball screw 82, and a Z-stage 84 that is fixed to the Zs-axis slider 83. The laser oscillator 85 is fixed to the Z-stage 84.

The configuration of the Zs-axis moving section 81 is similar to the configurations of the Ys-axis moving section 51 and the Xs-axis moving section 61 that are previously described. The controller 11 controls the driving section, which is not illustrated, to rotate the Zs-axis ball screw 82 about the axis thereof to move the Zs-axis slider 83 in the Z-direction. Since the Z-stage 84 and the laser oscillator 85 are fixed to the Zs-axis slider 83, the Zs-axis moving section 81 can move the laser oscillator 85 in the Z-direction.

The laser oscillator 85 is a generally-used laser oscillator and outputs a pulse laser having a wavelength so as to pass through (light rays passing through) the semiconductor wafer 91. The pulse laser is collected inside the laser head 85a and irradiated from the upper end of the laser head 85a upward and toward the grinding surface 91b of the semiconductor wafer 91. The irradiation of the pulse laser forms a modified layer inside the semiconductor wafer 91 without changing the surface condition of the grounding surface 91b.

The camera 86 is disposed adjacent to the laser head 85a so as to face upward or in the laser irradiation direction. The camera 86 detects a measurement point that is arbitrarily set on the circuit pattern of the semiconductor wafer 91 and transmits the coordinates (Xs, Ys, Zs) of the measurement point to the controller 11. The controller 11 calculates a relative position relation of the laser head 85a and the semiconductor wafer 91 based on the coordinates of the measurement point. The controller 11 controls each of the Ys-axis moving section 51, the Xs-axis moving section 61, and the Zx-axis moving section 81 such that the processing section 80 can irradiate a laser along the processing lines 95 of the semiconductor wafer 91.

As previously described, the semiconductor wafer 91 is held with the grinding surface 91b facing downward. Therefore, if the camera 86 is configured to detect only visible light, the camera 86 cannot recognize the circuit pattern on the device surface 91a that is on the opposite side from the camera 86. In this embodiment, an infrared camera is used as the camera 86. Infrared rays pass through the semiconductor wafer 91 that is made of silicon. Therefore, the camera 86 can take an image of the circuit pattern on the device surface 91a from the grinding surface 91b side. A previously set predefined pattern may be recognized from the taken image, and the image that is taken and the coordinates (Xs, Ys, Zs) where the predefined pattern exists can be transferred to the controller 11.

With such a configuration, the processing section 80 irradiates a laser on the grinding surface 91b of the semiconductor wafer 91 from below and a modified layer is formed inside the semiconductor wafer 91 without changing the surface condition of the semiconductor wafer 91. By moving the holding section 30 in the X-direction with continuing the irradiation of a laser, the modified layer can be formed along the processing lines 95.

After finishing the processing of one processing line 95, the holding section 30 is moved by the Xs-axis moving section 61 and the Ys-axis moving section 51 and the processing section 80 sequentially performs processing of other processing lines 95. Specifically, after finishing the processing from R1 to R2 in FIG. 10, the laser irradiation is stopped and the holding section 30 is moved and the processing from R3 to R4 is performed. Subsequently, the processing is similarly performed from R5 to R6. Thus, the processing section 80 sequentially performs processing along the processing lines 95 extending in the X-direction in FIG. 10. After finishing the processing of all the processing lines 95 extending in the X-direction, the workpiece 90 is rotated by 90 degrees by the 0-axis motor 31 and the processing lines 95 that are not processed yet are sequentially processed similarly to the above.

Thus, the processing section 80 processes all the processing lines 95 of the semiconductor wafer 91 and forms the modified layers along the processing lines 95. The controller 11 determines the processing starting position, the finishing position, and the rotation angle in the θ-direction based on the image and the coordinates obtained by the camera 86 and the processing instructions stored in the memory section 14.

Next, an expanding process will be briefly described. With the modified layers being formed, small cracks that extend from the modified layers to the plate surface of the semiconductor wafer 91 are created inside the semiconductor wafer 91. By expanding the dicing tape 93 and applying tension stress to the semiconductor wafer 91, the cracks extend from the modified layers and the semiconductor wafer 91 is separated into pieces along the separation border that corresponds to the modified layer extending along the processing line 95. Thus, the semiconductor chips 94 are obtained. The process described above is the expanding process. The expanding process is not performed by the processing device 10 but is performed by other device after the processing performed by the processing device 10.

As previously described, the processing section 80 irradiates a laser along the processing lines 95 and forms the modified layers that are to be the separation borders between the semiconductor chips 94. The processing section 80 is configured as a section irradiating a laser on the semiconductor wafer 91 and referred to as an irradiation section.

1.6 Configuration of Transfer Section

Next, a transfer section that transfers the workpiece 90 from and into the storing section 70 will be described. The processing device 10 includes two transfer sections including a first transfer section 110 disposed on the left side in FIG. 1A and a second transfer section 120 disposed on the right side. The first and second transfer sections are examples of the transfer section and have a same configuration. Hereinafter, the configuration of the first transfer section 110 will be described.

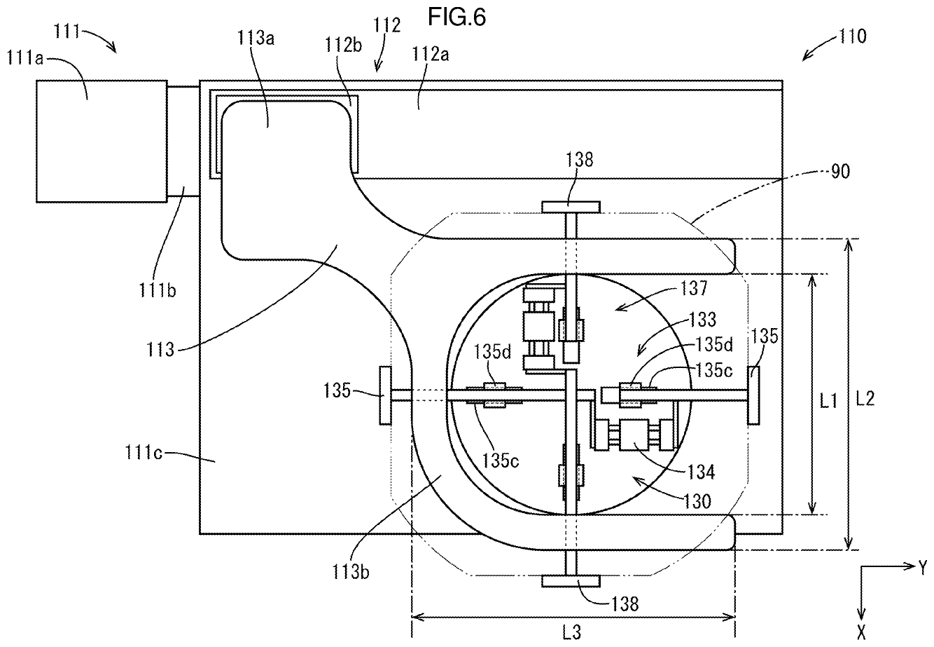

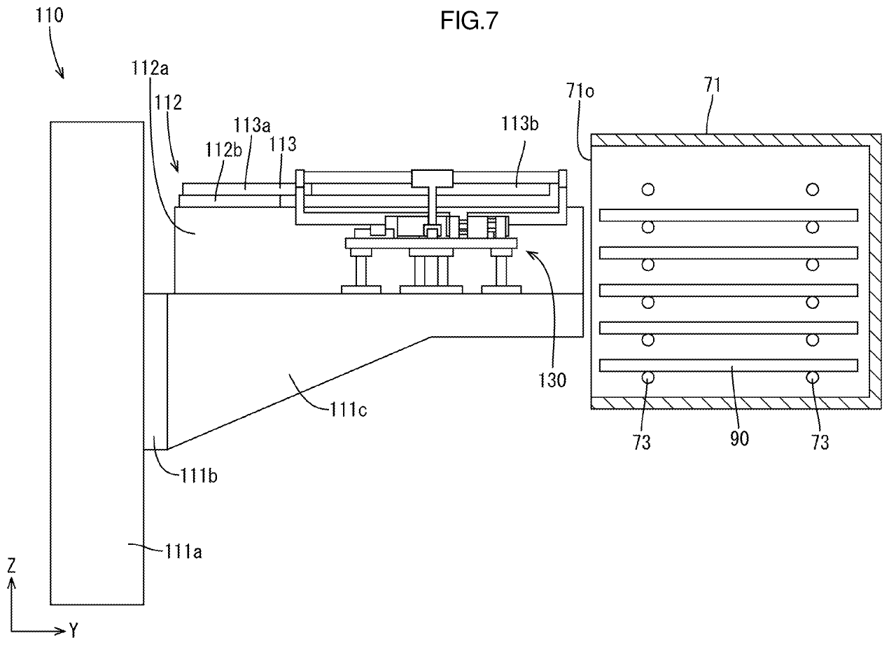

As illustrated in FIGS. 6 and 7, the first transfer section 110 includes a Z1-axis moving section 111, a Y1-axis moving section 112, a first transfer hand 113 (one example a transfer hand), and a temporary positioning unit 130. The Y1-axis and the Z1-axis are axes along which the first transfer hand 113 moves and are parallel to the Y-axis and the Z-axis, respectively.

The Z1-axis moving section 111 is fixed to the base horizontal portion 21 and includes a Z1-axis ball screw 111a extending in the Z-direction, a Za-axis slider 111b that includes a nut to be fitted to the Za-axis ball screw 111a, and a Z1-stage 111c that is fixed to the Z1-axis slider 111b. The Y1-axis moving section 112 and the temporary positioning unit 130, which will be described later, are arranged on the Z1-stage 111c.

The configuration of the Z1-axis moving section 111 is similar to the configuration of the Zs-axis moving section 81 that is previously described. The controller 11 controls the driving section, which is not illustrated, to rotate the Z1-axis ball screw 111a about the axis thereof to move the Z1-axis slider 111b in the Z-direction. Since the Z1-stage 111c is fixed to the Z1-axis slider 111b, the Y1-axis moving section 112 and the temporary positioning unit 130 that are arranged on the Z1-stage 111c move in the Z-direction with the Z1-axis moving section 111 being operated.

The Y1-axis moving section 112 is fixed to the upper surface of the Z1-stage 111c and includes a Y1-axis ball screw 112a and a Y1-axis slider 112b that includes a nut to be fitted to the Y1-axis ball screw 112a.

Similar to the Z1-axis moving section 111, the controller 11 controls the driving section, which is not illustrated, to rotate the Y1-axis ball screw 112a about the axis thereof to move the Y1-axis slider 112b in the Y-direction. The controller 11 is configured to move the Z1-axis moving section 111 and the Y1-axis moving section 112 to move the Y1-axis slider 112b freely in the Y-direction and the Z-direction.

<Transfer Hand>

As illustrated in FIG. 6, the first transfer hand 113 is a metal plate having a Y-shape and is made of stainless steel. The first transfer hand 113 includes a basal end portion 113a that is joined to the upper surface of the Y1-axis slider 112b. Therefore, the Y1-axis slider 112b and the first transfer hand 113 move together as a unit.

A distal end portion 113b of the first transfer hand 113 is branched into two portions and each of the two portions extends in the Y-direction. A distance between inner sides of the distal end portion 113b is defined as L1, a distance between outer sides of the distal end portion 113b is defined as L2, and a length of the distal end portion 113b extending in the Y-direction is defined as L3. Conditions required for the dimensions will be described below.

The distance L1 between the inner sides of the distal end portion 113b is set greater than the diameter W1 of the semiconductor wafer 91. Accordingly, with the workpiece 90 being disposed on the upper surface of the first transfer hand 113 such that the center of the semiconductor wafer 91 is positioned at a middle of the two branched portions of the distal end portion 113b, the first transfer hand 113 is not contacted with the semiconductor wafer 91.

The distance L2 between the outer sides of the distal end portion 113b and the length L3 measured in the Y-direction are smaller than the outer size W3 of the wafer ring 92. Accordingly, when the workpiece 90 is placed on the upper surface of the first transfer hand 113, at least a portion of the workpiece 90 is positioned outside the outer periphery of the distal end portion 113b with a plan view. With the temporary positioning unit 130 sandwiching the portion of the workpiece 90 from the outer side, temporary positioning can be performed.

The description above is the configuration of the first transfer section 110. The second transfer section 120 has the same configuration as that of the first transfer section 110 and will not be described in detail. The second transfer section 120 includes a second transfer hand 123 (one example of the transfer hand) and moving axes of the second transfer hand 123 are defined as a Y2-axis and a Z2-axis. The second transfer section 120 includes a Z2-axis moving section 121, a Y2-axis moving section 122, and the second hand 123.

1.7 Configuration of Temporary Positioning Unit

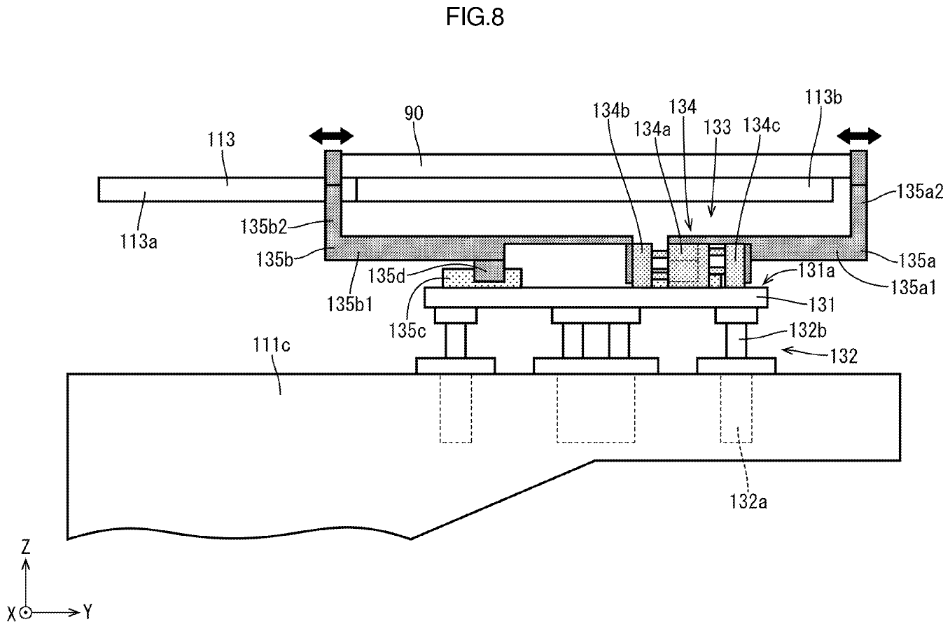

The temporary positioning unit 130 is configured to move the workpiece 90 that is disposed on the first transfer hand 113 to a predefined position on the first transfer hand 113 (normally a middle of the distal end portion 113b). As illustrated in FIG. 8, the temporary positioning unit 130 includes an up-down stage 131, a cylinder 132, a Y-sandwich section 133, and an X-sandwich section 137 (refer to FIG. 6). The Y-sandwich section 133 and the X-sandwich section 137 are examples of the sandwich section.

The cylinder 132 is a generally-used cylinder and includes a cylinder body 132a having a cylindrical shape and a rod 132b. The rod 132b is fitted in the cylinder body 132a to be movable in the axial direction of the cylinder body 132a. The cylinder bodies 132a are embedded in the Z1-stage 111c with the rods 132b projecting upward. The cylinders 132 are connected to an air supply cavity and an air pump, which are not illustrated. The controller 11 can move the rods 132b of the cylinders 132 up and down at the same time by switching air pressure in the air supply cavity between positive pressure and negative pressure.

The up-down stage 131 is a stage of a plate member that is joined to upper ends of the rods 132b. With the controller 11 controls the air pressure in the air supply cavity to positive pressure, the cylinders 132 expand upward at the same time and the up-down stage 131 moves upward. With the air pressure being changed to negative pressure, the cylinders 132 shrink at the same time and the up-down stage 131 moves downward.

The Y-sandwich section 133 and the X-sandwich section 137 are disposed on an upper surface 131a of the up-down stage 131.

The Y-sandwich section 133 includes a parallel chuck 134, a Y-sandwich member 135, a guide rail 135c, and a guide block 135d. The Y-sandwich member 135 and an X-sandwich member 138, which will be described later, are examples of a pair of sandwich members.

The parallel chuck 134 includes a body portion 134a and a pair of jaws 134b, 134c. The two cylinders are arranged in the body portion 134a so as to be oriented in opposite directions. The body portion 134a is connected to an air supply cavity and an air pump, which are not illustrated. The jaws 134b, 134c are disposed on two opposite sides of the body portion 134a, respectively. With the controller 11 switching the air pressure in the air supply cavity between positive pressure and negative pressure, a distance between the jaws 134b,134c is increased and decreased. The jaws 134b, 134c move in opposite directions with the same distance.

As illustrated in FIG. 8, the Y-sandwich member 135 includes two sandwich members 135a, 135b that have an L-shape seen from the X-direction. The sandwich member 135a includes a horizontal portion 135a1 and a vertical portion 135a2. One end portion of the horizontal portion 135a1 is joined to the jaw 134c. The vertical portion 135a2 extends upward vertically from another end of the horizontal portion 135al. The lower surface of the horizontal portion 135a1 is joined to the guide block 135d. The guide block 135d is slidably connected to the guide rail 135c that extends in the Y-direction on the upper surface 131a of the up-down stage 131. Therefore, the guide block 135d and the sandwich member 135a that is joined to the guide block 135d move along the guide rail 135c in the Y-direction.

The sandwich member 135b includes a horizontal portion 135b1 and a vertical portion 135b2. The sandwich member 135b has a configuration that is similar to but oriented in an opposite direction from that of the sandwich member 135a. The sandwich member 135b is movable in the Y-direction.

The Y-sandwich section 133 is operated as follows. With the controller 11 operating the parallel chuck 134, the Y-sandwich member 135 increases or decreases the distance between the sandwich members 135a, 135b with respect to the Y-direction. As illustrated in FIG. 8, with the large distance between the sandwich members 135a, 135b, the first transfer hand 113 having the workpiece 90 thereon is disposed between the two vertical portions 135a2, 135b2. Next, as the distance between the sandwich members 135a, 135b is decreased, the vertical portions 135a2, 135b2 hold the workpiece 90 therebetween. The jaws 134b, 134c move in opposite directions with the same distance. Therefore, with the sandwich members 135a, 135b holding the workpiece 90, the workpiece 90 can be moved to the predefined position with respect to the Y-direction on the first transfer hand 113. After moving the workpiece 90, the distance between the sandwich members 135a, 135b is increased to release the holding of the workpiece 90.

The X-sandwich section 137 has the configuration of the Y-sandwich section 133 that is rotated by 90 degrees with a plan view and will not be described in detail. The X-sandwich section 137 includes X-sandwich members 138a, 138b (one example of the pair of sandwich members). With vertical portions 138a2, 138b2 of the respective sandwich members holding the workpiece 90, the workpiece 90 can be moved to the predefined position with respect to the X-direction on the first transfer hand 113.

As described above, with the Y-sandwich member 135 and the X-sandwich member 138 holding the workpiece 90, the workpiece 90 can be moved to the predefined position on the first transfer hand 113, that is, the temporary positioning can be performed by the temporary positioning unit 130. In the temporary positioning of this embodiment, the workpiece 90 is moved such that the center of the semiconductor wafer 91 is positioned at a center of the distal end portion 113b of the first transfer hand 113 and the temporary positioning may be referred to centering.

1.8 Description of Wafer Inclination Correction Process

As previously described, the processing device 10 moves the holding section 30 in the X-direction with irradiating a laser on the workpiece 90 that is held by the holding section 30 from below and accordingly, the processing device 10 performs processing along the processing lines 95 that extend in a grid. To perform such processing with high precision, it is important to control position relation of the laser head 85a, which irradiates laser, and the surface (the device surface 91a in this embodiment) of the semiconductor wafer 91 with high precision.

The processing device 10 performs a wafer inclination correction process to keep a constant distance F between the laser head 85a and the device surface 91a.

If the semiconductor wafer 91 is moved in the X-direction with the device surface 91a being inclined with respect to the X-axis, the distance F changes according to the movement in the X-direction. If the distance F changes, the depth at which the laser is collected inside the semiconductor wafer 91 may be changed or the laser may not be collected inside the semiconductor wafer 91 and the modified layer may not be formed.

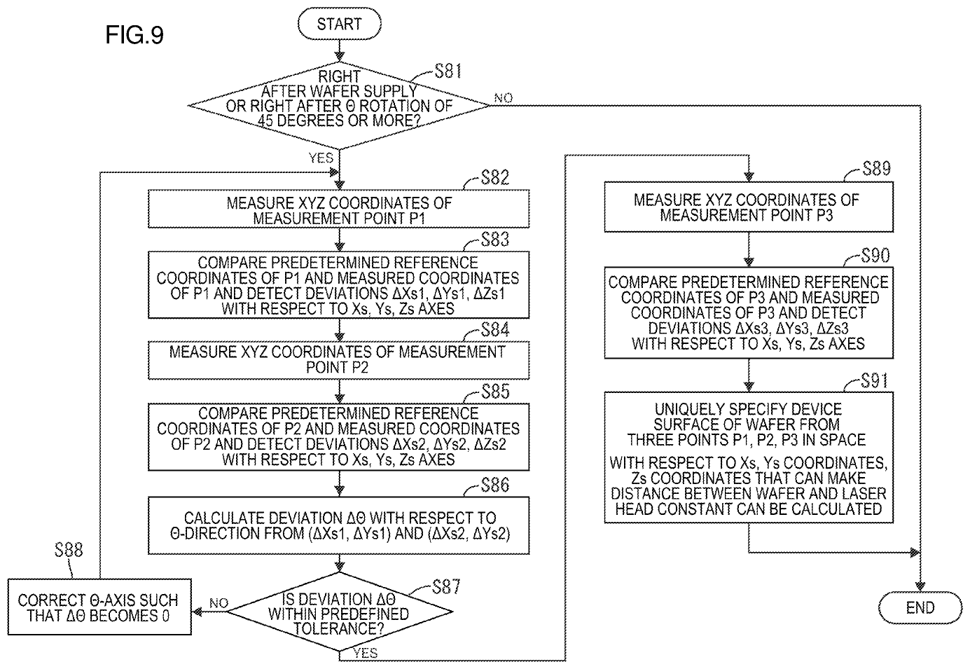

The wafer inclination correction process is performed. In the wafer inclination correction process, the inclination of the semiconductor wafer 91 is obtained before the irradiation of laser and the laser oscillator 85 is moved in the Z-direction according to the inclination to keep the distance F between the laser head 85a and the device surface 91a constant. In the following, the wafer inclination correction process will be specifically described with reference to the flowchart in FIG. 9 and FIGS. 10 to 12.

In the wafer inclination correction process, a wafer inclination calculation process is performed first and an Xs-Zs axes synchronization control is subsequently performed. The wafer inclination calculation process will be described.

<Wafer Inclination Calculation Process>

As illustrated in FIG. 10, measurement points P1, P2, P3 are previously defined in the pattern to be formed on the device surface 91a. The measurement points P1, P2, P3 are defined such that the measurement points P1, P2, P3 are not arranged on a straight line on the device surface 91a and are at corners of a triangle. As the distance between the measurement points becomes greater, the inclination can be calculated more precisely. Examples of the measurement points P1, P2, P3 on the device surface 91a are illustrated in FIG. 10.

The X-coordinates, the Y-coordinates, and the Z-coordinates of the measurement points P1-P3 on the device surface 91a that is in a completely flat condition with respect to the X-axis and the Y-axis are defined as reference coordinates. Specific values of the reference coordinates are calculated from the design positions of the measurement points P1-P3 on the semiconductor wafer 91 and are stored in the memory section 14.

If the controller 11 starts the wafer inclination calculation process, the controller 11 determines whether it is right after the semiconductor wafer 91 (the workpiece 90) is supplied to the holding section 30 or right after the 0-axis motor 31 rotates the rotary member 32 with 45 degrees or more.

If it is right after the supply of the semiconductor wafer 91 or right after the rotation of the 0-axis motor 31 (S81: YES), the inclination of the device surface 91a is unknown or the device surface 91a is likely to be moved from the previous position with the inclination being corrected. Therefore, the process will continue as follows. If the determination is other than above (S81: NO), the wafer calculation process is terminated to perform the Xs-Zs axes synchronization control, which will be described later, based on the inclination same as the one that is used in the previous correction.

If the determination at S31 is YES, the controller 11 moves the holding section 30 in the X-direction and the Y-direction such that the measurement point P1 is within the field of view of the camera 86. The controller 11 measures measurement coordinates (Xs1, Ys1, Zs1) of the measurement point P1 with respect to the Xs-axis, the Ys-axis, and the Zs-axis from the image taken by the camera 86 with the contrast method using the Zs-axis (S82).

Next, the controller 11 compares the reference coordinates of the measurement point P1 and the coordinates measured at S82 and calculates deviations ΔXs1, ΔYs1, ΔZs1 from the reference coordinates (S83).

The controller 11 performs measurement of the measurement point P2 similar to that of the measurement point P1 (S84) and calculates deviations ΔXs2, ΔYs2, ΔZs2 from the reference coordinates (S85).

From the deviations (ΔXs1, ΔYs1) and (ΔXs2, ΔYs2) calculated as described above, it can be known how much the measurement points P1, P2 deviate from the reference coordinates with respect to the X-axis and the Y-axis. An angle formed by a line segment P1P2 of the reference coordinates and a line segment P1P2 of the measured coordinates is a deviation Δθ of the device surface 91a with respect to the θ-direction (S86).

Next, the controller 11 determines whether the deviation Δθ is within a predefined tolerance Δθ0 (S87). If the deviation Δθ is greater than the predefined tolerance Δθ0 (S87: NO), the controller 11 corrects the θ-axis such that the Δθ becomes 0.

Specifically, the controller 11 drives the θ-axis motor 31 to rotate the rotary member 32 with −Δθ. Accordingly, the deviation Δθ is cancelled and the process returns to S82 and the coordinates of the measurement points P1, P2 are measured and the deviation ΔXs1 and other deviations are calculated to confirm that the deviation Δθ is cancelled.

If the deviation Δθ is smaller than the predefined tolerance Δθ0 (S87: YES), the controller 11 measures the XYZ-coordinates of the measurement point P3 (S89) and calculates deviations ΔXs3, ΔYs3, ΔZs3 (S90).

Accordingly, the coordinates of the three measurement points P1-P3 on the device surface 91a are obtained and the controller 11 can uniquely specify the device surface 91a and calculate the inclination (S91). Then, the wafer inclination process is terminated.

<Xs-Zs Axes Synchronization Control>

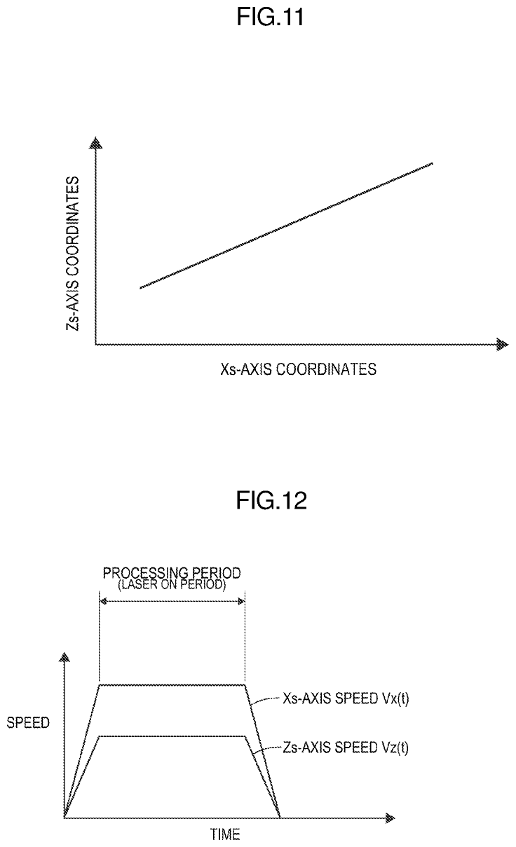

Next, the controller 11 performs the Xs-Zx axes synchronization control. The device surface 91a is uniquely specified and the Z-coordinates and the X-coordinates of the device surface 91a with respect to the Zs-axis and the Xs-axis are illustrated by the line segment in FIG. 11. Therefore, when the processing is performed with moving the holding section 30 in the X-direction, the laser head 85a is moved in the Z-direction along the line segment to keep the constant distance F.

In performing the Xs-Zx axes synchronization control, the relation of the X-direction moving speed Vx (t) of the holding section 30 and the semiconductor wafer 91, which moves together with the holding section 30, and the Z-direction moving speed Vz (t) of the laser head 85a is represented by the following formula (1). a represents the inverse of the inclination of the line segment in FIG. 11. By plotting the values of the speed Vx (t) and the speed Vz (t), which include the speeds vx(t) and Vz(t) before and after the processing, with the time being on the lateral axis and the speed being on the vertical axis, graphs in FIG. 12 are obtained.

Vx(t)=a×Vz(t) (1)

In FIG. 12, the speed of the holding section 30 and the speed of the laser head 85a are plotted. The plotting starts from when the holding section 30 starts moving in the Xs-axis direction and the laser head 85a starts moving in the Zs-axis direction at the time t is zero and the plotting continues during the processing at the constant speed after increasing the speed and until the movement stops after the processing is finished and decreasing the speed. The flat portions of the graphs correspond to the processing period and a laser is irradiated from the laser head 85a to the semiconductor wafer 91 during the processing period.

Accordingly, the speed Vx (t) and the speed Vz (t) satisfy the formula (1) and are constant from the beginning to the end of the processing period while a laser is irradiated. Namely, the semiconductor wafer 91 that is inclined with the inclination 1/a moves in the Xs-axis direction at the constant speed Vx (t) and the laser head 85a moves at the constant speed Vz (t)=Vx (t)/a in the Zs-axis direction with respect to the semiconductor wafer 91. Therefore, with performing the Xs-Zx axes synchronization control, the values of the distance F are same from the beginning to the end during the processing period.

The wafer inclination correction process including the wafer inclination calculation process and the Xs-Zx axes synchronization control is performed as described above. Accordingly, even if the device surface 91a is inclined, the inclination can be corrected and the distance F can be maintained constant during the processing period while the laser irradiation is ON. The wafer inclination correction process is performed ever time before performing the processing to increase the processing accuracy in the Zs-axis direction.

1.9 Description of Previous Calibration Process

In the wafer inclination correction process, the measurement points P1-P3 are defined on the device surface 91a and the inclination of the device surface 91a is calculated based on the measured coordinates of each of the measurement points P1-P3. Before performing the wafer inclination correction process, the previous calibration process may be performed with respect to the processing section 80 and the holding section 30.

In the previous calibration process, the bottom surface 33a of the chuck head 33 is uniquely specified and the Z-coordinates of the measurement points P1-P3 on the device surface 91a are presumed. By previously presuming the Z-coordinates of the measurement points P1-P3, the Z-coordinates can be measured in a short time in the wafer inclination correction process. The process will be specifically described below.

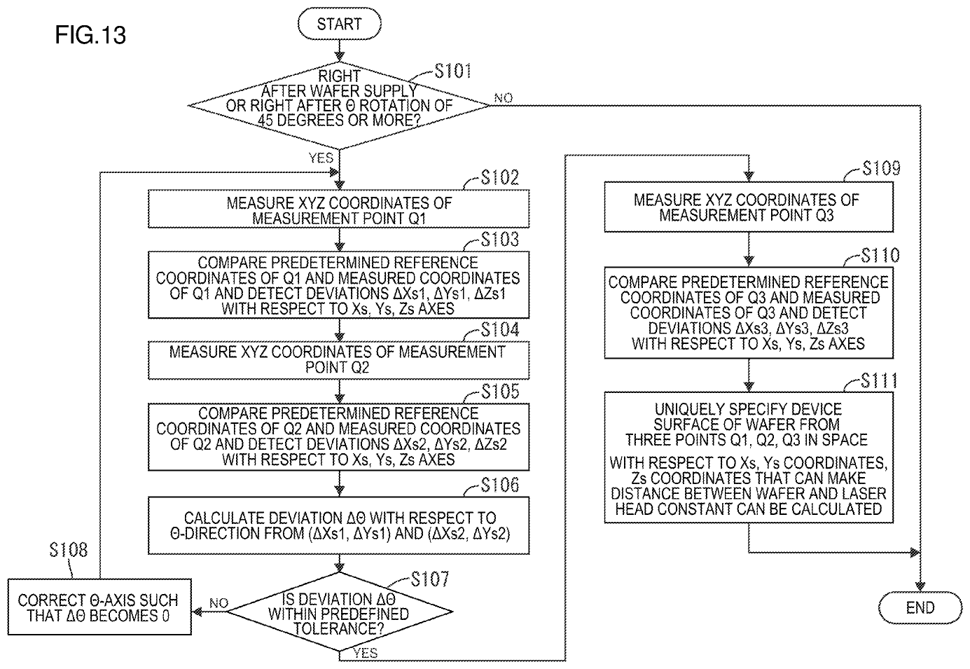

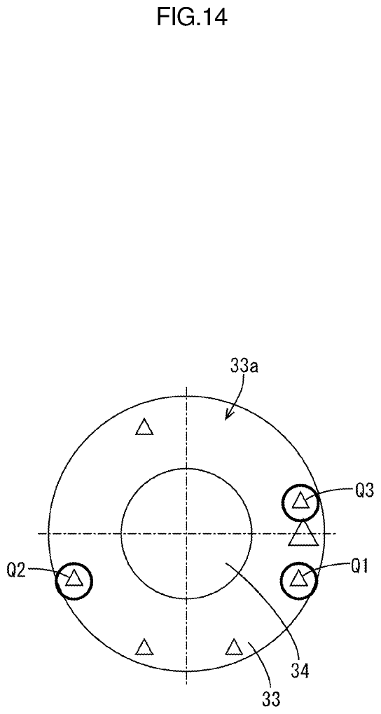

A flowchart is illustrated in FIG. 13 and is substantially same as the flowchart of the wafer inclination calculation process of the wafer inclination correction process (FIG. 9). As illustrated in FIG. 14, measurement points Q1-Q3 are previously defined on the bottom surface 33a. The controller 11 calculates a deviation Δθ with respect to the θ-direction based on the actually measured coordinates of the two measurement points (Q1, Q2) and corrects the θ such that the Δθ becomes 0 (START to S108).

Next, the controller 11 measures the coordinates of the measurement point Q3 and uniquely specifies the bottom surface 33a based on the three measurement points Q1-Q3 (S109 to end).

By uniquely specifying the bottom surface 33a, the Z-coordinate of any point having the X-coordinate and the Y-coordinate on the bottom surface 33a can be calculated. As illustrated in FIG. 3, the bottom surface 33a and the device surface 91a are very close to each other and only the dicing tape 93 is disposed therebetween. Therefore, by calculating the Z-coordinates on the bottom surface 33a, values close to the Z-coordinates of the measurement points P1-P3 on the device surface 91a can be obtained.

The previous calibration process may be performed before holding the workpiece 90 with the bottom surface 33a or may be performed after holding the workpiece 90 and before performing the wafer inclination correction process as is in this embodiment.

2. Description of Flow Operations

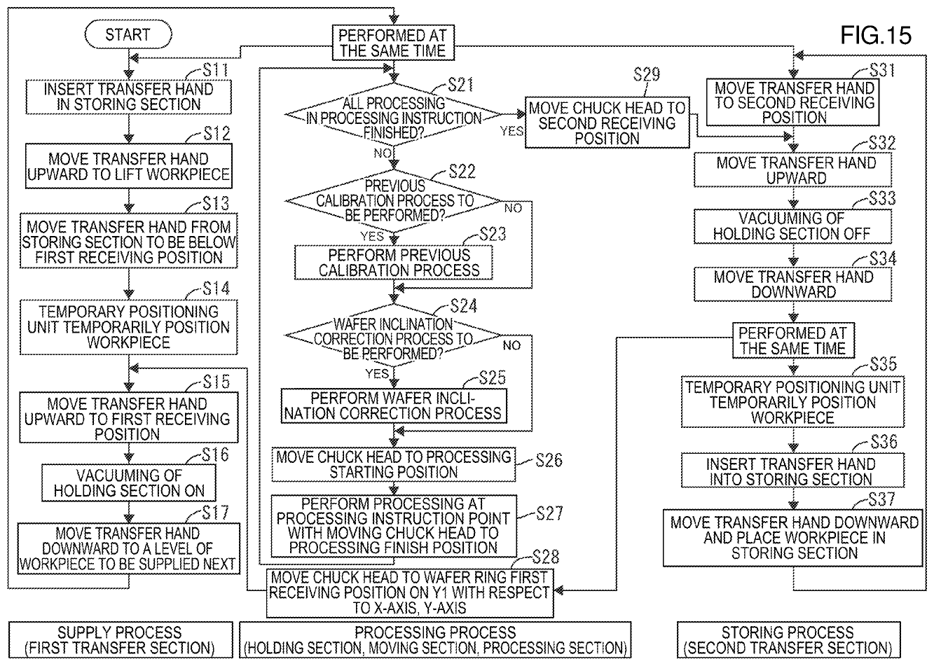

FIG. 15 is a flowchart for describing the processes performed by the whole processing device 10. Several processes are actually performed simultaneously in the processing device 10. In the following, a supply process (S11-S17) that is mainly performed in the first transfer section 110, a storing process (S31-S37) that is mainly performed in the second transfer section 120, and a whole process will be described. The whole process includes a processing process (S21-S29) in addition to the supply process and the storing process.

2.1 Description of Supply Process

In the supply process, the workpiece 90 that is stored in the first storing section 71 and is not yet processed is supplied to the chuck head 33 of the holding section 30 with using the first transfer hand 113 of the first transfer section 110. In the following, S11 to S17, which correspond to one cycle of the supply process will be described.

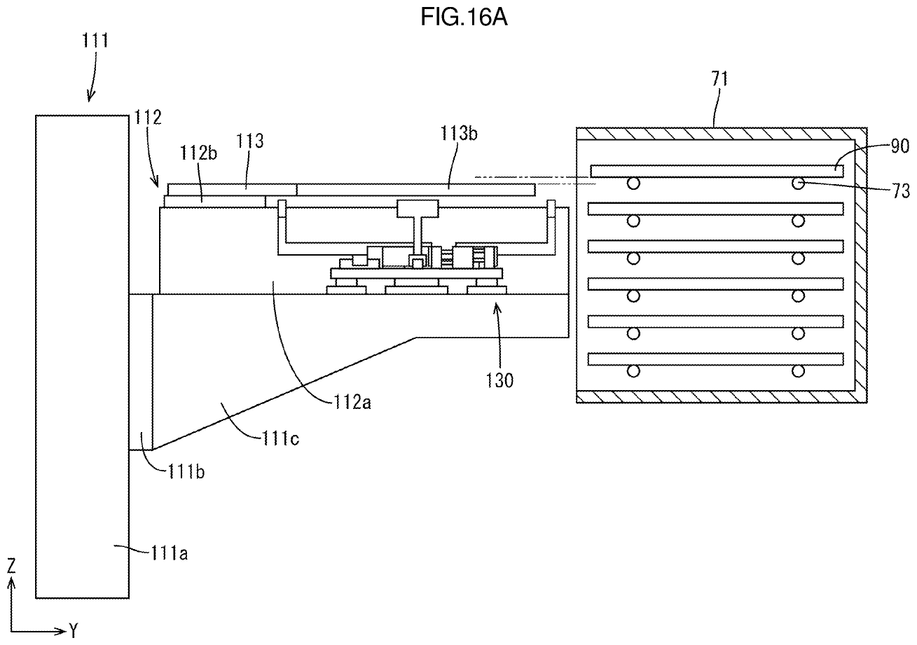

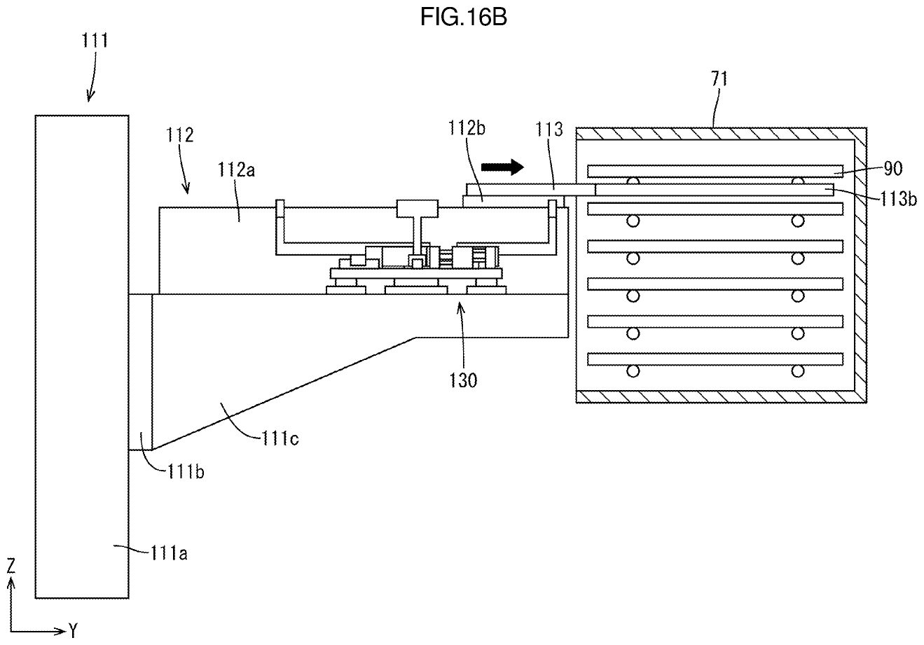

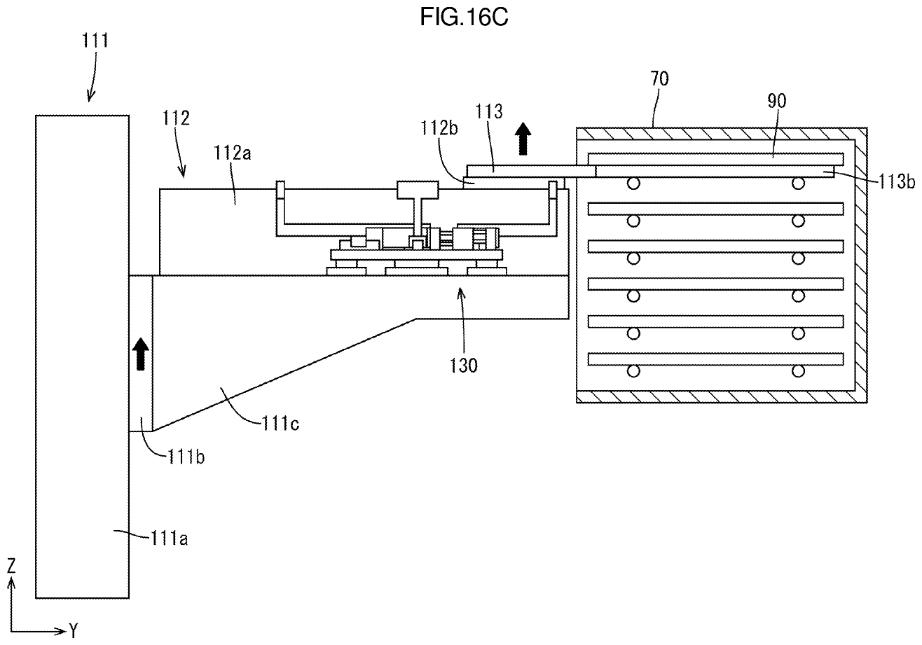

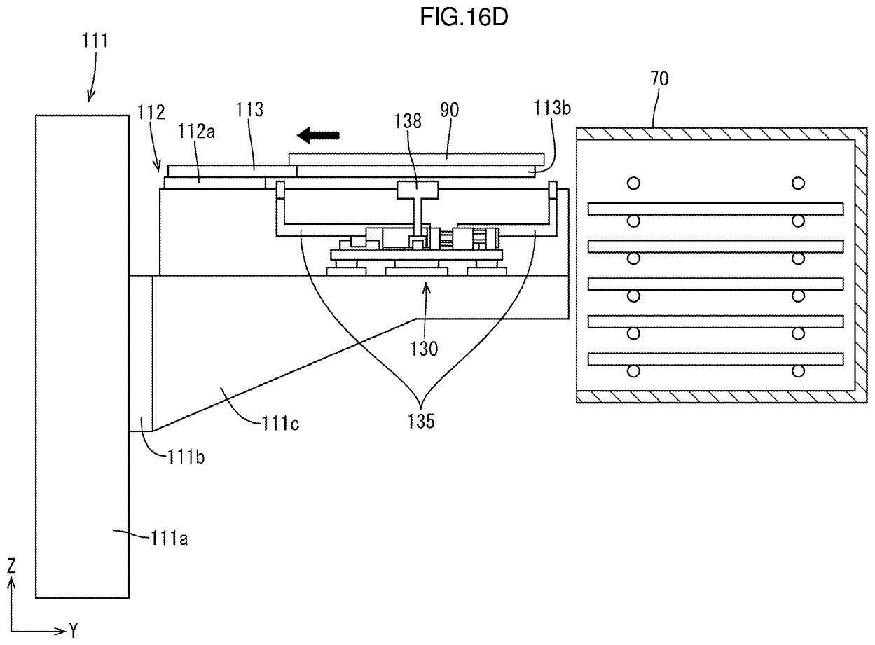

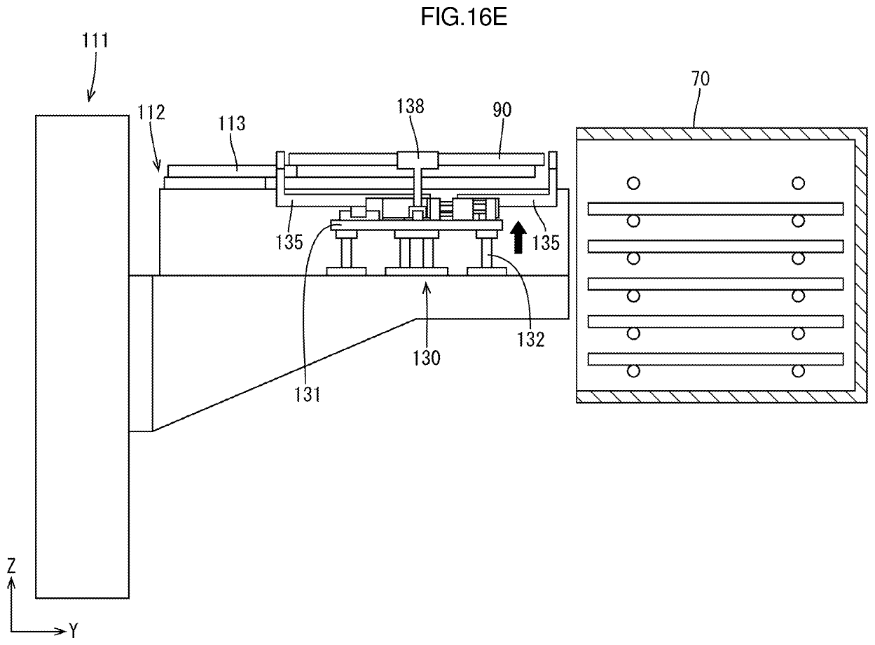

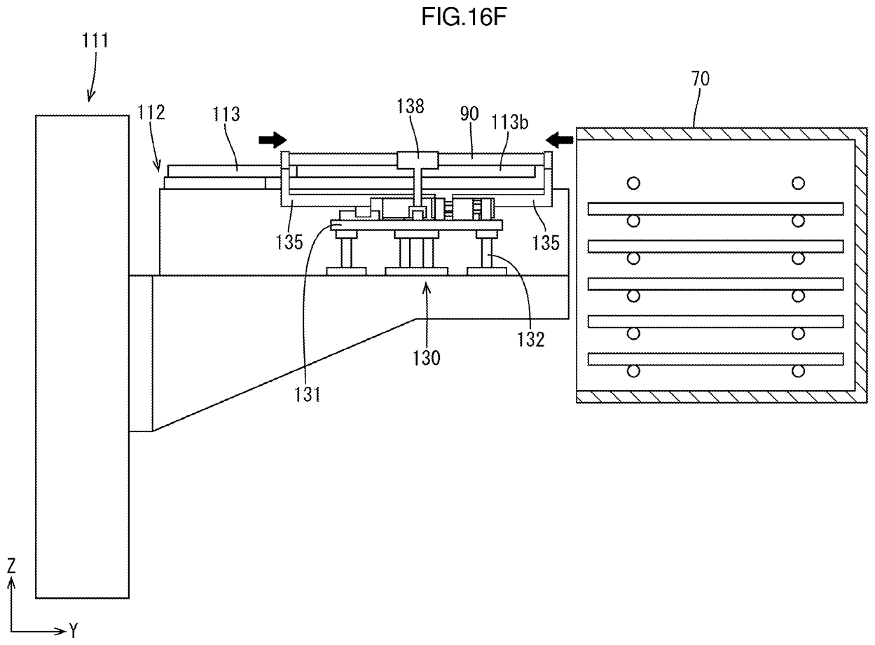

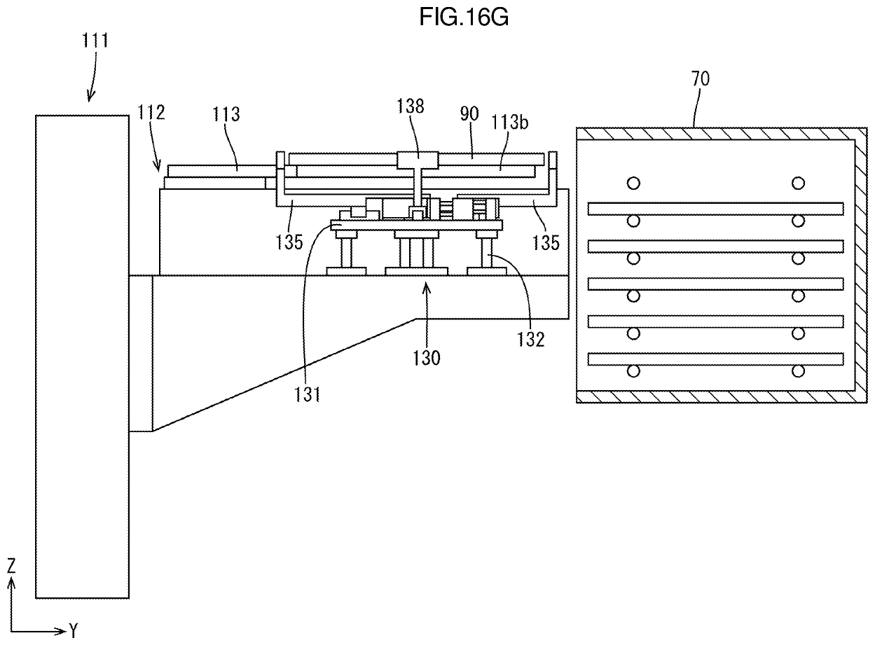

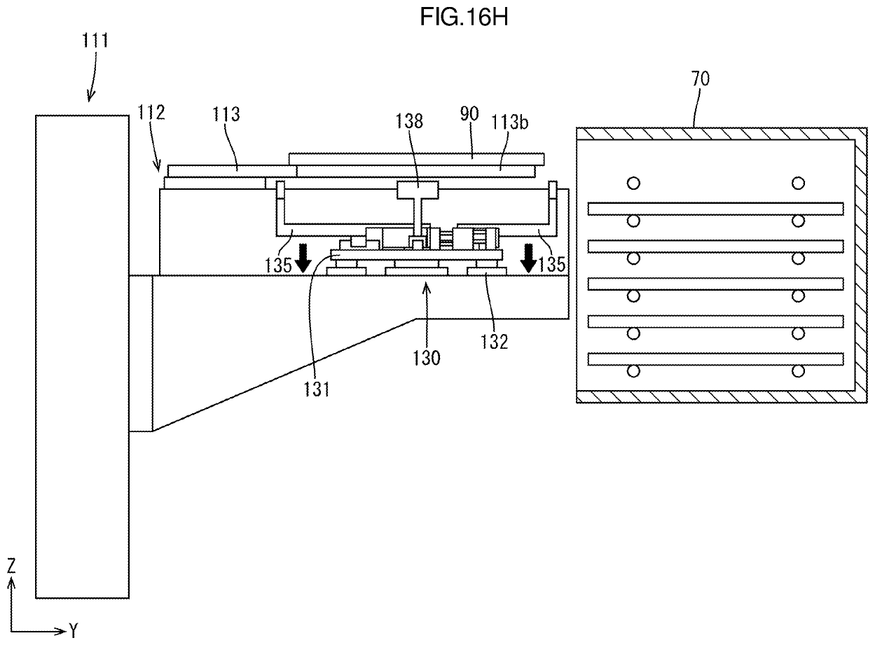

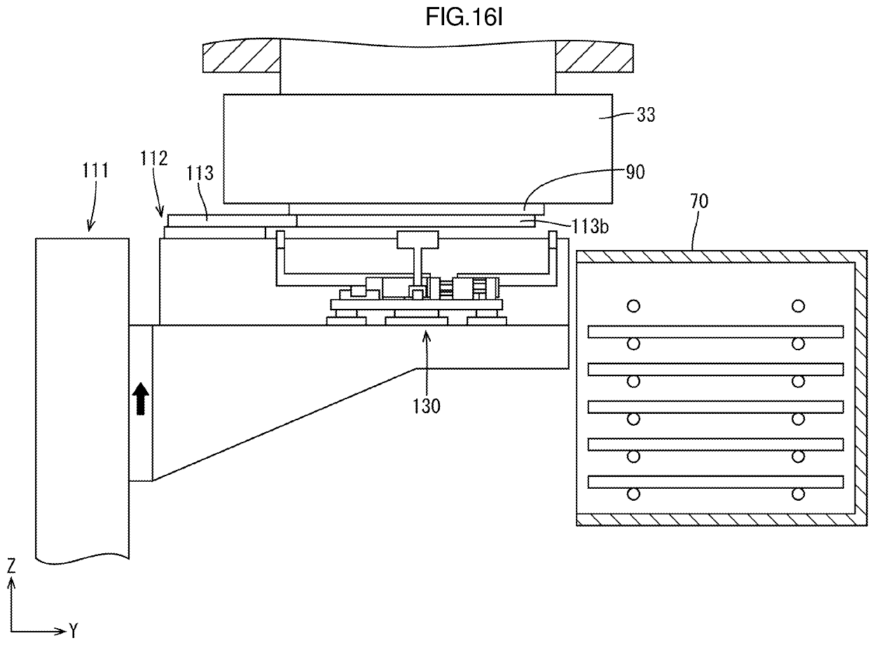

An initial state of the first transfer section 110 is illustrated in FIG. 16A. The workpieces 90 are arranged at intervals in the Z-direction in the inner space of the first storing section 71. The controller 11 controls the Z1-axis moving section 111 to move the first transfer hand 113 such that the height of the first transfer hand 113 is slightly lower than the bottom surface of the workpiece 90 that is to be supplied to the holding section 30.

The controller 11 controls the Y1-axis moving section 112 to insert the first transfer hand 113 into the first storing section 71 such that the distal end portion 113b of the first transfer hand 113 is not contacted with the workpiece 90 (FIG. 16B, S11).

The controller 11 moves the first transfer hand 113 upward. The workpiece 90 is lifted up by the distal end portion 113b and the workpiece 90 is placed on the upper surface of the distal end portion 113b (FIG. 16C, S12).

The controller 11 moves back the first transfer hand 113 from the first storing section 71 with keeping the workpiece 90 on the distal end portion 113b (FIG. 16D, S13). As illustrated in FIG. 6, the workpiece 90 is disposed at the position between the two vertical portions 135a2, 135b2 of the Y-sandwich section 133 and between the two vertical portions 138a2, 138b2 of the X-sandwich section 137 with a plan view.

The controller 11 controls the cylinder 132 to move the up-down stage 131 upward. The Y-sandwich section 133 and the X-sandwich section 137 also move upward together with the up-down stage 131 until the upper edges of the vertical portions of the Y-sandwich section 133 and the X-sandwich section 137 are upper than the workpiece 90 (FIG. 16E, S14).

Next, the Y-sandwich section 133 is operated. The Y-sandwich section 133 holds the side surfaces of the workpiece 90 from both sides to temporarily determine the position with respect to the Y-direction (FIG. 16F). Then, the similar operation is performed with the X-sandwich section 137 to determine the position with respect to the X-direction (FIG. 16G). Accordingly, the workpiece 90 is moved to the predefined position on the distal end portion 113b of the first transfer hand 113. The controller 11 controls the cylinder 132 to move the up-down stage 131 downward (FIG. 16H). Thus, the temporary positioning is finished.

Next, the controller 11 controls the Xs-axis moving section 61 and the Ys-axis moving section 51 to move the chuck head 33 to the predefined receiving position (a first receiving position) (S28). The first receiving position is directly above the distal end portion 113b. After the chuck head 33 arrives at the first receiving position, the first transfer hand 113 is moved upward to the first receiving position and vacuuming of the chuck head 33 becomes ON (S16). Accordingly, the chuck head 33 holds the workpiece 90 with sucking the upper surface of the workpiece 90 at the bottom surface 33a (FIG. 16I). The holding section 30 includes an air pressure sensor, which is not illustrated, for monitoring the air pressure in the suction cavity 35 to determine whether the holding with sucking is surely performed. Lowering of the air pressure detected by the air pressure sensor means the chuck head 33 holds the workpiece 90.

After confirming that the chuck head 33 holds the workpiece 90 with the lowering of the pressure detected by the air pressure sensor, the controller 11 moves the first transfer hand 113 having no workpiece downward to the level of the workpiece 90 that is to be supplied to the chuck head 33 next (S17) and inserts the first transfer hand 113 into the first storing section 71 (S11, FIG. 16B). The operations described above correspond to one cycle of the supply process performed by the first transfer section 110.

The second transfer section 120 that has the same configuration as that of the first transfer section 110 can perform the supply process.

2.2 Description of Storing Process

Next, the storing process will be described. In the storing process, the processed workpiece 90 held by the chuck head 33 is transferred to and stored in the second storing section 72 by the second transfer hand 123 of the second transfer section 120. In the following, S31 to S37 that correspond to one cycle of the storing process will be described.

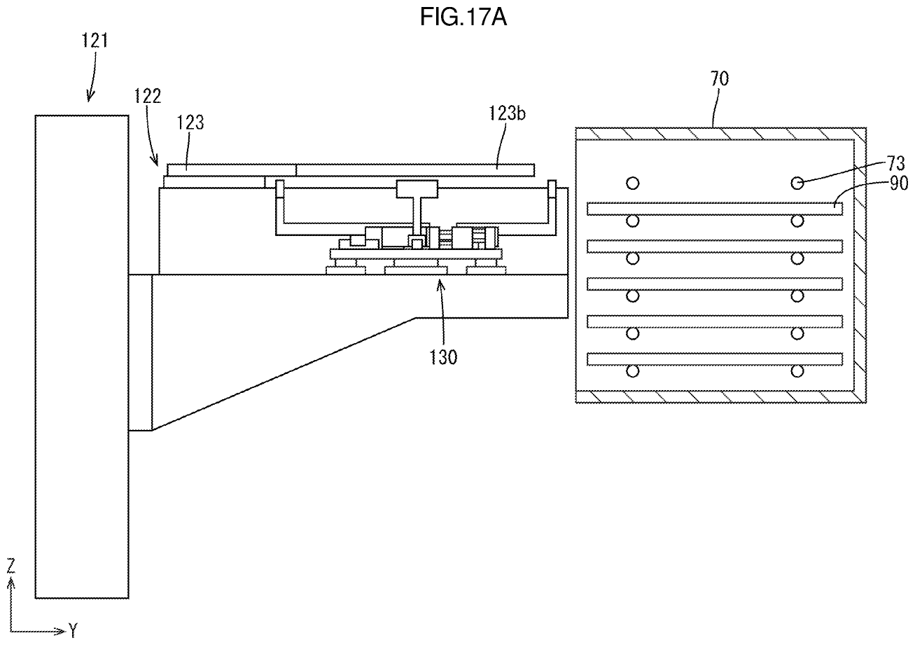

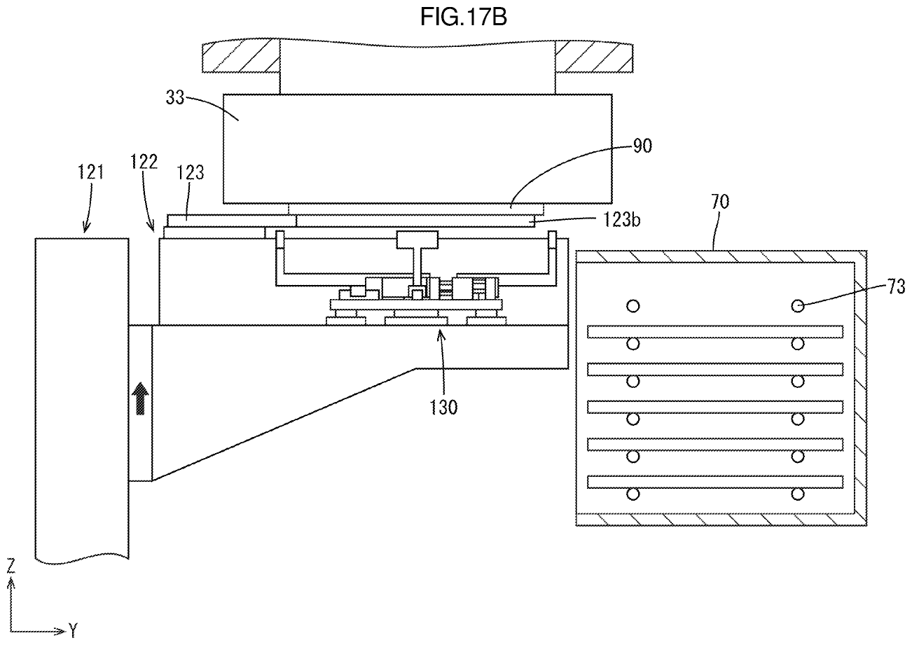

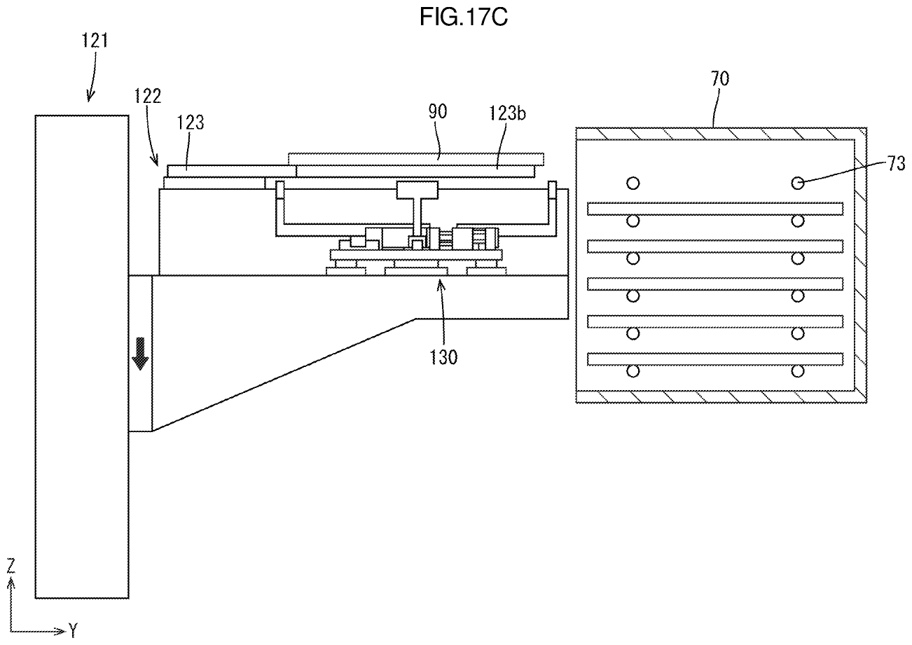

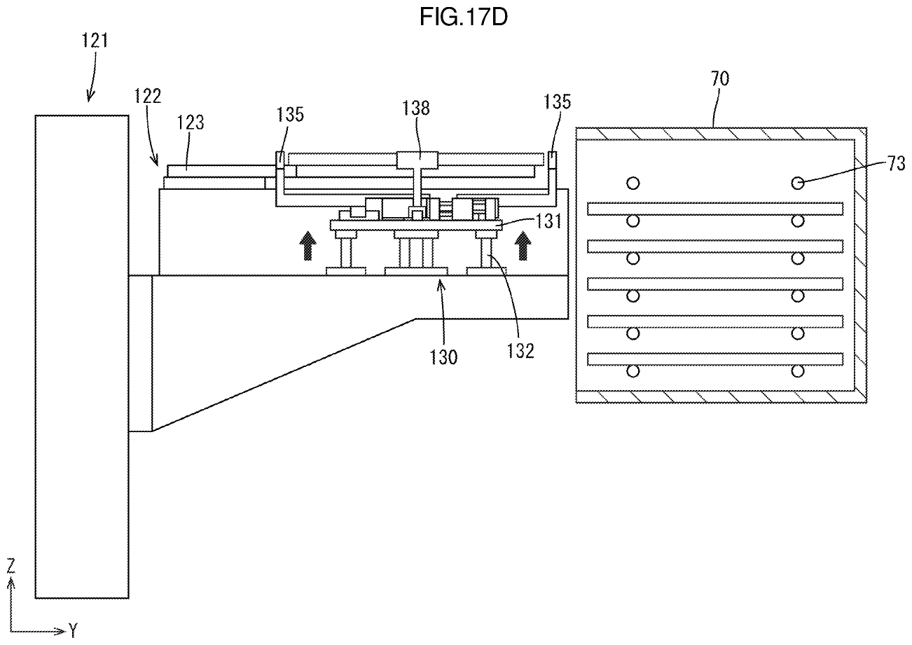

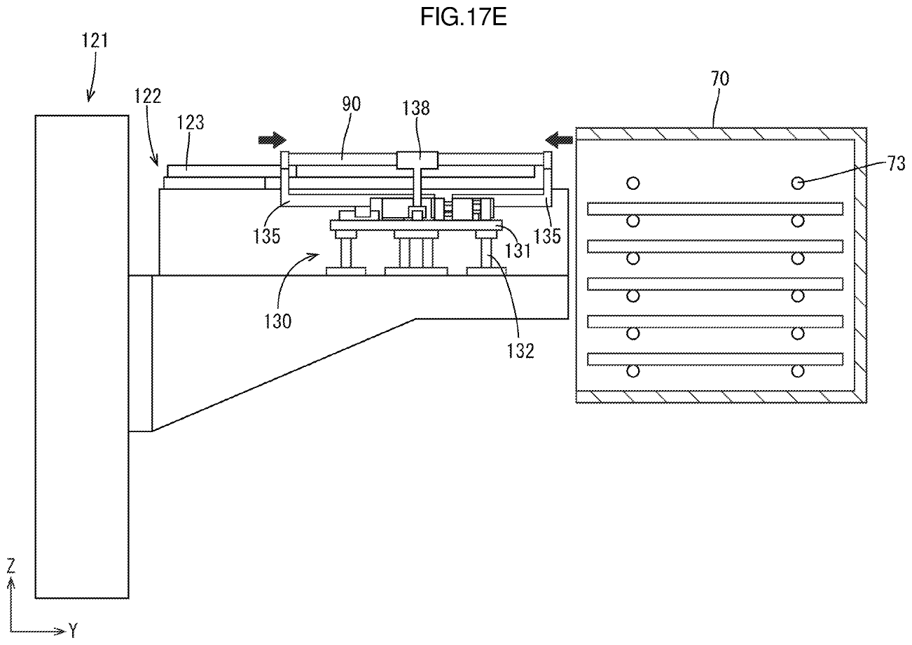

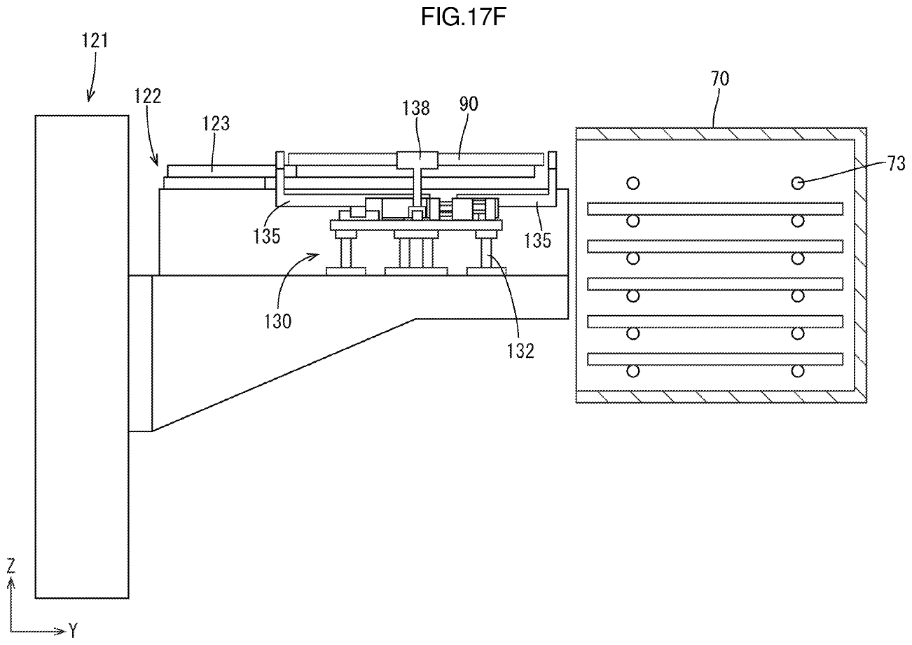

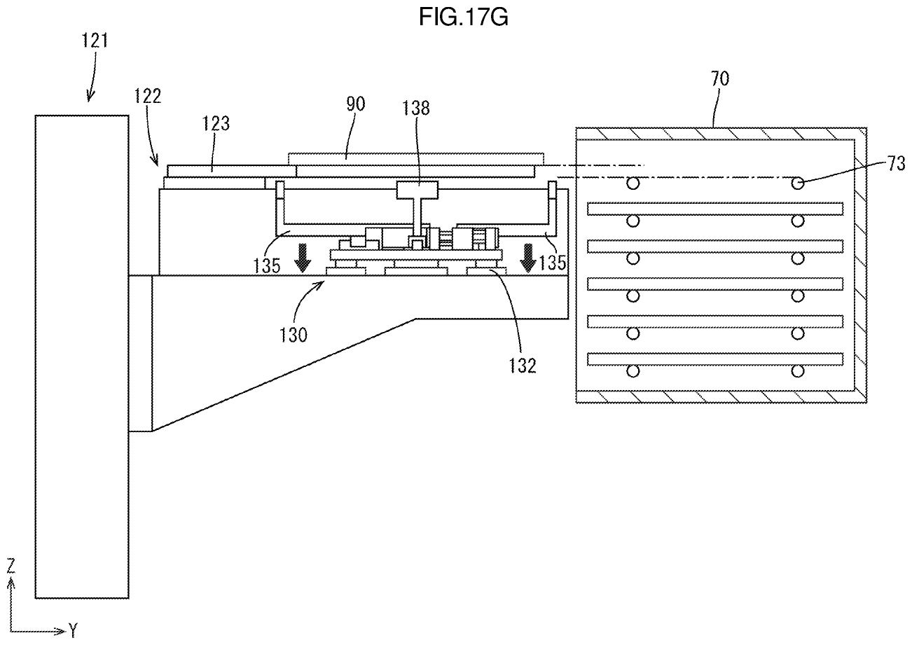

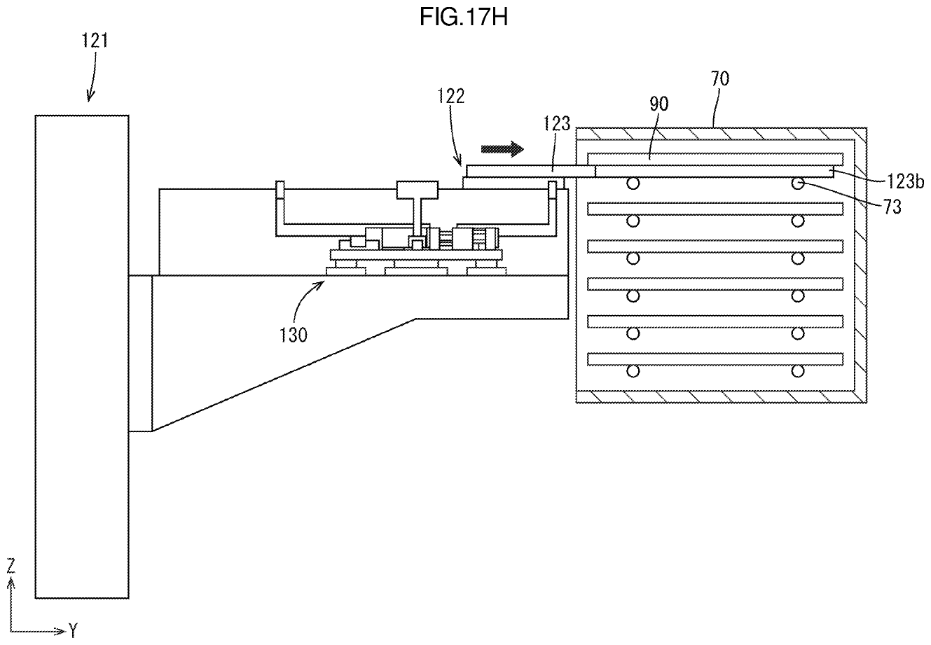

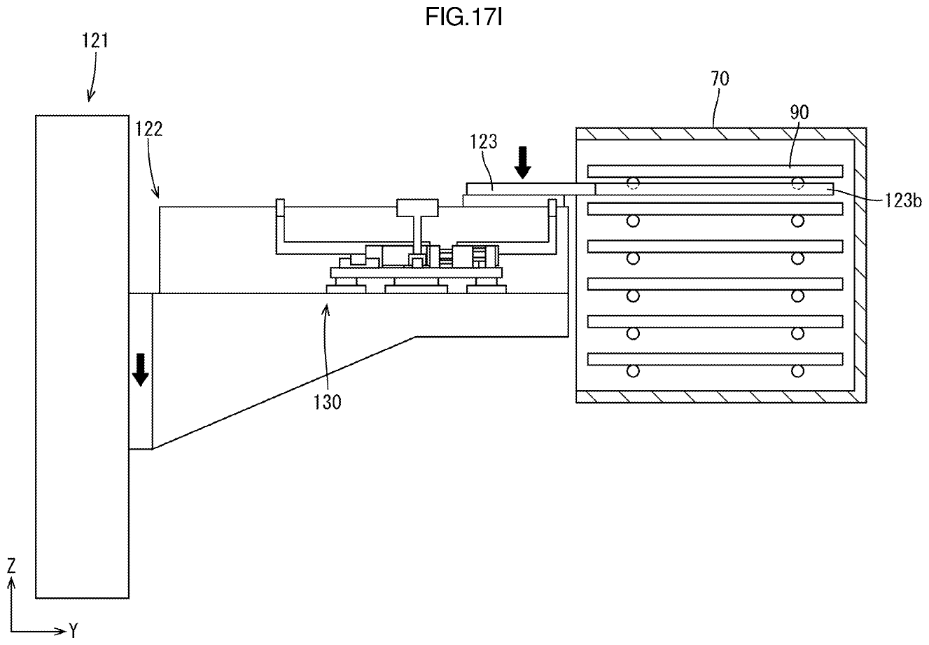

FIG. 17A illustrates an initial state of the second transfer section 120. Five processed workpieces 90 are stored in the inner space of the second transfer section 120. An uppermost storing space is free and the workpiece 90 is to be stored therein. The controller 11 controls the Z2-axis moving section 121 and the Y2-axis moving section 122 such that the second transfer hand 123 is disposed directly below a predefined receiving position (a second receiving position). The second transfer hand 123 is on standby at the position lower than the second receiving position so as not to be contacted with the chuck head 33 (FIG. 17A, S31).

Next, the controller 11 moves the chuck head 33 that holds the processed workpiece 90 to the second receiving position. After confirming that the chuck head 33 arrives at the second receiving position, the controller 11 moves the second transfer hand 123 upward to the second receiving position (FIG. 17B, S32) and controls vacuuming of the chuck head 33 to be OFF (S33). Then, the holding of the workpiece 90 is released and the workpiece 90 is placed on the second transfer hand 123.

After confirming that the air pressure of the suction cavity 35 detected by the air pressure sensor, which is not illustrated, becomes a normal pressure, the controller 11 moves downward the second transfer hand 123 on which the processed workpiece 90 is disposed and stops the second transfer hand 123 at the position slightly higher than the uppermost storing position (FIG. 17C, S34).

The chuck head 33 having no workpiece moves to the first receiving position and receives the workpiece 90 from the first transfer hand 113.

Next, the controller 11 moves the temporary positioning unit 130 included in the second transfer section 120 to temporarily position the workpiece 90 on the distal end portion 123b of the second transfer hand 123 (FIGS. 17D-17G, S35). With positioning the workpiece 90 before being stored in the second storing section 72, the workpiece 90, which is being moved to be stored, is less likely to be contacted with the wall surface of the second storing section 72 and less likely to drop and the processed semiconductor wafer 91 is less likely to be broken. Details of the process of the temporary positioning is similar to the process of the supplying operation described above and will not be described.

The controller 11 moves and inserts the second transfer hand 123 into the second storing section 72 (FIG. 17H, S36). Subsequently, the second transfer hand 123 is moved downward and places the workpiece 90 on the projections 73 in the second storing section 72 (FIG. 17I, S37) and the second transfer hand 123 is moved out therefrom. Then, the controller 11 moves the second transfer hand 123 to the second receiving position (S31) to be on standby. The operations described above correspond to one cycle of the storing process.

The first transfer section 110 can perform the supply process since the first transfer section 110 has the same configuration as that of the second transfer section 120.

2.3 Description of Whole Process

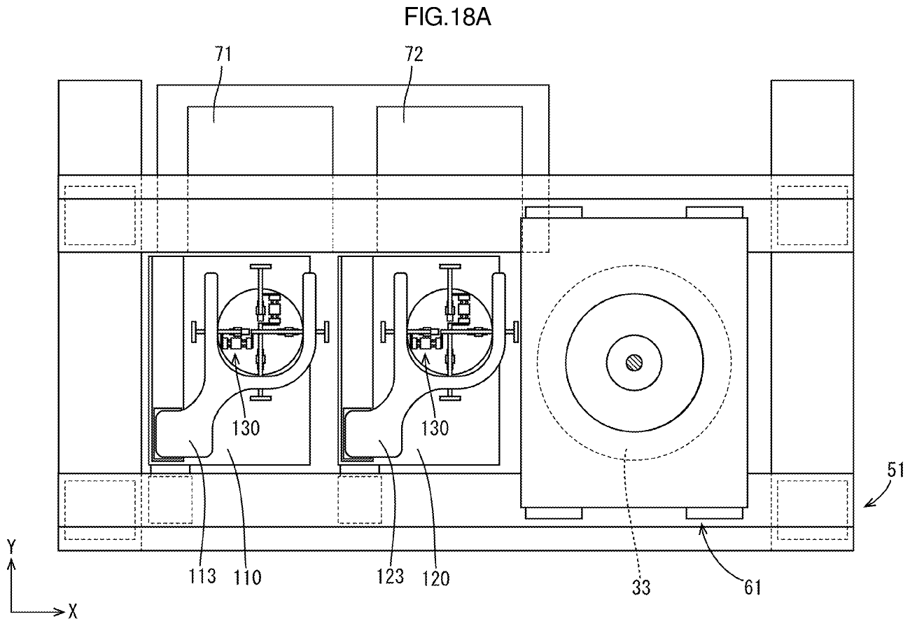

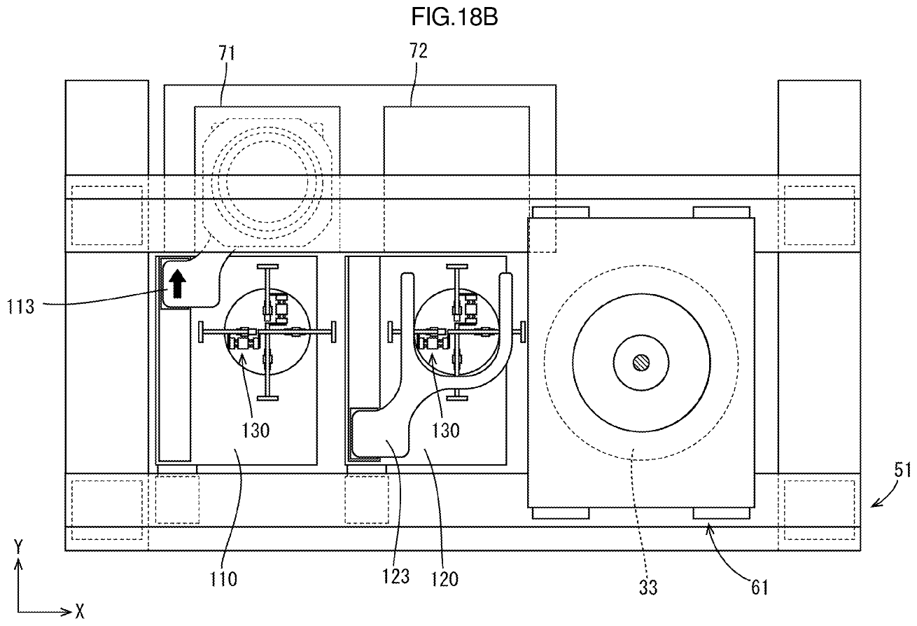

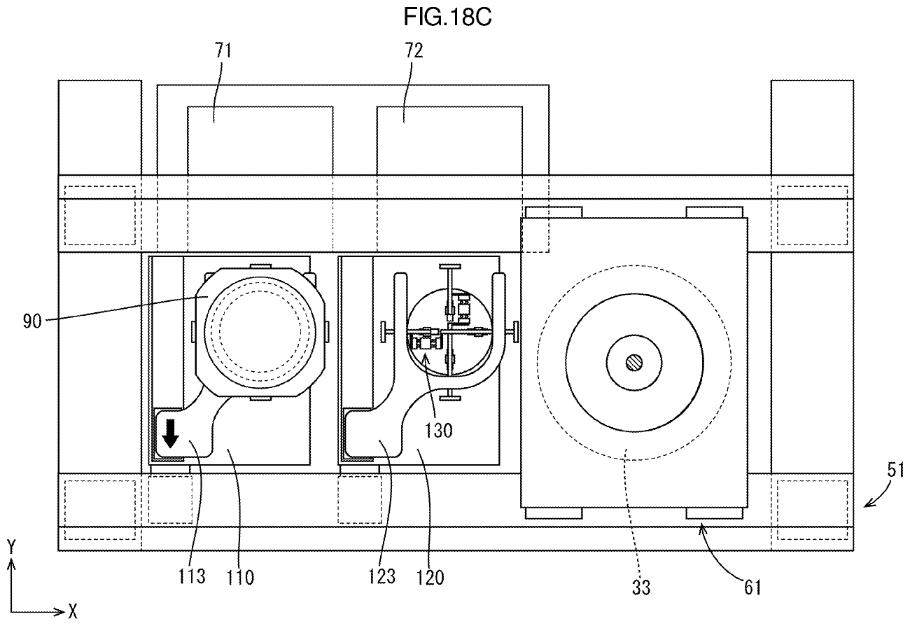

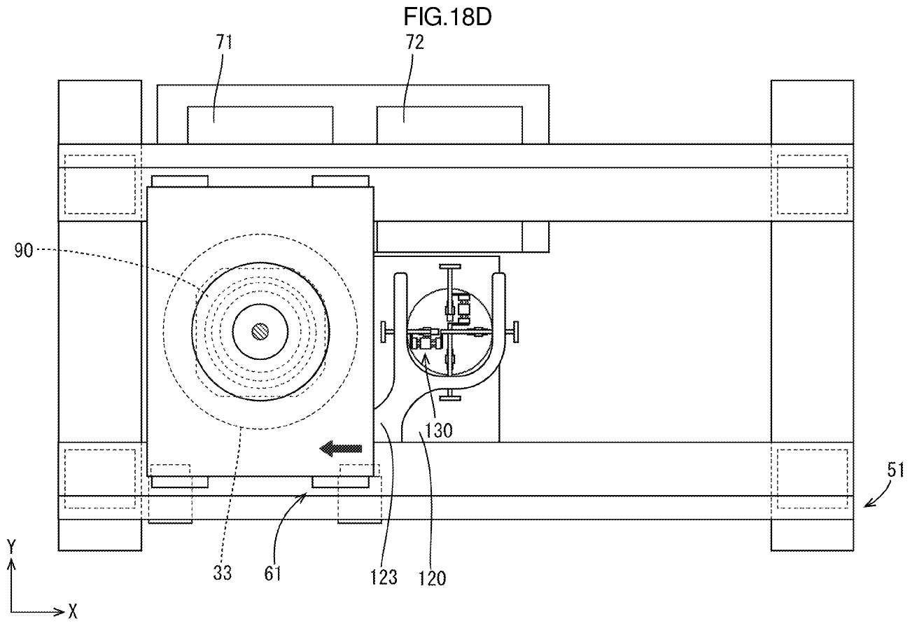

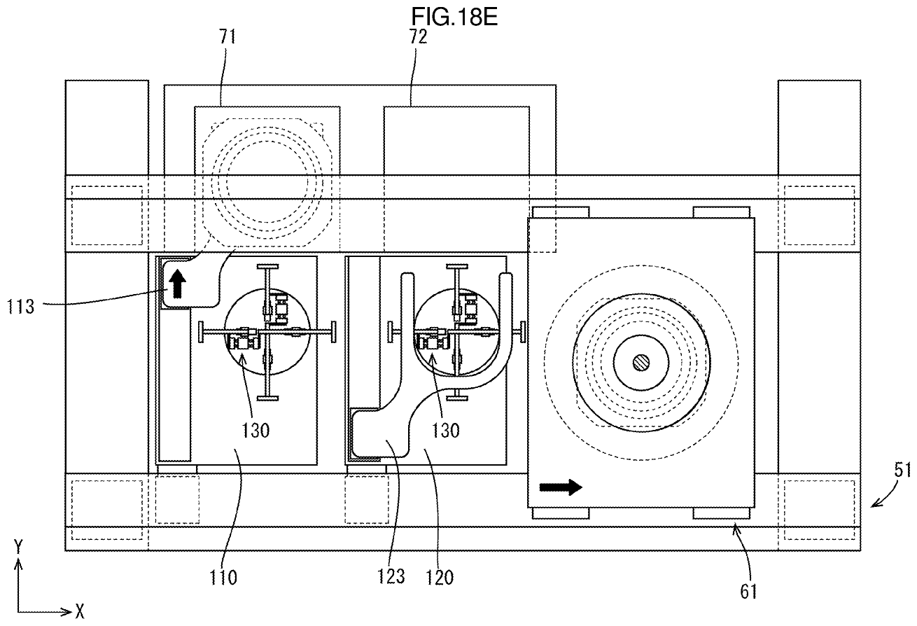

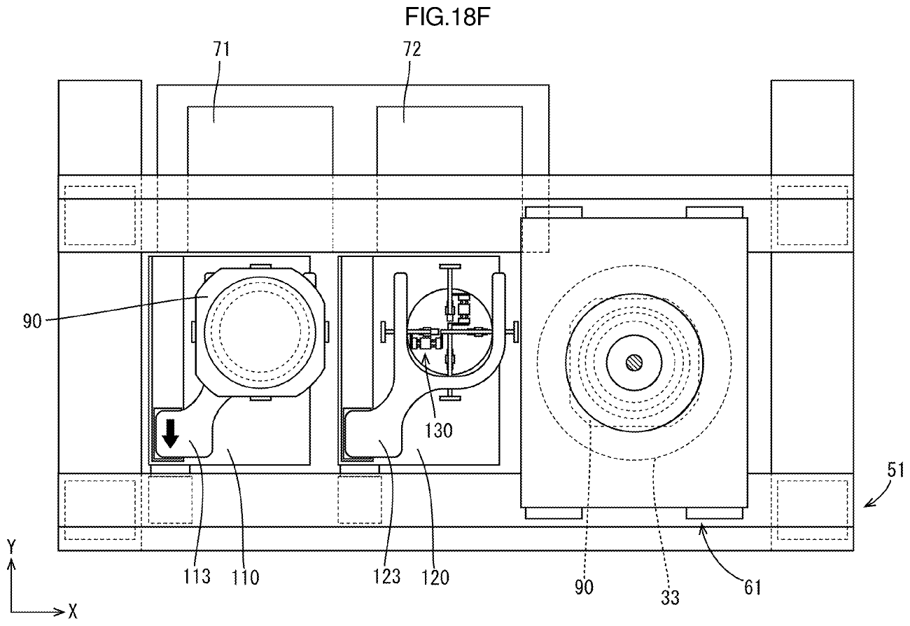

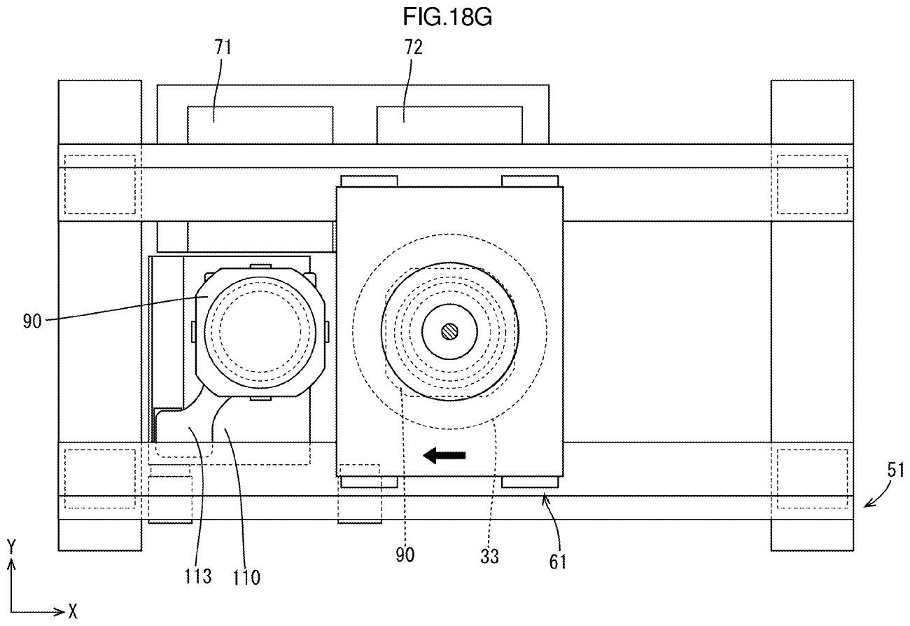

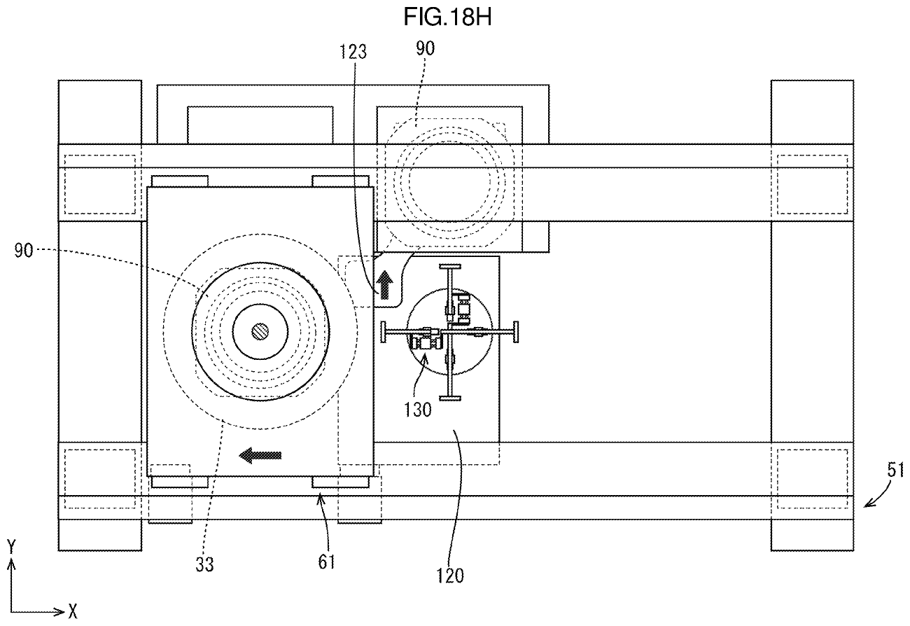

Next, the process performed by the whole processing device 10 that includes the processing process in addition to the supply process and the storing process, which are described above, will be described with reference to FIGS. 18A to 18H. In the processing process, a laser processing is performed by the processing section 80.

In an initial state illustrated in FIG. 18A, the first transfer section 110 and the second transfer section 120 are in the same state as the initial state of the supply process and the storing process (FIGS. 16A, 17A). The chuck head 33 is disposed directly above the laser oscillator 85 (referred to as a processing position) as illustrated in the FIG. 1B; however, the chuck head 33 does not hold any workpiece 90.

With starting the whole process (START), the controller 11 performs the supply process described above. Specifically, the first transfer hand 113 is inserted in the first storing section 71 and moved out therefrom with the workpiece 90 that are not processed (S11-S14, FIGS. 18B, 18C). Subsequently, the chuck head 33 is moved to the first receiving position (S28) and holds the workpiece 90 that is disposed on the first transfer hand 113 (S15-S17, FIG. 18D).

After the chuck head 33 holding the workpiece 90, it is determined whether all the processing included in the processing instructions that are to be performed to the workpiece 90 held by the chuck head 33 is completed. The processing is normally performed several times for one workpiece 90 and the controller 11 makes the determination with reference to the processing instructions and the history data that includes data related to the processed performances (S21).

If the processing of the held workpiece 90 is not completed (S21: NO), the controller 11 determines whether or not to perform the previous calibration process with reference to the processing instructions (S22). The controller 11 performs the previous calibration process if necessary (S23). Furthermore, the controller 11 determines whether or not to perform the wafer inclination correction process and performs the wafer inclination correction process if necessary (S24, S25 FIG. 18E). Accordingly, the XYZO positions of the chuck head 33 are adjusted.

Next, the controller 11 moves the chuck head 33 to the processing starting position (S26). Then, the controller 11 controls the Xs-axis moving section 61 and the Zs-axis moving section 81 (refer to FIG. 3) to move the chuck head 33 and the laser oscillator 85 to the position where the processing is finished with irradiating a laser from the laser head 85a to the semiconductor wafer 91. Thus, the processing is performed (S27, FIG. 18F).

If the processing is finished, the process returns to S21 and the controller 11 determines again whether all the processing included in the processing instructions are finished. Thus, S21 to S27 will be performed repeatedly until the processing included in the processing instructions are finished.

While the holding section 30 and the processing section 80 are performing the processes from the calibration to the processing (S21 to S27) repeatedly, the first transfer section 110 performs some of the steps of the supply process (S11 to S14) and the workpiece 90 that is to be processed next is prepared on the first transfer hand 113 (FIG. 18F) in parallel with the operations of the steps S21 to S27.

If the controller 11 determines that all the processing included in the processing instructions are finished (S21: YES), the controller 11 moves the chuck head 33 to the second receiving position (S29) and transfers the workpiece 90 to the second transfer hand 123 (S32 to S33, FIG. 18G). Then, the storing process is performed with the second transfer section 120 and the workpiece 90 that is held by the chuck head 33 is stored in the second storing section 72 (S34 to S37, FIG. 18H).

The controller 11 controls the chuck head 33 to receive the workpiece 90 that is to be processed next in parallel with the storing process performed with the second transfer section 120. Specifically, after the chuck head 33 transfers the processed workpiece 90 to the second transfer hand 123 and has no workpiece (S33 to S34), the chuck head 33 moves to the first receiving position (S28) and receives the workpiece 90 that is prepared on the first transfer hand 113 (S15 to S17). Then, the controller 11 determines whether all the processing included in the processing instructions are finished for the workpiece 90 (S21).

The whole process is thus performed and the whole process including the supply process and the storing process is performed repeatedly until the processing of all the workpieces 90 stored in the first storing section 71 is finished and the processed workpieces 90 are stored in the second stored section 72.

### 3. Description of Effects

Effects of the processing device 10 according to this embodiment will be described below.

According to the processing device 10 having such a configuration, with the holding section 30 holding the workpiece 90 disposed on the first transfer hand 113 from above, the holding section 30 can directly receive the workpiece 90. The holding section 30 holding the workpiece 90 below can directly place the workpiece 90 on the second transfer hand 123.

Accordingly, a space (a temporary space) in which the workpiece 90 is temporarily placed is not necessary between the first transfer hand 113, 123 and the holding section 30. This downsizes the processing device 10 and an installation space for the processing device 10 can be reduced.

The direct transferring without using the temporary space can reduce the number of times the workpieces 90 stored in the storing section 70 are transferred. Specifically, in the transferring via the temporary space, the workpiece is transferred from the storing section to the holding section via the transfer hand and the temporary space in this order. Therefore, the number of transfer times is four. On the other hand, in this embodiment, the workpiece is transferred from the storing section 70 to the holding section 30 via the first transfer hand 113. Therefore, the number of transfer times is two. This shortens the time required for the transferring and the processing of the workpiece 90 stored in the storing section 70 can be started in a short time. Furthermore, the processed workpiece 90 can be stored in the storing section 70 in a short time. This increases productivity of the processing device 10.

In the transferring, an impact may be applied to the workpiece 90 or the workpiece 90 may be contacted with other components and damaged. In this embodiment, the number of transfer times can be reduced and therefore, the workpiece 90 has less opportunity to receive an impact and is less likely to be damaged and the yield is less likely to decrease.

The processing section 80 processes the workpiece 90, which is held from above by the holding section 30, from a lower side. Dust caused by the processing drops down and is less likely to adhere to the workpiece 90. Accordingly, the workpiece 90 can be kept clean and contamination is less likely to occur and the yield is less likely to decrease.

The processing device 10 includes the sandwich section (the Y-sandwich section 133, the X-sandwich section 137). The sandwich sections 133, 137 hold the side surfaces of the workpiece 90, which is disposed on the transfer hand (the first transfer hand 113, the second transfer hand 123), from the outer side and temporarily positions the workpiece 90 on the transfer hand.

The temporary positioning is performed for holding the workpiece 90 at the predefined position of the holding section 30 and storing the workpiece 90 at the predefined position of the storing section 70. By performing the temporary positioning, the laser irradiation position can be moved to the processing starting position in a short time. The workpiece 90 is less likely to drop due to position displacement when the workpiece 90 is stored in the storing section 70 and the storing can be performed smoothly.

Furthermore, the temporary positioning can be performed with the workpiece 90 being disposed on the first transfer hand 113. Therefore, another space for the temporary positioning (a temporary positioning table) is not necessary and a space for the processing device 10 can be reduced.

Since the workpiece need not be disposed on the temporary positioning table, the number of transfer time of the workpiece 90 can be decreased. This shortens the takt time and productivity can be increased. The workpiece 90 is less likely to be damaged during the transferring and the yield is less likely to decrease.

The moving section 50 includes the Xs-axis moving section 61 (the first moving section) and the Ys-axis moving section 51 (the second moving section). The Xs-axis moving section 61 is configured to move the holding section 30 in the X-direction (the first direction) that is perpendicular to the upper-bottom direction. The Ys-axis moving section 51 is configured to move the holding section 30 in the Y-direction (the second direction) that is perpendicular to the upper-bottom direction and the X-direction. The X-direction corresponds to the processing direction in which the workpiece 90 is processed and the Y-direction corresponds to the interval feeding direction of the workpiece 90. The position (the receiving position) where the holding section 30 receives and places the workpiece 90 from and on the transfer hand (the first transfer hand 113 or the second transfer hand 123) and the position (the processing position) of the holding section 30 when the processing section 80 processes the workpiece 90 are arranged in the X-direction.

The distance that the holding section 30 moves in the X-direction between the receiving position and the processing position is greater than the distance that the holding section 30 moves in the Y-direction, which is the interval feeding direction. The processing direction in which the workpiece 90 is processed and the direction in which the holding section 30 moves between the receiving position and the processing position are the X-direction.

In such a configuration, it is particularly effective to increase the speed of the holding section 30 that moves a greater distance in the X-direction to shorten the time required for the movement of the holding section 30 and increase the productivity. Furthermore, high straightness is demanded for the X-direction movement to perform the processing linearly along the processing line 95. On the other hand, in the movement in the Y-direction, which is the interval feeding direction, higher positioning accuracy is demanded than the movement in the X-direction to process the workpiece 90 at higher accuracy.

Namely, the Xs-axis moving section 61 that moves a great distance in the X-direction or the processing direction can be designed with focusing on the moving speed and the straightness. On the other hand, the Ys-axis moving section 51 that moves in the interval feeding direction is designed with more focusing on the positioning accuracy than the moving speed and the straightness. The Xs-axis moving section 61 and the Ys-axis moving section 51 can be reasonably designed according to the respective performances and a cost for the processing device 10 can be reduced.

The workpiece 90 is transferred by the transfer hand (the first transfer hand 113 and the second transfer hand 123) from and to the storing section 70 in the Y-direction. The storing section 70 is disposed below the moving section 50 so as to partially overlap the movable area in which the moving section 50 can move with a plan view.

As previously described, the receiving position and the processing position are arranged in the X-direction and the distance that the holding section 30 moves between the receiving position and the processing position is greater than the distance that the holding section 30 moves in the Y-direction (the interval feeding direction). Therefore, the shape of the processing device 10 excluding the storing section base 69 is elongated in the X-direction.

If the workpiece 90 is transferred from and to the storing section 70 in the X-direction, the storing section base 69 and the receiving position may be arranged in the X-direction and this further increases the size of the processing device 10 including the storing section base 69. On the other hand, with the transferring direction of the workpiece 90 being the Y-direction, the storing section base 69 and the receiving position are arranged in the Y-direction. Therefore, the length of the processing device 10 in the X-direction is not increased.

The storing section and the storing section base 69 overlap the movable area of the moving section 50 with a plan view. This suppresses the processing device 10 from increasing its size in the second direction. Accordingly, the space for the processing device 10 can be reduced.

The Xs-axis moving section 61 (the first moving section) includes a pair of (two) Xs-axis ball screws 62 (the first guide portion) that extend in the first direction (X-direction) parallel to each other and are arranged in the second direction (Y-direction). The Xs-axis ball screws 62 support the holding section 30 via the Xs-axis slider 63 and the XY-stage 64 so as to be movable in the X-direction.

With the holding section 30 being supported by the pair of (two) Xs-axis ball screws 62, the holding section 30 can be firmly supported and rattling and vibration can be suppressed. Accordingly, the workpiece 90 held by the holding section 30 is less likely to drop and the holding section 30 can move fast in the X-direction.

The Ys-axis moving section 51 includes a pair of (two) Ys-axis ball screws 52 that extend in the Y-direction parallel to each other and are arranged in the X-direction. The Ys-axis ball screws 52 support the Xs-axis moving section 61 so as to be movable in the Y-direction.

According to such a configuration, with the Xs-axis moving section 61 being supported by the pair of (two) Ys-axis ball screws 52, the Xs-axis moving section 61 can be firmly supported and rattling and vibration can be suppressed. Accordingly, the posture of the holding section 30 can be stable in the movement in the Y-direction or the interval feeding direction. The interval feeding can be performed precisely.

The storing section 70 includes the first storing section 71 that stores the workpieces 90 that are not processed and the second storing section 72 that stores the workpieces that are processed. The transfer hand includes the first transfer hand 113 that transfers the workpiece 90 from the first storing section 71 to the holding section 30 and the second transfer hand 123 that receives the workpiece 90 from the holding section 30 and transfers it to the second storing section 72.

According to such a configuration, the supply process is performed by the first transfer hand 113 and the storing process is performed by the second transfer hand 123. Therefore, after the processed workpiece 90 is transferred from the holding section 30 to the second transfer hand 123, the holding section 30 can receive the workpiece 90 that is not processed from the first transfer hand 113 while the second transfer hand 123 storing the workpiece 90 into the second storing section 72.

Accordingly, the storing process performed by the second transfer hand 123 and the supply process performed by the first transfer hand 113 can be performed at the same time and the takt time of the processing device 10 can be shortened and the productivity is increased.

The workpiece 90 includes the three plate surface measurement points P1-P3 on the device surface 91a (the plate surface). The processing section 80 includes the camera 86 and the Zx-axis moving section 81. The camera 86 takes images of the plate surface measurement points P1-P3 and measures the coordinates of the plate surface measurement points P1-P3. The Zs-axis moving section 81 is configured to move the processing section 80 in the upper-bottom direction. The controller 11 is configured to specify the plate surface before the processing based on the coordinates of the plate surface measurement points P1-P3. The controller 11 controls the processing section 80 to perform the processing with controlling the Zs-axis moving section 81 to move the processing section 80 such that a constant distance is kept between a certain point on the plate surface and the processing section 80.

Accordingly, the semiconductor wafer 91 can be processed with laser irradiation with keeping a constant distance F1 between the device surface 91a and the laser head 85a of the processing section 80. This increases the processing accuracy. Accordingly, the yield of the semiconductor chip 94 can be increased.

The holding section 30 includes the three bottom surface measurement points Q1-Q3 on the bottom surface 33a of the chuck head 33 that holds the workpiece 90. The processing section 80 includes the camera 86 that takes images of the bottom surface measurement points Q1-Q3 and measures the coordinates of the bottom surface measurement points Q1-Q3. The controller 11 is configured to specify the bottom surface 33a based on the coordinates of the bottom surface measurement points Q1-Q3. The controller 11 calculates the distance F2 between a certain point and the processing section 80.

The calculated distance F2 between a certain point on the bottom surface 33a and the processing section 80 (the laser head 85a) is close to the distance between workpiece 90 and the processing section 80. Therefore, with the calculated distance F2 being used as an initial value of the distance between the workpiece 90 and the processing section 80 in the processing, the distance between the workpiece 90 and the processing section 80 can be measured in a short time.

### Second Embodiment

The processing device 10 according to the first embodiment includes two storing sections that are arranged in the X-direction. The two storing sections include the first storing section 71 storing the workpieces 90 that are not processed and the second storing section 72 storing the workpieces 90 that are processed. Furthermore, the processing device 10 includes two transfer sections (the first transfer section 110, the second transfer section 120) that correspond to the storing sections 71, 72, respectively. The first transfer section 110 only performs the supply process and the second transfer section 120 only performs the storing process.

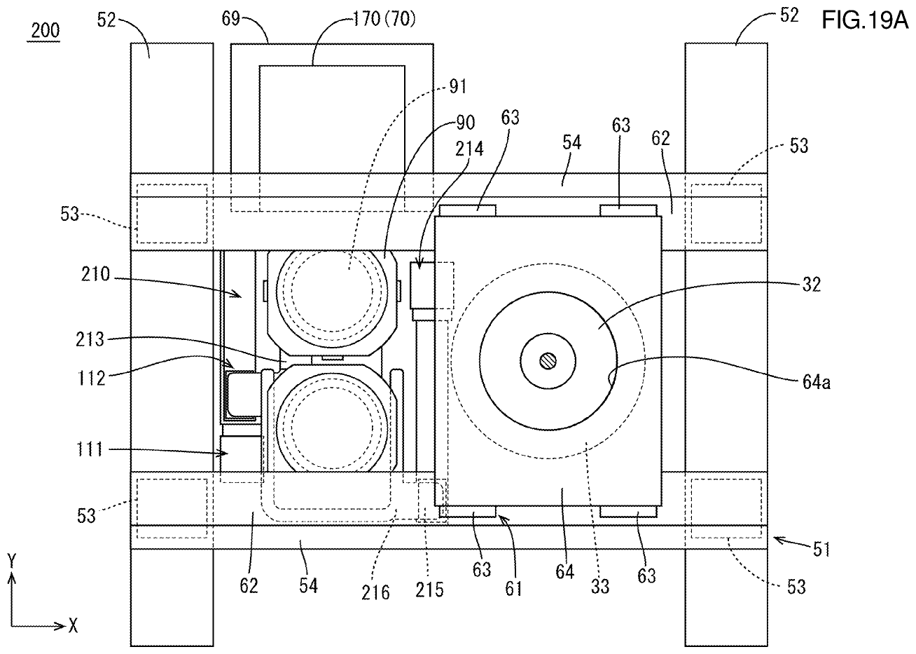

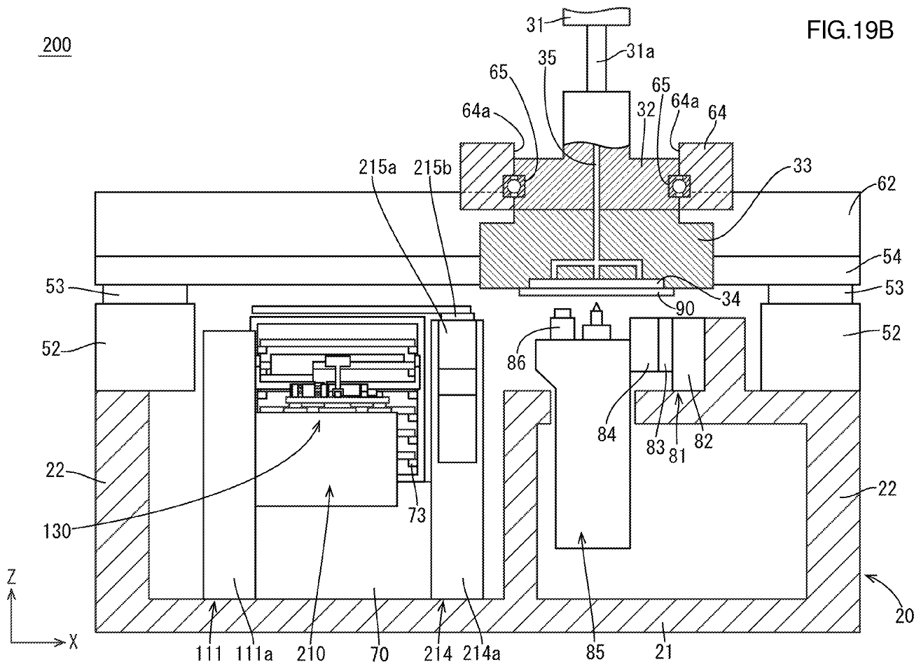

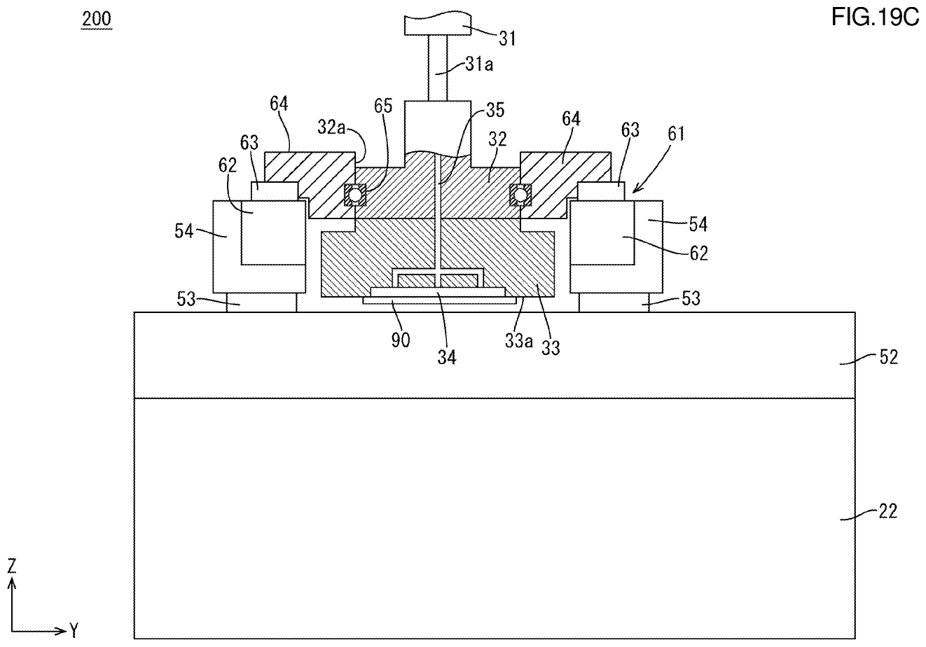

As illustrated in FIG. 19A, a processing device 200 according to a second embodiment includes one storing section 170 and one transfer section (a third transfer section 210). Accordingly, the length in the X-direction can be reduced compared to that of the processing device 10. A specific configuration of the processing device 200 will be described with reference to FIGS. 19A to 22.

The processing device 200 according to the second embodiment differs from the processing device 10 of the first embodiment in the following points. The processing device 200 includes only one storing section (the storing section 170), the third transfer hand 213 (one example of the transfer hand) has a shape different from that of the processing device 10, and the processing device 200 includes an auxiliary hand 216 in addition to the third transfer hand 213. The configuration, operations, and effects that are similar to those of the first embodiment will not be described. The components having the configurations same as those of the first embodiment are designated by the same reference signs.

A whole configuration of the processing device 200 is illustrated in FIGS. 19A to 19C. FIGS. 19A to 19C are a plan view, a front view, and a side view, respectively. The processing device 200 includes the storing section 170 and the third transfer section 210.

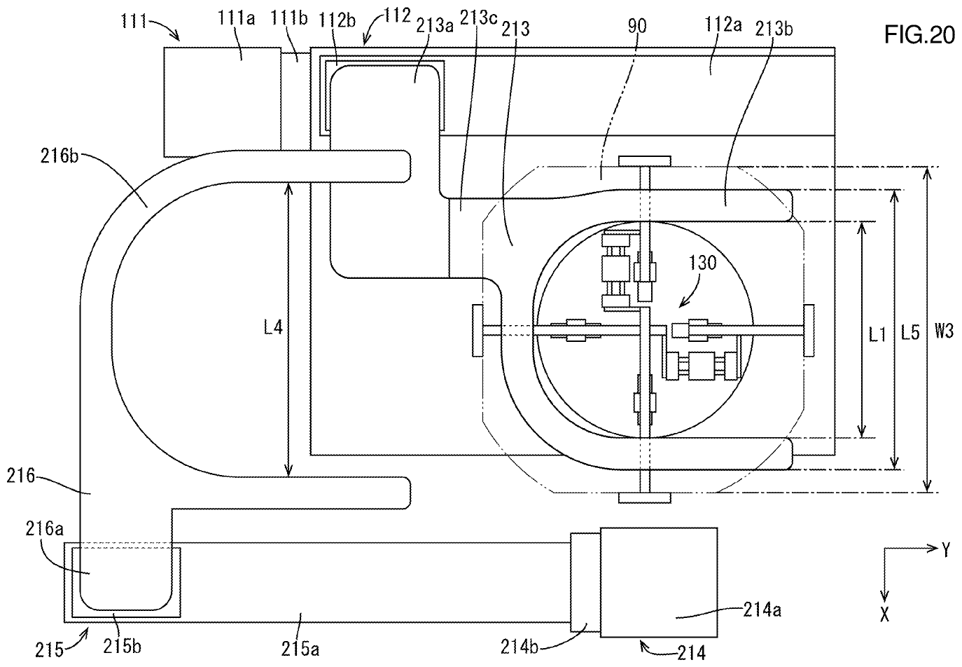

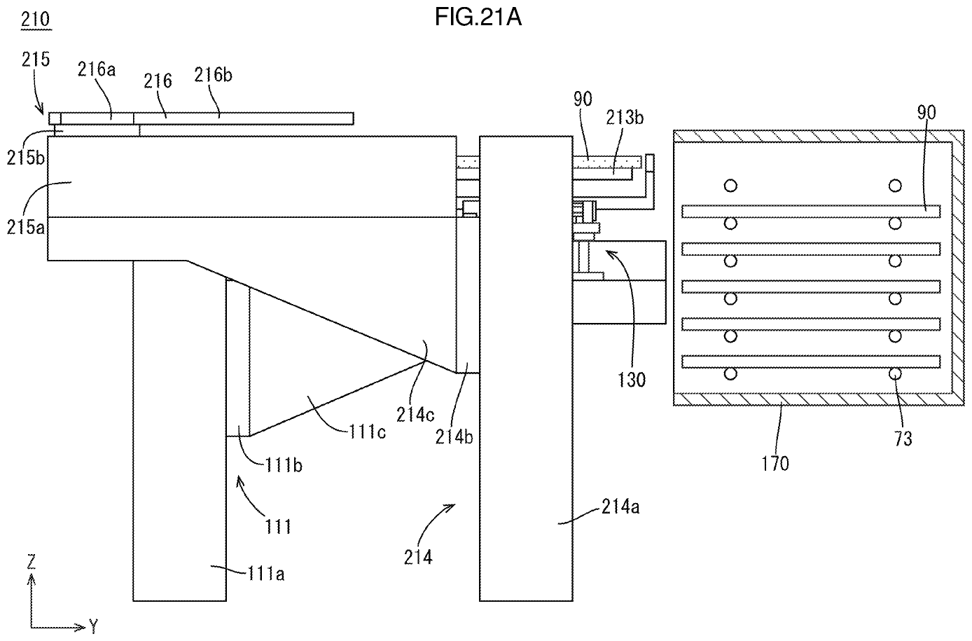

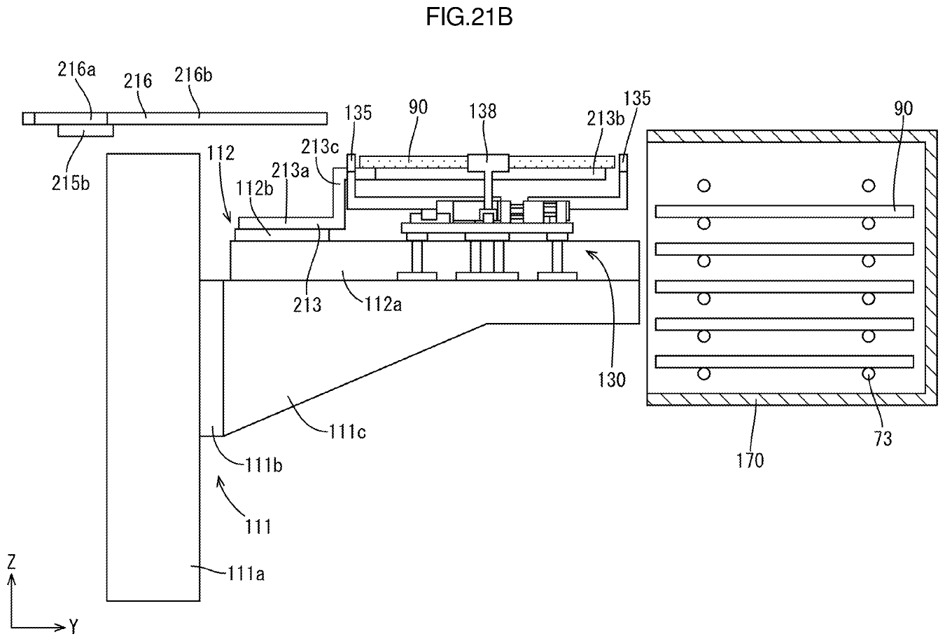

FIG. 20 is a plan view of the third transfer section 210 and FIG. 21A is a side view. The third transfer section 210 includes the third transfer hand 213, a Z3-axis moving section 214, a Y3-axis moving section 215, and the auxiliary hand 216 in addition to the Z1-axis moving section 111 and the Y1-axis moving section 112. The auxiliary hand 216 moves along the Y3-axis and the Z3-axis that are parallel to the Y-axis and the Z-axis, respectively.

As illustrated in FIG. 19B, the Z3-axis moving section 214 is fixed to the base horizontal portion 21. As illustrated in FIG. 21A, the Z3-axis moving section 214 includes a Z3-axis ball screw 214a that extends in the Z-direction, a Z3-axis slider 214b, and a Z3-stage 214c. The Z3-axis slider 214b includes a nut that is fitted to the Z3-axis ball screw 214a. The Z3-stage 214c is fixed to the Z3-axis slider 214b. The Y3-axis moving section 215, which will be described later, is joined to the Z3-stage 214c.

The configuration of the Z3-axis moving section 214 is similar to the configuration of the Z1-axis moving section 111. Namely, the controller 11 controls the driving section, which is not illustrated, to rotate the Z3-axis ball screw 214a about the axis thereof to move the Z3-axis slider 214b in the Z-direction. Since the Z3-stage 214c is fixed to the Z3-axis slider 214b, the Y3-axis moving section 215 that is arranged on the Z3-stage 214c moves in the Z-direction with the Z3-axis moving section 214 being operated.

The Y3-axis moving section 215 is fixed to the upper surface of the Z3-stage 214c and includes a Y3-axis ball screw 215a that extends in the Y-direction and a Y3-axis slider 215b that includes a nut to be fitted to the Y3-axis ball screw 215a.

Similar to the Y1-axis moving section 112, the controller 11 controls the driving section, which is not illustrated, to rotate the Y3-axis ball screw 215a about the axis thereof to move the Y3-axis slider 215b in the Y-direction. The controller 11 is configured to move the Z3-axis moving section 214 and the Y3-axis moving section 215 to move the Y3-axis slider 215b freely in the Y-direction and the Z-direction.

As illustrated in FIG. 20, the auxiliary hand 216 is a metal plate having a plan view Y-shape and is made of stainless steel. The auxiliary hand 216 includes a basal end portion 216a that is joined to the upper surface of the Y3-axis slider 215b. Therefore, the auxiliary hand 216 moves in the Y-direction and the Z-direction together with the Y3-axis slider 215b that moves in the Y-direction and the Z-direction.

A distal end portion 216b of the auxiliary hand 216 is branched into two portions to form a U-shape and each of the two portions extends in the Y-direction. A distance between inner sides of the distal end portion 216b is defined as L4.

With a distance between outer sides of a distal end portion 213b being defined as L5, the distance L4 between the inner sides of the distal end portion 216b is greater than the distance L5 between the outer sides of the distal end portion 213b and smaller than the outer diameter size W3 of the wafer ring 92. Namely, the relation represented by the following formula (2) is established.

L2<L4<W3 (2)

According to such a configuration, the workpiece 90 can be transferred between the third transfer hand 213 and the auxiliary hand 216. A distance between the inner sides of the distal end portion 213b of the third transfer hand 213 is L1 similar to the first transfer hand 113 and is greater than the diameter W1 of the wafer.

As illustrated in FIG. 21B, a shape of the third transfer hand 213 seen from the X-direction differs from that of the first transfer hand 113 of the first embodiment (refer to FIG. 7). FIG. 21B is similar to FIG. 21A but does not illustrate the Z3-axis moving section 214 and the Y3-axis moving section 215 such that the third transfer hand 213 and the auxiliary hand 216 can be seen. In FIG. 21B, the Z3-axis moving section 214 and the Y3-axis moving section 215 are not illustrated.

As illustrated in FIG. 21B, the third transfer hand 213 includes a crank portion 213c between a basal end portion 213a that is joined to the Z1-axis slider 111b and the distal end portion 213b. The crank portion 213c projects in the Z-direction. Due to the crank portion 213c, the positions of the basal end portion 213a and the distal end portion 213b with respect to the Z-direction (the height) differ from each other and the third transfer hand 213 has a crank shape seen from the X-direction. The crank portion 213c is included for preventing the basal end portion 213a of the third transfer hand 213 from being contacted with the basal end portion 216a of the auxiliary hand 216 when transferring the workpiece 90 between the third transfer hand 213 and the auxiliary hand 216 in the supply and storing process.

### Description of Whole Process (Second Embodiment)

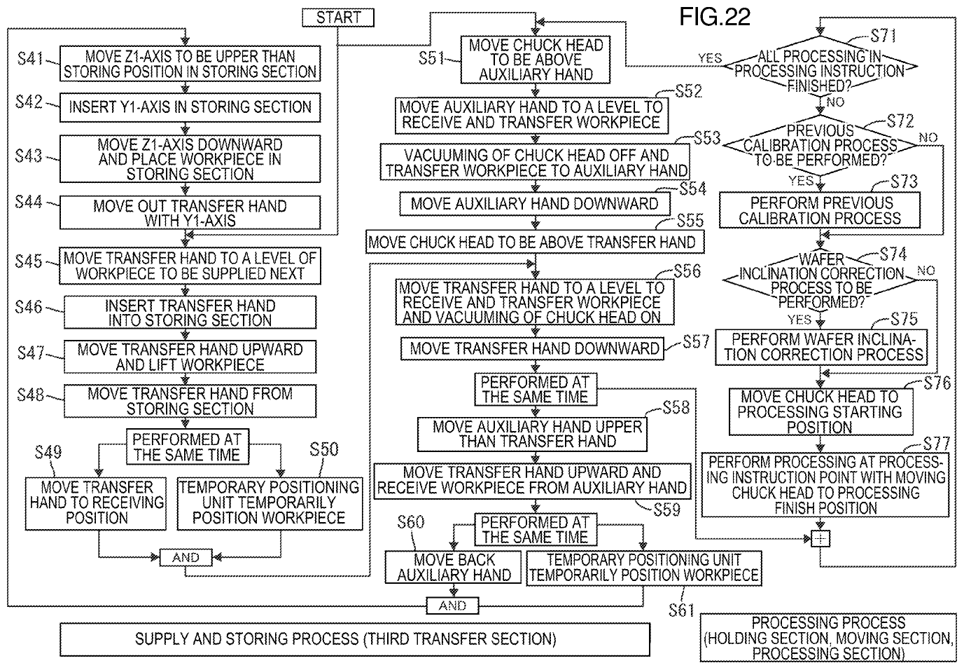

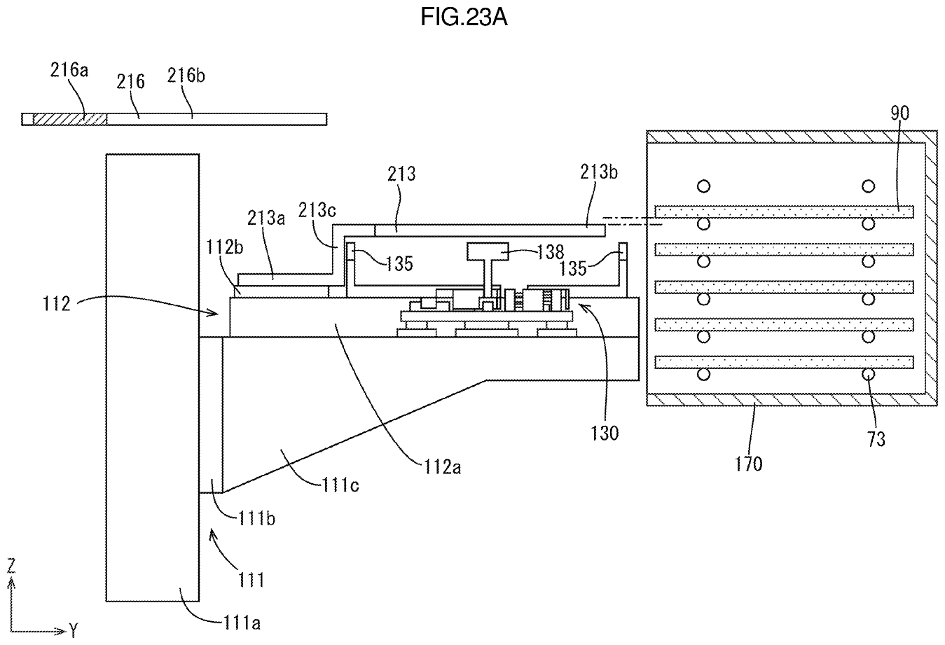

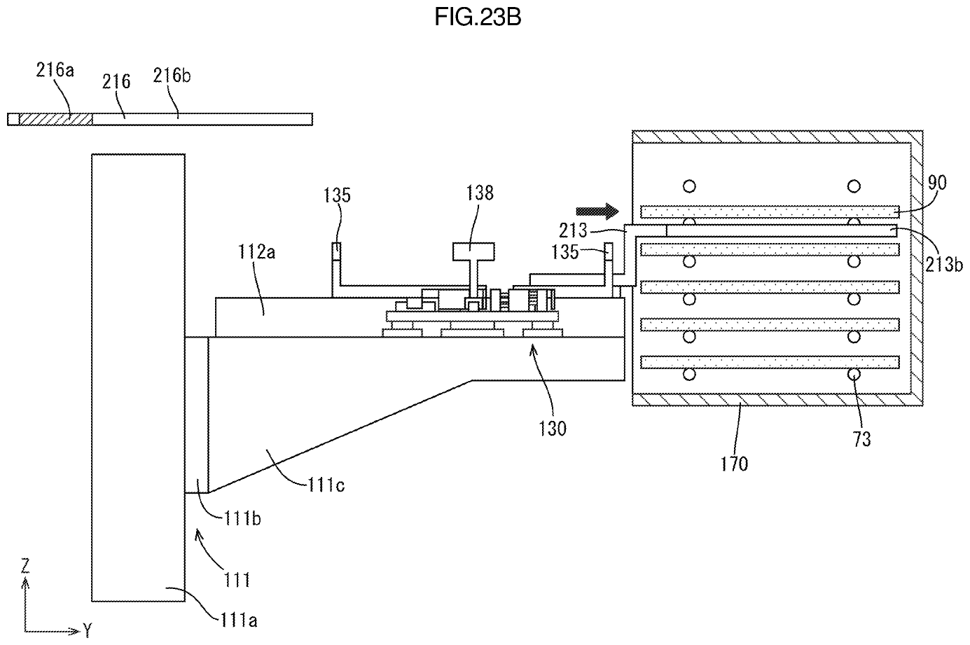

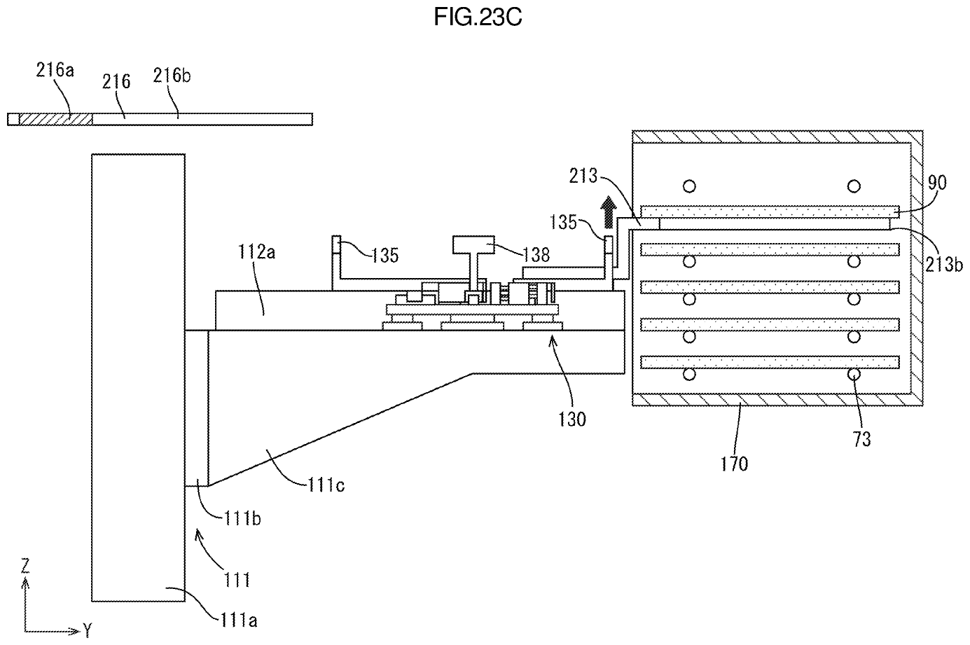

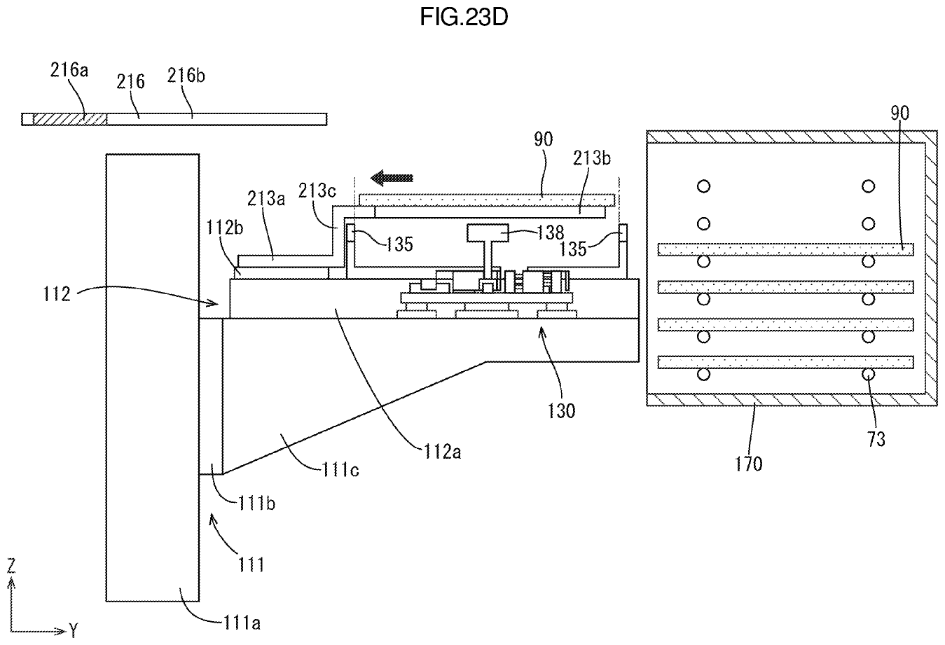

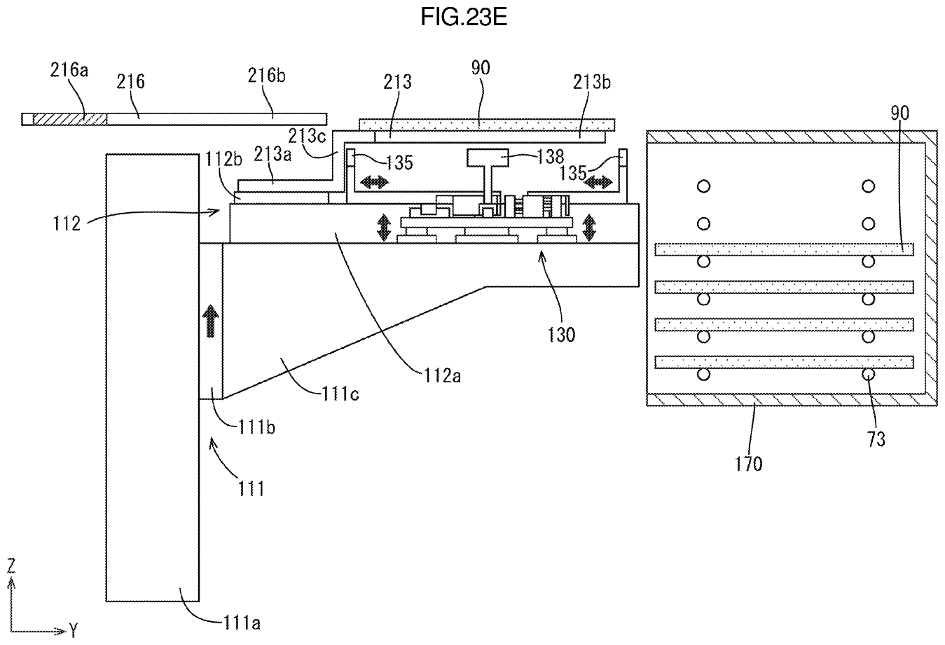

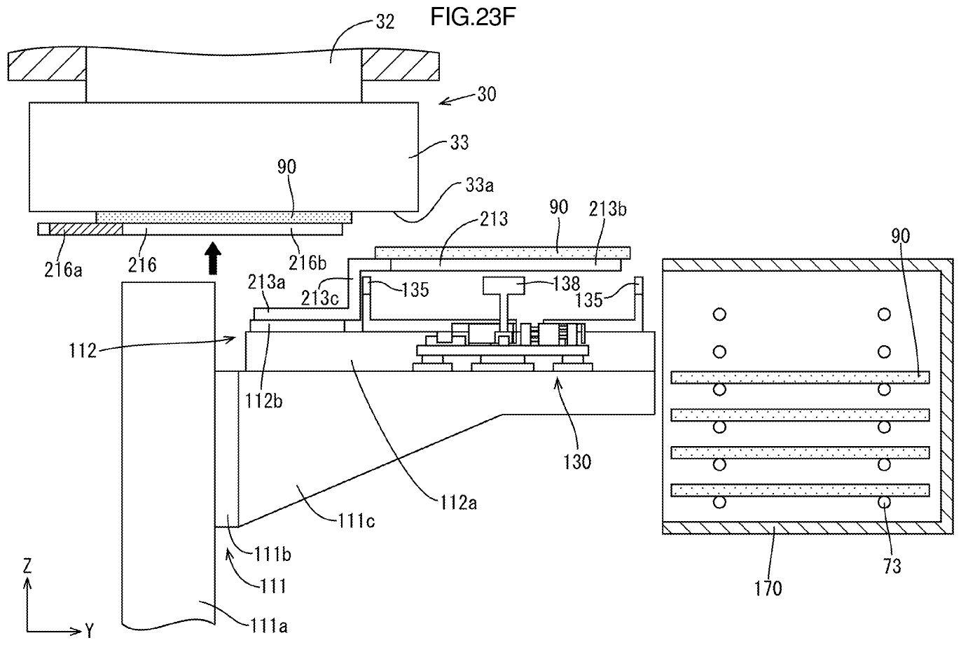

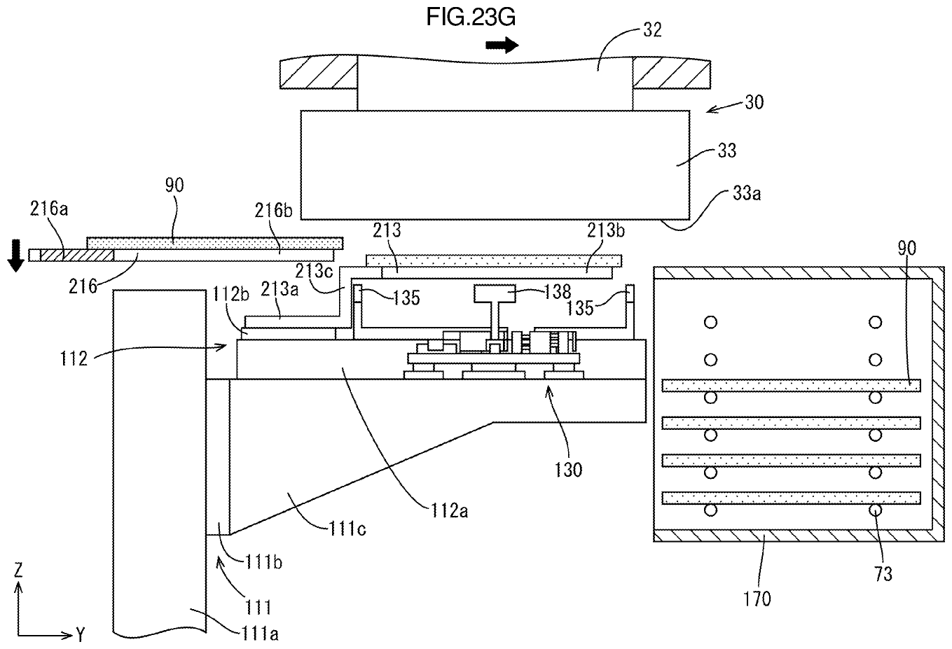

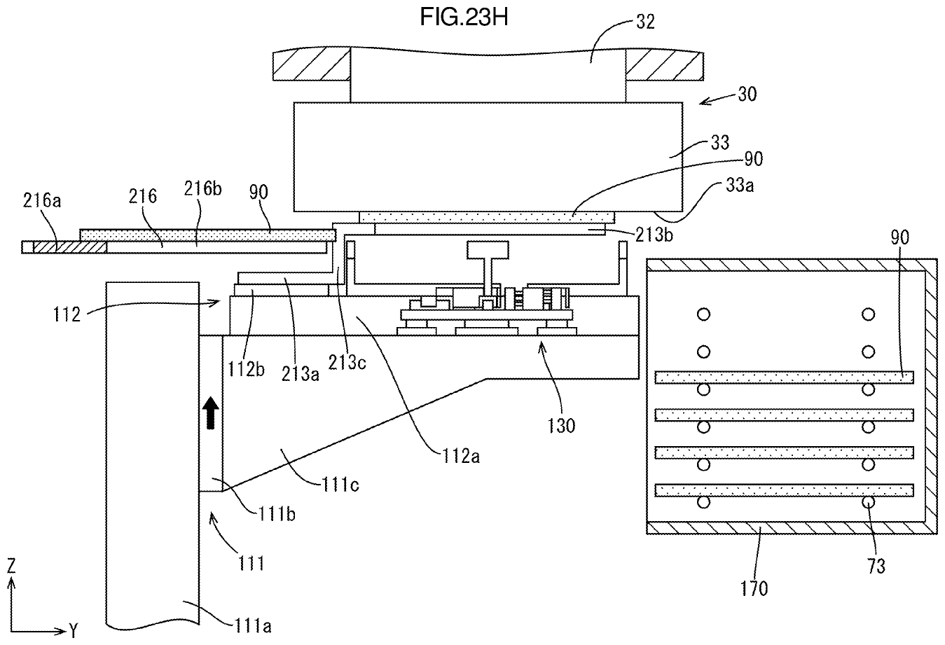

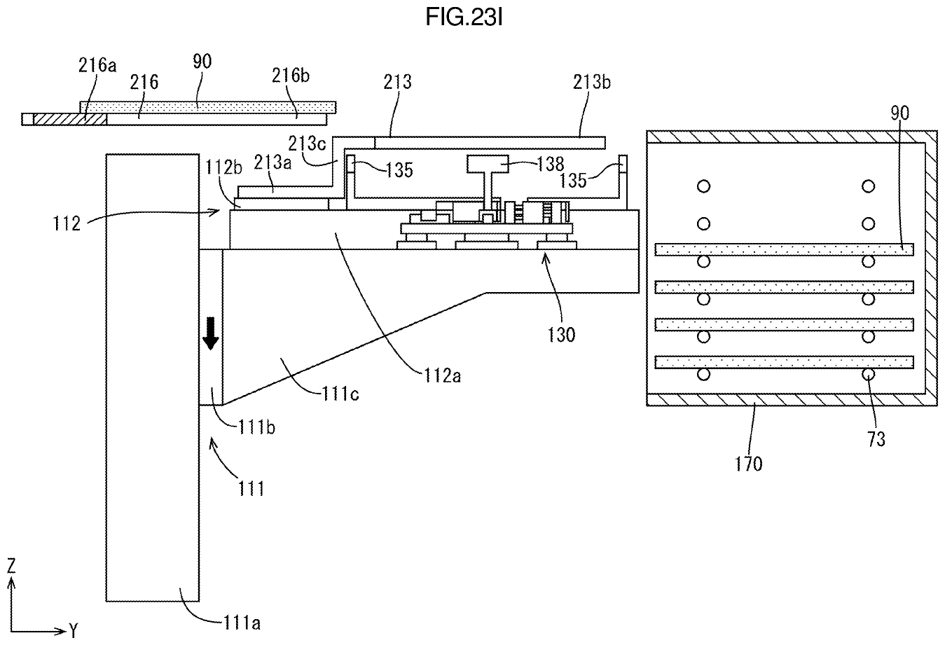

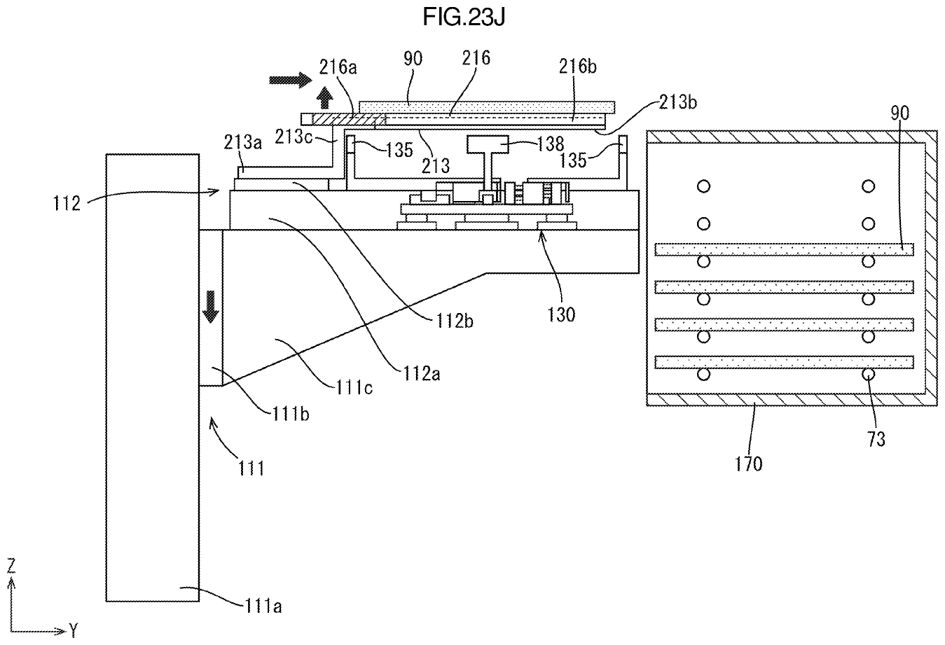

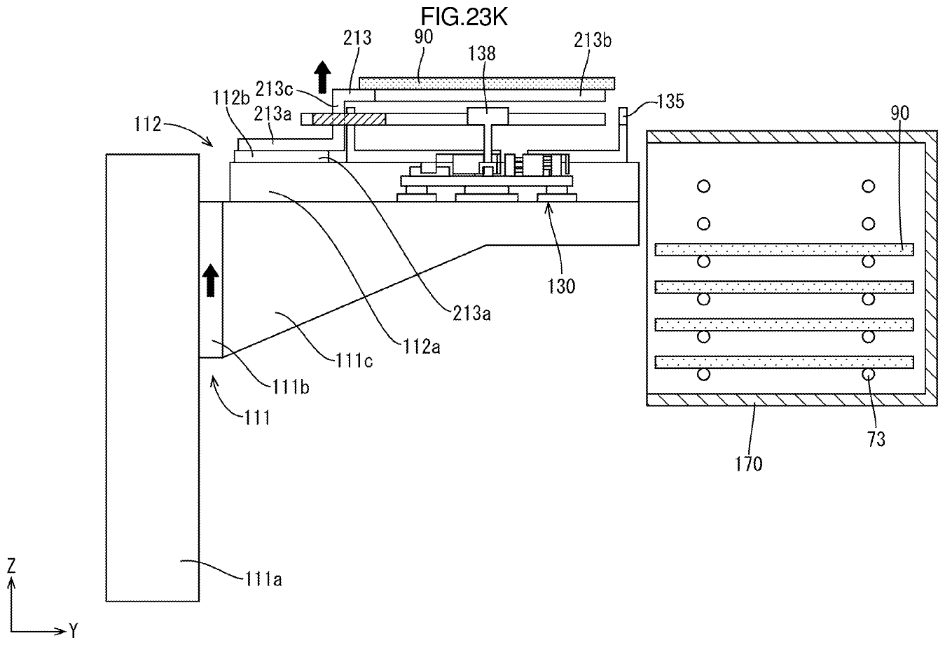

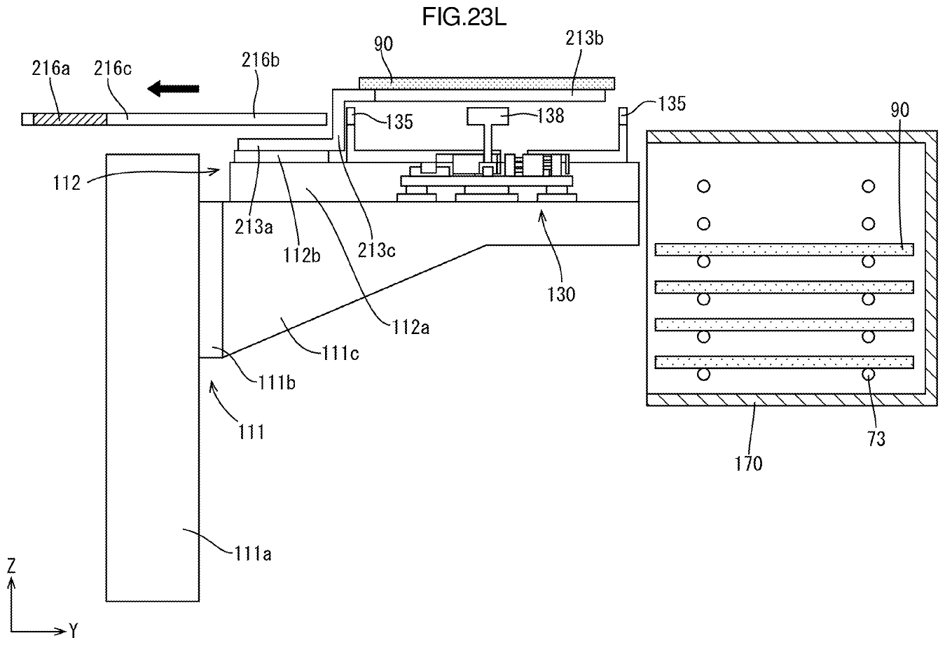

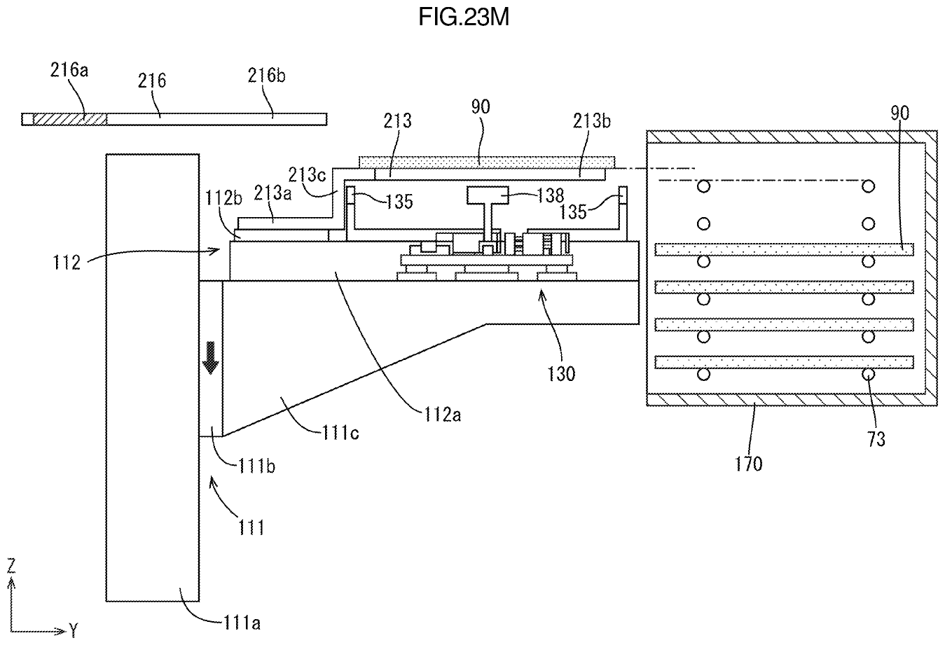

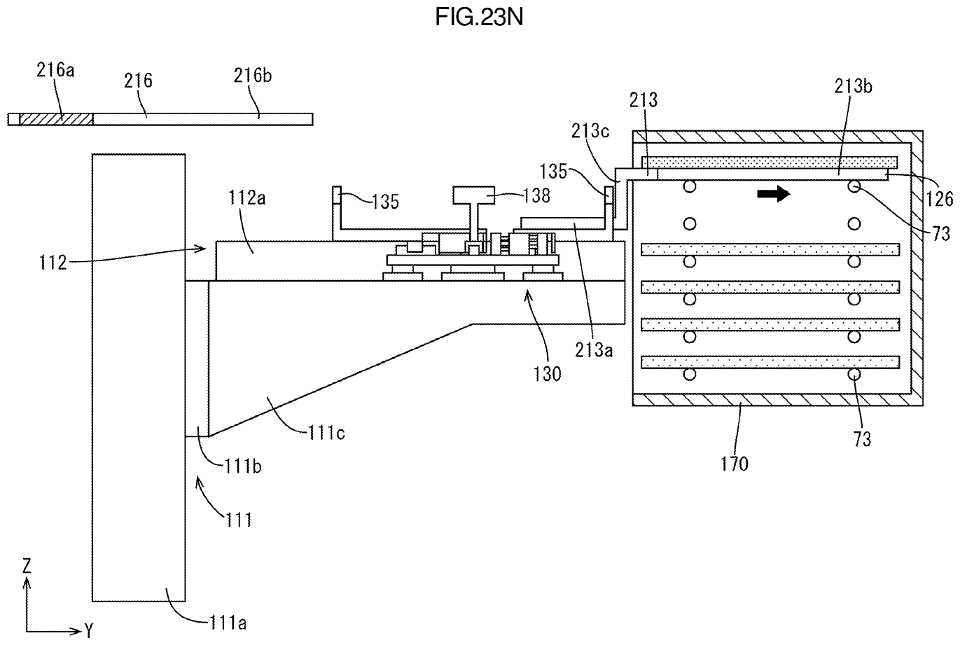

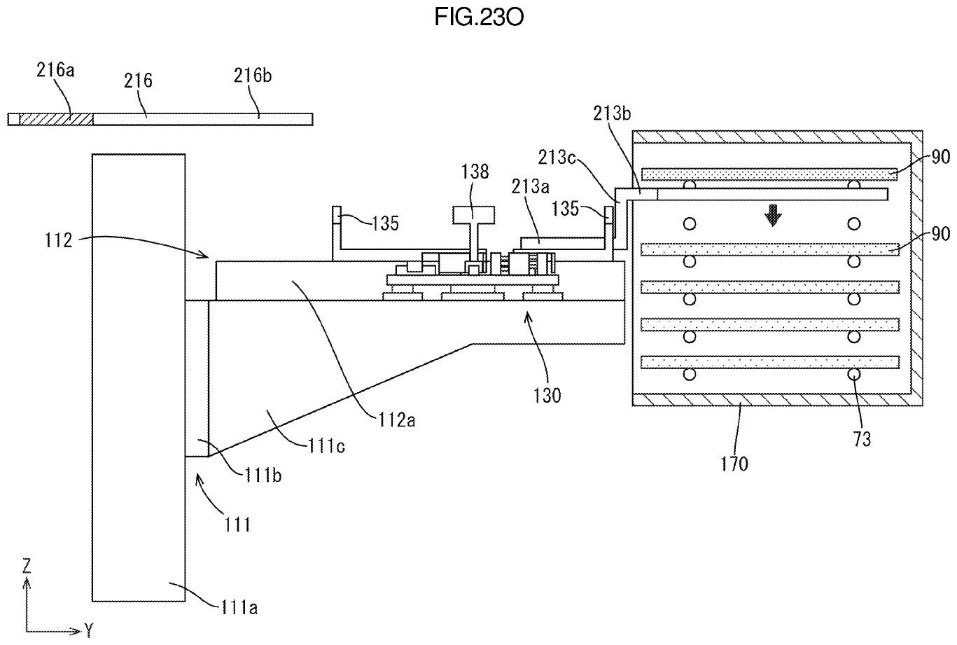

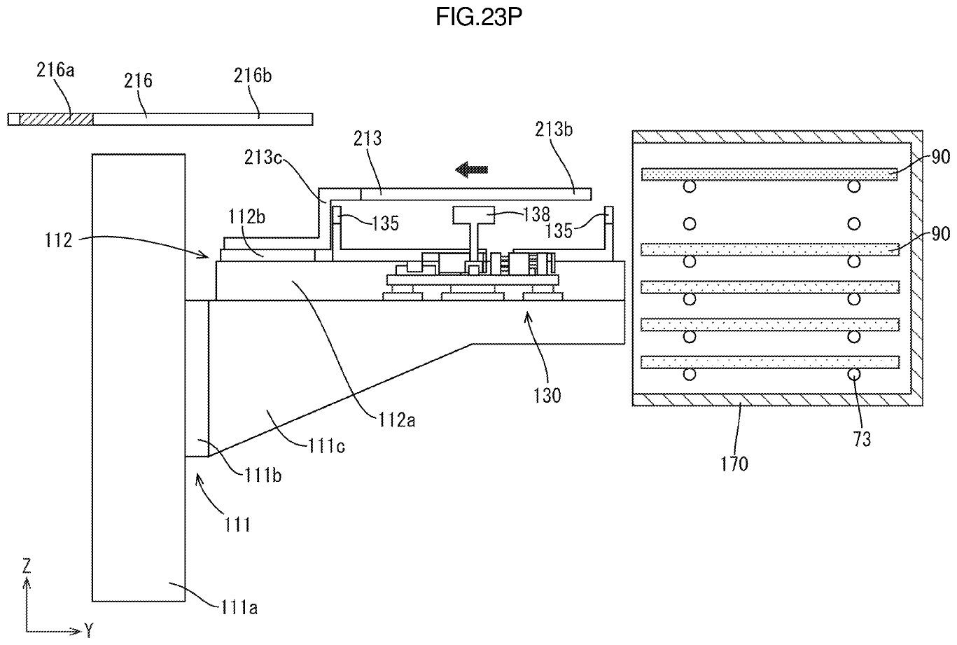

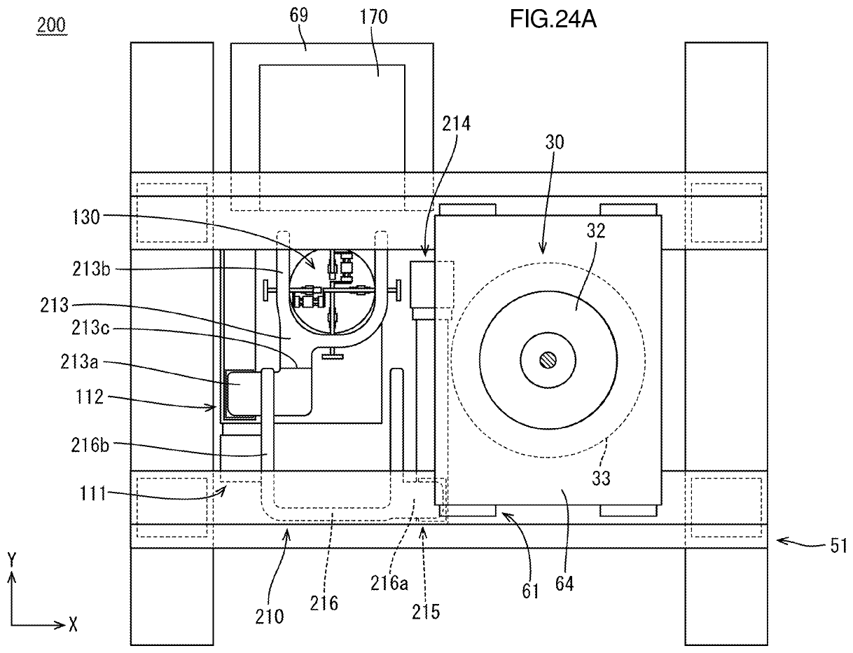

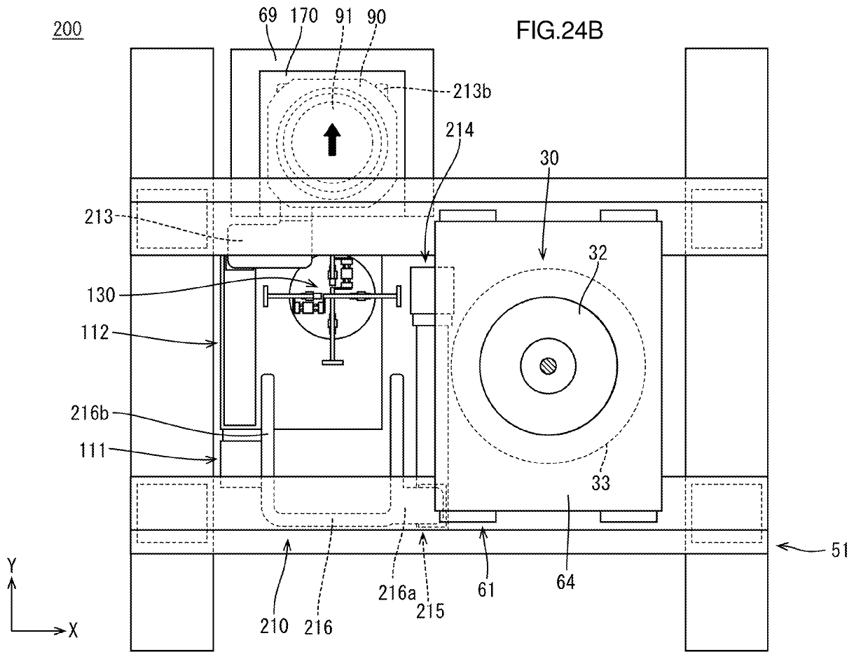

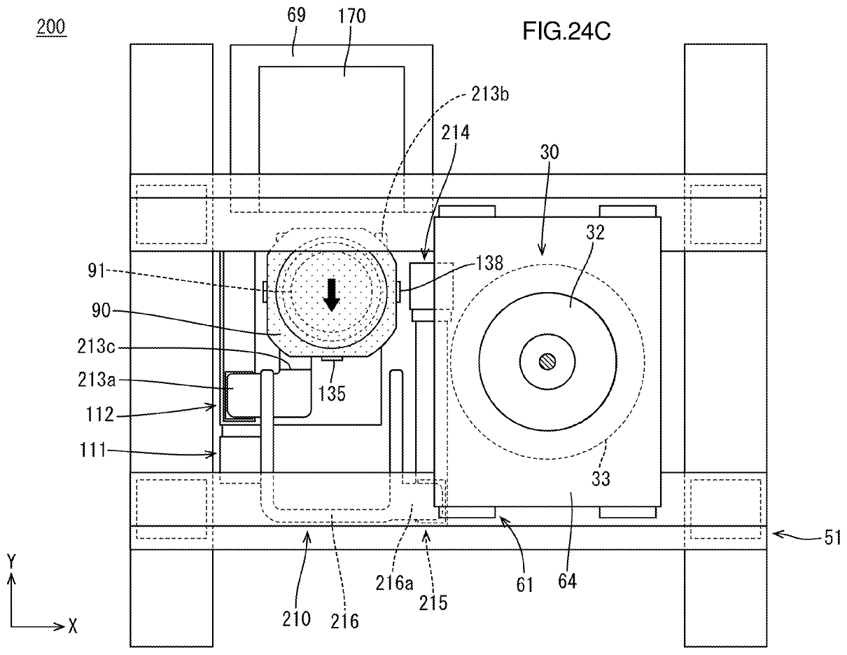

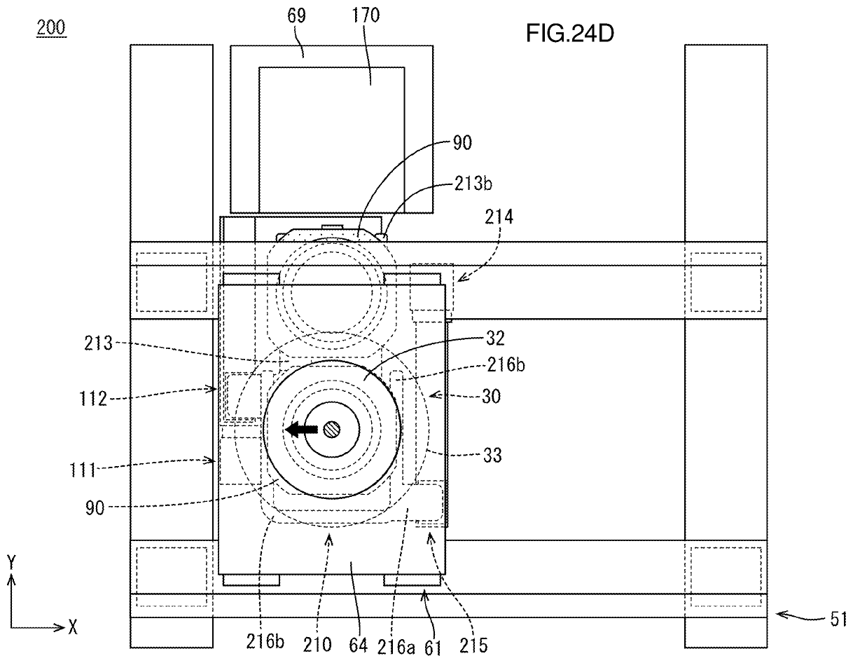

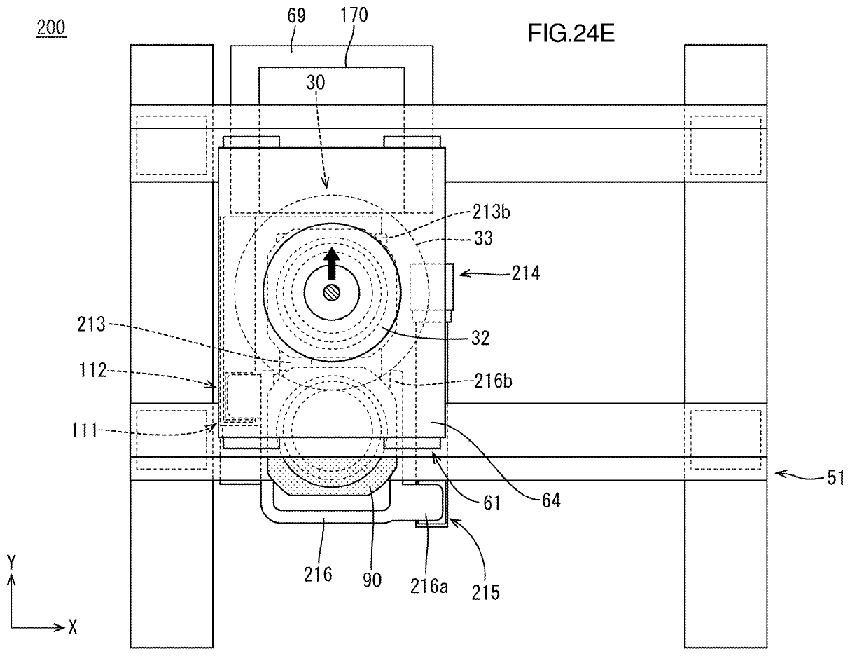

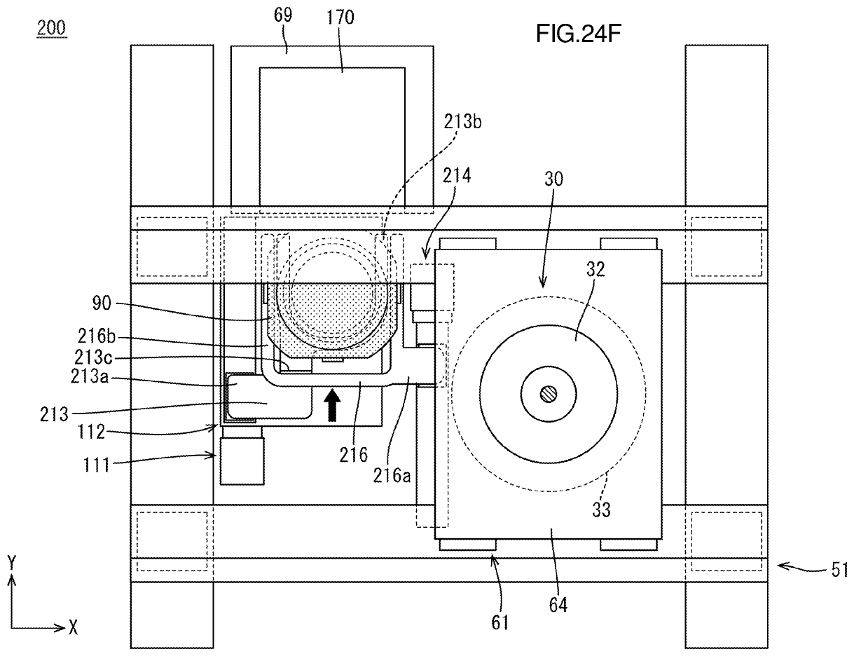

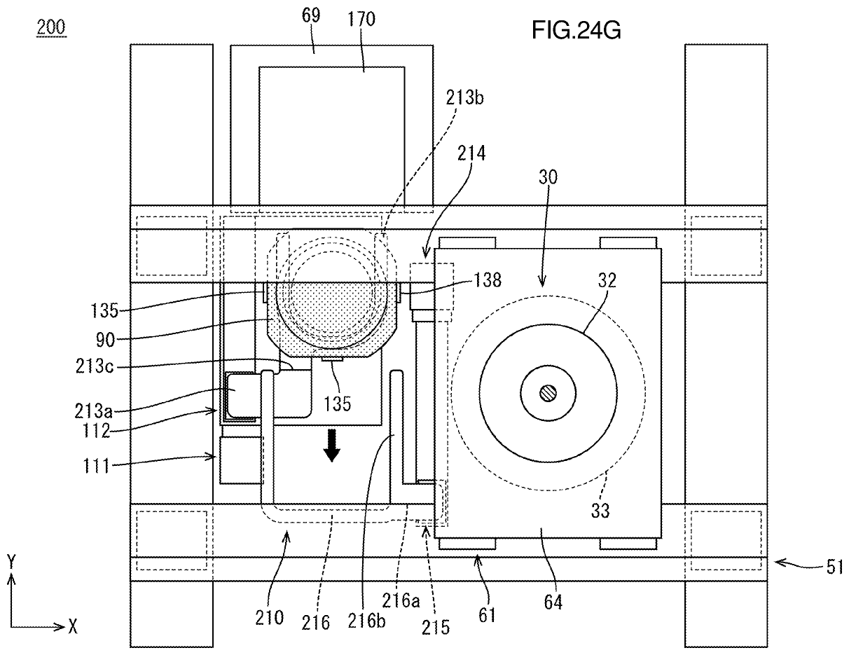

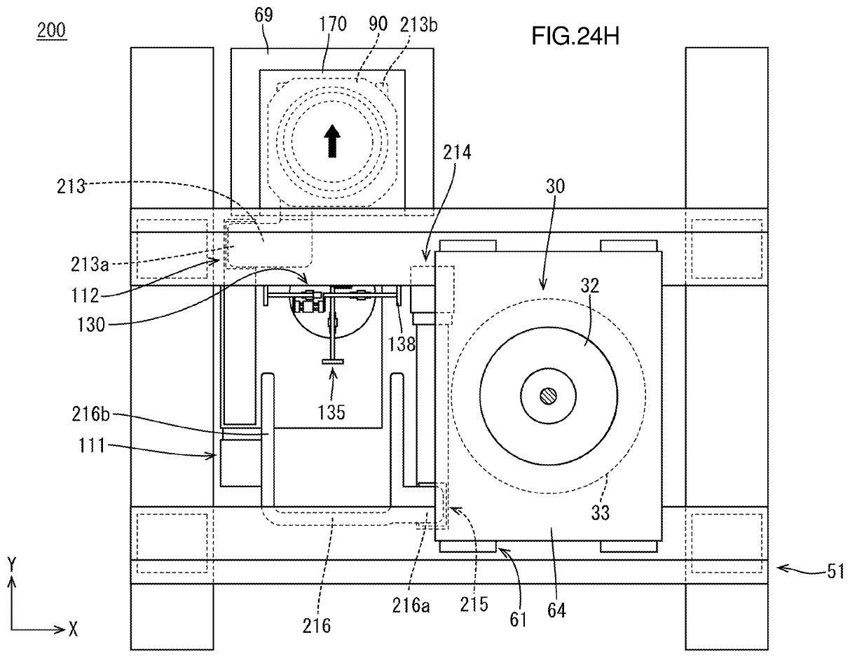

Next, the supply process, the processing process, and the storing process that are performed by the processing device 200 will be described with reference to the flowchart in FIG. 22, and FIGS. 23A to 23P, and FIGS. 24A to 24H. In FIGS. 23A to 23P that are side views (partially cross-sectional views) of the storing section 170 and the third transfer section 210, similar to FIG. 21B, the Z3-axis moving section 214 and the Y3-axis moving section 215 that move the auxiliary hand 216 are not illustrated. FIGS. 24A to 24H are plan views that correspond to the side views of FIGS. 23A to 23P.

As illustrated in FIG. 23A, in an initial state at the time of starting, five workpieces 90 that are not processed are stored in the inner space of the storing section 170 and an uppermost storing space of the storing section 170 is free. No workpiece 90 is disposed on the third transfer hand 213 and the auxiliary hand 216. The workpiece 90 that is processed is held on the bottom surface of the chuck head 33 (illustrated in FIG. 23F). FIG. 24A is a plan view corresponding to FIG. 23A.

With starting the operation of the processing device 200 in response to an instruction from the controller 11, the controller 11 controls the Z1-axis moving section 111 to move the third transfer hand 213 such that the height of the third transfer hand 213 is slightly lower than the bottom surface of the workpiece 90 (stored in a second uppermost storing space in the storing section 170) that is to be supplied to the holding section 30 (FIG. 23A, FIG. 24A, S45).

The controller 11 controls the Y1-axis moving section 112 to insert the third transfer hand 213 into the storing section 170 such that the distal end portion 213b of the third transfer hand 213 is not contacted with the workpiece 90 (FIG. 23B, FIG. 24B, S46).

The controller 11 moves the third transfer hand 213 upward. The workpiece 90 is lifted up by the distal end portion 213b and the workpiece 90 is placed on the upper surface of the distal end portion 213b (FIG. 23C, S47).

The controller 11 moves back the third transfer hand 213 from the storing section 170 with keeping the workpiece 90 on the distal end portion 213b (FIG. 23D, FIG. 24C, S48).

The controller 11 controls the Z1-axis moving section 111 to move the third transfer hand 213 upward to the position (referred to as the receiving position) where the workpiece 90 that is not processed is moved between the third transfer hand 213 and the chuck head 33 (FIG. 23E, S49). At the same time, the controller 11 controls the temporary positioning unit 130 to temporarily position the workpiece 90 on the third transfer hand 213 (S50).

In S45 to S50 described above, the third transfer hand 213 moves out the workpiece 90, which is not processed, from the storing section 170 to the receiving position. During the movement, the chuck head 33 that holds the processed workpiece 90 in the initial state performs operations of transferring the workpiece 90 to the auxiliary hand 216 in parallel with the movement of the third transfer hand 213 (S51 to S55). S51 to S55 will be described below.

The controller 11 controls the Ys-axis moving section 51 and the Xs-axis moving section 61 to move the chuck head 33 to be above the auxiliary hand 216 (S51, FIG. 24D). Next, the auxiliary hand 216 is moved upward by the Z3-axis moving section 214 to move the upper surface of the distal end portion 216b of the auxiliary hand 216 closer to the workpiece 90 that is held by the chuck head 33 (FIG. 23F, S52). Then, the vacuuming of the chuck head 33 becomes OFF. This releases the holding of the workpiece 90 and the workpiece 90 is placed on the distal end portion 216b (S53).

After detecting that the air pressure of the suction cavity 35 (refer to FIG. 19C) detected by the air pressure sensor, which is not illustrated, becomes a normal pressure and confirming releasing of the holding, the controller 11 moves downward the auxiliary hand 216 on which the processed workpiece 90 is disposed (S54). Then, the controller 11 moves the chuck head 33 to be above the third transfer hand 213 on which the workpiece 90 that is not processed is disposed (FIG. 23G, FIG. 24E, S55).

The controller 11 moves the third transfer hand 213 upward to press the workpiece 90 toward the bottom surface 33a of the chuck head 33 and controls vacuuming of the chuck head 33 to be ON (FIG. 23H, S56). Accordingly, the chuck head 33 suctions and holds the workpiece 90 with the bottom surface 33a from above. After detecting lowering of pressure detected by the pressure sensor, which is not illustrated, and confirming the holding of the workpiece, the controller 11 moves downward the third transfer hand 213 without having any workpiece (FIG. 23I, S57).

The controller 11 moves the chuck head 33 to the processing position and processes the workpiece 90 that is not processed (S71 to S77). S71 to S77 correspond to S21 to S27 of the first embodiment, respectively, and will not be described.

While performing the processing of S71 to S77, the workpiece 90 that is processed is transferred from the auxiliary hand 216 to the third transfer hand 213 (S58 to S61) and the workpiece 90 is stored in the storing section 170 by the third transfer hand 213 (S41 to S44) in the third transfer section 210. Such processes will be described below.

The controller 11 moves the auxiliary hand 216 on which the processed workpiece 90 is disposed to be upper than the third transfer hand 213 and the controller 11 moves the third transfer hand 213 upward (FIG. 23J, FIG. 24F, S58). As illustrated by the formula (2) and FIG. 20, the distance L4 between the inner sides of the distal end portion 216b is greater than the distance L5 between the outer sides of the distal end portion 213b. Therefore, the distal end portion 213b can pass through the inside of the distal end portion 216b although the distal end portion 216b and the distal end portion 213b appear to overlap in FIG. 23J seen from the X-direction. The distal end portion 213b and the distal end portion 216b are not contacted with each other. As illustrated in FIG. 21B, the third transfer hand 213 has a crank shape seen from the X-direction. With such a configuration, with the distal end portion 213b being disposed upper than the distal end portion 216b as illustrated in FIG. 23K, the basal end portion 213a is not contacted with the auxiliary hand 216.

Therefore, although the auxiliary hand 216 and the third transfer hand 213 overlap seen from the X-direction as illustrated in FIG. 23J, the auxiliary hand 216 and the third transfer hand 213 are not contacted with each other. With the third transfer hand 213 being moved upward further than the state in FIG. 23J, the workpiece 90 on the auxiliary hand 216 is disposed on the third transfer hand 213 (FIG. 23K, S59). Accordingly, the workpiece 90 that is processed is transferred from the auxiliary hand 216 to the third transfer hand 213.

Next, the controller 11 moves back the auxiliary hand 216 to the left side in the drawing (FIG. 23L, FIG. 24G, S60) and the temporary positioning is performed on the third transfer hand 213 by the temporary positioning unit 130 (S61).

Next, the processed workpiece 90 disposed on the third transfer hand 213 is stored in the storing section 170. Specifically, the controller 11 moves downward and stops the third transfer hand 213 at a position slightly higher than the uppermost storing position (FIG. 23M, S41).

The controller 11 moves and inserts the third transfer hand 213 into the storing section 170 (FIG. 23N, FIG. 24H, S42). Subsequently, the third transfer hand 213 is moved downward and the workpiece 90 is placed on the projections 73 in the storing section 170 (FIG. 23O, S43) and the third transfer hand 213 is moved out from the storing section 170 (FIG. 23P, S44). Then, the controller 11 moves downward the third transfer hand 213 to a level of the workpiece 90 that is to be transferred to the chuck head 33 next (S45) and inserts the third transfer hand 213 into the storing section 170 (S40). The operations described above correspond to one cycle of the process performed by the processing device 200.

### Description of Effects (Second Embodiment)

As previously described, the third transfer section 210 of the processing device 200 according to the second embodiment includes the auxiliary hand 216 on which the workpiece 90 can be disposed. The auxiliary hand 216 receives the workpiece 90 from the holding section 30 (the chuck head 33) and transfers the workpiece 90 to the third transfer hand 213.

Accordingly, right after transferring the processed workpiece 90 to the auxiliary hand 216, the holding section 30 can move to the receiving position on the third transfer hand 213 and receive the workpiece 90 that is not processed from the third transfer hand 213. Namely, before waiting until the processed workpiece 90 is stored in the storing section 170, the holding section 30 holds the workpiece 90 to be processed next and the workpiece 90 can be processed by the processing section 80. Accordingly, the takt time of the processing device 200 can be shortened and the productivity is increased.

With the processing device 200 according to the second embodiment including one storing section and one transfer section (the storing section 170, the third transfer section 210), the takt time of the processing section can be shortened and the productivity of the processing device 200 can be increased. Compared to the processing device 10 including two storing sections and two transferring sections, the device can be downsized and a space for the device can be reduced.

### OTHER EMBODIMENTS

(1) In the first embodiment, the processing device 10 includes two storing sections (the first storing section, the second storing sections) and two transfer sections (the first transfer section 110, the second transfer section 120). However, the number of storing sections and transfer sections may be one. In such a configuration, a process of moving out the workpiece (the supply process) and a process of moving the workpiece in (the storing process) are performed by one transfer hand.

(2) In the first embodiment, the first storing section stores the workpieces that are not processed and the second storing section stores the workpieces that are processed. However, the workpieces stored in each of the storing sections may not be necessarily the ones before or after the processing. In such a configuration, the transfer hand of the transfer section that corresponds to each storing section performs both of the process of moving the workpiece out (the supply process) and the process of moving the workpiece in (the storing process).

(3) The number of transfer sections and the storing sections may be three or more.

(4) In the above embodiments, the holding section 30, the transfer hand 113, and the auxiliary hand 216 are moved in the X-direction, the Y-direction, and the Z-direction with using ball screws. As a configuration for moving the holding section and other components, the mechanism other than the ball screws such as a linear motor, a belt pulley mechanism, and a gear mechanism may be used.

(5) In the above embodiments, as one example of the laser processing, the method of forming the modified layer inside the semiconductor wafer is described. However, laser processing other than the above method such as full cutting processing, half cutting processing, and grooving processing may be performed. The full cutting processing is a method of cutting an entire thickness of a semiconductor wafer with a laser. The half cutting processing is a method of cutting a half of a thickness of a semiconductor wafer from a surface thereof with a laser and grinding an opposite surface to obtain semiconductor chips. The grooving processing is a method of removing a fragile layer included in the semiconductor wafer with laser processing and processing other layers with a laser or other method to obtain semiconductor chips. With any methods, the portions processed with a laser correspond to separation borders for dividing the semiconductor wafer into pieces.

(6) In the above embodiments, the laser oscillator 85 is fixed to the Z-stage 84. A Ox-stage that adjusts a rotation angle about the X-axis and a αy-stage that adjusts a rotation angle about the Y-axis may be disposed between the Z-stage 84 and the laser oscillator 85 such that an angle of the laser oscillator 85 can be adjusted. According to such a configuration, the angle of the laser head 85a with respect to the Z-axis can be adjusted by the Ox-stage and the θy-stage and therefore, a laser can be irradiated on the plate surface of the workpiece 90 at a desired angle (normally a right angle).

What is claimed is:

1. A processing device processing a workpiece of a plate shape having a thickness direction along an upper-bottom direction, the processing device comprising:
a controller configured to control an operation of the processing device;
a storage configured to store the workpiece;
a transfer mechanism including a transfer hand configured to receive the workpiece, the transfer mechanism being configured to move the workpiece from and into the storage;
a processing machine configured to process the workpiece;
a holding mechanism configured to hold an upper surface of the workpiece; and
a moving mechanism configured to horizontally moving the holding mechanism between the transfer hand and the processing machine, the moving mechanism being configured to move the holding mechanism relative to the processing machine when the processing machine processes the workpiece, wherein
the holding mechanism is configured to receive and place the workpiece from and on the transfer hand above the transfer hand, and
the processing machine is configured to process the workpiece from below, the workpiece being held by the holding mechanism.

2. The processing device according to claim 1, wherein
the transfer mechanism includes at least one sandwich mechanism,
the sandwich mechanism includes at least two sandwich members,
the two sandwich members are configured to hold a side surface of the workpiece that is placed on the transfer hand from an outer side to position the workpiece on the transfer hand.

3. The processing device according to claim 1, wherein
the moving mechanism includes a first moving mechanism configured to move the holding mechanism in a first direction that is perpendicular to the upper-bottom direction and a second moving mechanism configured to move the holding mechanism in a second direction that is perpendicular to the upper-bottom direction and the first direction,
the first direction corresponds to a processing direction in which the workpiece is processed,
the second direction corresponds to an interval feeding direction of the workpiece, and
a position where the holding mechanism receives and places the workpiece from and on the transfer hand and a position of the holding mechanism when the workpiece is processed by the processing machine are arranged in the first direction.

4. The processing device according to claim 3, wherein
the workpiece is received from and placed on the transfer hand in the second direction, and
the storage is disposed below the moving mechanism such that the storage at least partially overlaps an area in which the moving mechanism is movable with a plan view.

5. The processing device according to claim 3, wherein
the first moving mechanism includes at least two first guide portions that extend in the first direction and are in parallel to each other with respect to the second direction, and
the two first guide portions are configured to support the holding mechanism to move in the first direction.

6. The processing device according to claim 5, wherein
the second moving mechanism includes at least two second guide portions that extend in the second direction and are in parallel to each other with respect to the first direction, and
the two second guide portions are configured to support the first moving mechanism to move in the second direction.

7. The processing device according to claim 1, wherein
the storage includes a first storage configured to store the workpiece that is not processed and a second storage configured to store the workpiece that is processed, and
the transfer hand includes a first transfer hand that is configured to transfer the workpiece from the first storage and to a position where the holding mechanism is configured to receive the workpiece and a second transfer hand that is configured to receive the workpiece from the holding mechanism and transfer the workpiece into the second storage.

8. The processing device according to claim 1, wherein
the transfer mechanism includes an auxiliary hand on which the workpiece is placed, and
the auxiliary hand is configured to receive the workpiece from the holding mechanism and transfer the workpiece to the transfer hand.

9. The processing device according to claim 1, wherein
the workpiece has at least three plate surface measurement points on a plate surface,
the processing machine includes a camera configured to take an image of each of the at least three plate surface measurement points and measure of each of the at least three plate surface measurement points and further includes a third moving mechanism configured to move the processing machine in the upper-bottom direction, and
the controller is configured to specify the plate surface based on coordinates of the plate surface measurement points before performing processing and control the processing machine to perform the processing with controlling the third moving mechanism to move the processing machine such that distances between arbitrary points on the plate surface and the processing machine are same.

10. The processing device according to claim 1, wherein
the holding mechanism has a bottom surface that is configured to hold the workpiece and the bottom surface includes at least three bottom surface measurement points,
the processing machine includes a camera that is configured to take an image of each of the at least three bottom surface measurement points and measure coordinates of each of the at least three bottom surface measurement points, and
the controller is configured to specify the plate surface based on the coordinates of the bottom surface measurement points and calculate a distance between a point on the bottom surface and the processing machine.

11. The processing device according to claim 2, wherein
the moving mechanism includes a first moving mechanism configured to move the holding mechanism in a first direction that is perpendicular to the upper-bottom direction and a second moving mechanism configured to move the holding mechanism in a second direction that is perpendicular to the upper-bottom direction and the first direction,
the first direction corresponds to a processing direction in which the workpiece is processed,
the second direction corresponds to an interval feeding direction of the workpiece, and
a position where the holding mechanism receives and places the workpiece from and on the transfer hand and a position of the holding mechanism when the workpiece is processed by the processing machine are arranged in the first direction.

12. The processing device according to claim 4, wherein
the first moving mechanism includes at least two first guide portions that extend in the first direction and are in parallel to each other with respect to the second direction, and
the two first guide portions are configured to support the holding mechanism to be move in the first direction.

13. The processing device according to claim 2, wherein
the storage includes a first storage configured to store the workpiece that is not processed and a second storage configured to store the workpiece that is processed, and
the transfer hand includes a first transfer hand that is configured to transfer the workpiece from the first storage and to a position where the holding mechanism is configured to receive the workpiece and a second transfer hand that is configured to receive the workpiece from the holding mechanism and transfer the workpiece into the second storage.

14. The processing device according to claim 3, wherein
the storage includes a first storage configured to store the workpiece that is not processed and a second storage configured to store the workpiece that is processed, and
the transfer hand includes a first transfer hand that is configured to transfer the workpiece from the first storage and to a position where the holding mechanism is configured to receive the workpiece and a second transfer hand that is configured to receive the workpiece from the holding mechanism and transfer the workpiece into the second storage.

15. The processing device according to claim 2, wherein
the transfer mechanism includes an auxiliary hand on which the workpiece is placed, and
the auxiliary hand is configured to receive the workpiece from the holding mechanism and transfer the workpiece to the transfer hand.

16. The processing device according to claim 3, wherein
the transfer mechanism includes an auxiliary hand on which the workpiece is placed, and
the auxiliary hand is configured to receive the workpiece from the holding mechanism and transfer the workpiece to the transfer hand.

17. The processing device according to claim 2, wherein
the workpiece has at least three plate surface measurement points on a plate surface,
the processing machine includes a camera configured to take an image of each of the at least three plate surface measurement points and measure of each of the at least three plate surface measurement points and further includes a third moving mechanism configured to move the processing machine in the upper-bottom direction, and
the controller is configured to specify the plate surface based on coordinates of the plate surface measurement points before performing processing and control the processing machine to perform the processing with controlling the third moving mechanism to move the processing machine such that distances between arbitrary points on the plate surface and the processing machine are same.

18. The processing device according to claim 3, wherein
the workpiece has at least three plate surface measurement points on a plate surface,
the processing machine includes a camera configured to take an image of each of the at least three plate surface measurement points and measure of each of the at least three plate surface measurement points and further includes a third moving mechanism configured to move the processing machine in the upper-bottom direction, and
the controller is configured to specify the plate surface based on coordinates of the plate surface measurement points before performing processing and control the processing machine to perform the processing with controlling the third moving mechanism to move the processing machine such that distances between arbitrary points on the plate surface and the processing machine are same.

19. The processing device according to claim 2, wherein
the holding mechanism has a bottom surface that is configured to hold the workpiece and the bottom surface includes at least three bottom surface measurement points,
the processing machine includes a camera that is configured to take an image of each of the at least three bottom surface measurement points and measure coordinates of each of the at least three bottom surface measurement points, and
the controller is configured to specify the plate surface based on the coordinates of the bottom surface measurement points and calculate a distance between a point on the bottom surface and the processing machine.

20. The processing device according to claim 3, wherein
the holding mechanism has a bottom surface that is configured to hold the workpiece and the bottom surface includes at least three bottom surface measurement points,
the processing machine includes a camera that is configured to take an image of each of the at least three bottom surface measurement points and measure coordinates of each of the at least three bottom surface measurement points, and
the controller is configured to specify the plate surface based on the coordinates of the bottom surface measurement points and calculate a distance between a point on the bottom surface and the processing machine.
